(19) United States
(12) Patent Application Publication
(10) Pub. No.: US 2025/0204247 A1
(43) Pub. Date: Jun. 19, 2025

(54) DISPLAY APPARATUS AND ELECTRONIC DEVICE

(71) Applicant: SEMICONDUCTOR ENERGY LABORATORY CO., LTD., Atsugi-shi, Kanagawa-ken (JP)

(72) Inventors: Takayuki IKEDA, Atsugi, Kanagawa (JP); Sachiko KAWAKAMI, Atsugi, Kanagawa (JP); Nobuharu OHSAWA, Zama, Kanagawa (JP); Akira NAGASAKA, Atsugi, Kanagawa (JP); Takeyoshi WATABE, Atsugi, Kanagawa (JP); Takuya ISHIMOTO, Isehara, Kanagawa (JP); Yuko KUBOTA, Atsugi, Kanagawa (JP); Masatoshi TAKABATAKE, Atsugi, Kanagawa (JP)

(21) Appl. No.: 18/846,917

(22) PCT Filed: Mar. 7, 2023
(86) PCT No.: PCT/IB2023/052111

§ 371 Date: Sep. 13, 2024

(30) Foreign Application Priority Data
Mar. 18, 2022 (JP) 2022-044247

(51) Int. Cl. H10K 85/60; H10K 50/17; H10K 50/19; H10K 59/35

(52) U.S. Cl. CPC H10K 85/6572; H10K 85/626; H10K 85/654; H10K 50/171; H10K 50/19; H10K 59/351

(57) ABSTRACT

A novel display apparatus that is highly convenient, useful, or reliable is provided. The display apparatus includes a first tandem light-emitting device and a second tandem light-emitting device. The first tandem light-emitting device includes a first intermediate layer, the second tandem light-emitting device is adjacent to the first tandem light-emitting device, and the second tandem light-emitting device includes a second intermediate layer. A gap is included between the second intermediate layer and the first intermediate layer, the second intermediate layer contains an organic compound exhibiting an electron-injection property, and the organic compound exhibiting an electron-injection property is represented by General Formula (G0). Note that A is a substituted or unsubstituted aryl skeleton having 6 to 30 carbon atoms or a substituted or unsubstituted heteroaryl skeleton having 2 to 30 carbon atoms, and n is an integer greater than or equal to 1 and less than or equal to 4.

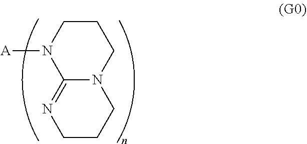

### TECHNICAL FIELD

One embodiment of the present invention relates to a display apparatus, an electronic device, or a semiconductor device.

Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Thus, more specifically, examples of the technical field of one embodiment of the present invention disclosed in this specification include a semiconductor device, a display apparatus, a light-emitting apparatus, a power storage device, a memory device, a driving method thereof, and a manufacturing method thereof.

### BACKGROUND ART

As an organic thin film that can obtain an excellent electron-injection property and electron-transport property when used as an electron-injection layer of an organic EL element, for example, a single film containing a hexahydropyrimidopyrimidine compound and a second material transporting an electron, and a stacked film of a film containing a hexahydropyrimidopyrimidine compound and a film containing the second material are known (Patent Document 1).

### Reference

### Patent Document

[Patent Document 1] International Publication WO 2021/045178 Pamphlet

### SUMMARY OF THE INVENTION

### Problems to be Solved by the Invention

An object of one embodiment of the present invention is to provide a novel display apparatus that is highly convenient, useful, or reliable. Another object is to provide a novel electronic device that is highly convenient, useful, or reliable. Another object is to provide a novel display apparatus, a novel electronic device, or a novel semiconductor device.

Note that the description of these objects does not preclude the presence of other objects. Note that in one embodiment of the present invention, there is no need to achieve all these objects. Note that other objects will be apparent from the description of the specification, the drawings, the claims, and the like, and other objects can be derived from the description of the specification, the drawings, the claims, and the like.

### Means for Solving the Problems

(1) One embodiment of the present invention is a display apparatus including a first light-emitting device and a second light-emitting device.

The first light-emitting device includes a first electrode, a second electrode, a first unit, a second unit, and a first intermediate layer; the first unit is sandwiched between the first electrode and the second electrode; and the first unit contains a first light-emitting material. The second unit is sandwiched between the second electrode and the first unit, and the second unit contains a second light-emitting material. The first intermediate layer is sandwiched between the second unit and the first unit; the first intermediate layer includes a first layer and a second layer; and the first layer is sandwiched between the second unit and the second layer. The first layer contains an organic compound having a halogen group or a cyano group or a transition metal oxide, and the second layer contains an organic compound exhibiting an electron-injection property.

The second light-emitting device is adjacent to the first light-emitting device; the second light-emitting device includes a third electrode, a fourth electrode, a third unit, a fourth unit, and a second intermediate layer; and a gap is included between the third electrode and the first electrode. The third unit is sandwiched between the third electrode and the fourth electrode, and the third unit contains a third light-emitting material. The fourth unit is sandwiched between the fourth electrode and the third unit, and the fourth unit contains a fourth light-emitting material. The second intermediate layer is sandwiched between the fourth unit and the third unit, and a region is included between the second intermediate layer and the first intermediate layer. The first intermediate layer and the second intermediate layer are separated from each other by the region, and the region overlaps with the gap.

The second intermediate layer includes a third layer and a fourth layer; the third layer is sandwiched between the fourth unit and the fourth layer; and the third layer contains an organic compound having a halogen group or a cyano group or a transition metal oxide. The fourth layer contains the organic compound exhibiting an electron-injection property, and the organic compound exhibiting an electron-injection property is represented by General Formula (G0).

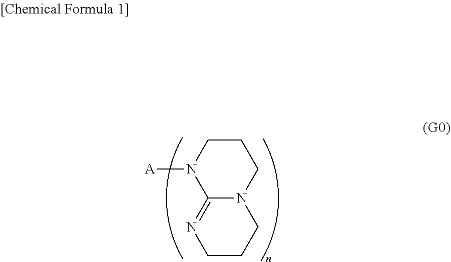

Note that A is a substituted or unsubstituted aryl skeleton having 6 to 30 carbon atoms or a substituted or unsubstituted heteroaryl skeleton having 2 to 30 carbon atoms, and n is an integer greater than or equal to 1 and less than or equal to 4.

Accordingly, electrons can be supplied from the second layer to the first unit. In addition, holes can be supplied from the first layer to the second unit. Furthermore, carriers can move in the second layer. The second layer with high film quality can be provided. A display apparatus with a low driving voltage can be provided. A display apparatus with low power consumption can be provided. As a result, a novel display apparatus that is highly convenient, useful, or reliable can be provided.

(2) Another embodiment of the present invention is the display apparatus in which a solubility of the organic compound exhibiting an electron-injection property in water is less than or equal to 1/10 of a solubility of 1,1′-pyridine-2,6-diyl-bis(1,3,4,6,7,8-hexahydro-2H-pyrimido [1,2-a]pyrimidine) in water at a pressure of one atmosphere and 300 K.

(3) Another embodiment of the present invention is the display apparatus in which the organic compound exhibiting an electron-injection property has a solubility in water of greater than 0 and less than 4.0×10⁻⁴ by weight fraction at a pressure of one atmosphere and 300 K.

(4) Another embodiment of the present invention is the display apparatus in which the organic compound exhibiting an electron-injection property is represented by General Formula (G1).

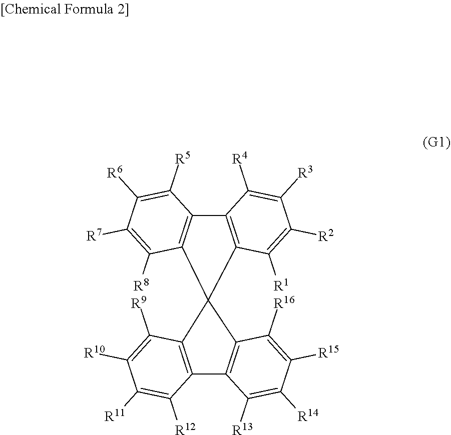

Note that in General Formula (G1) above, one or more and four or less of R¹ to R¹⁶ each include a substituted or unsubstituted 1,3,4,6,7,8-hexahydro-2H-pyrimido[1,2-a]pyrimidino group, and the others are each hydrogen, a substituted or unsubstituted alkyl group having 1 to 6 carbon atoms, a substituted or unsubstituted cycloalkyl group having 3 to 10 carbon atoms, a substituted or unsubstituted polycyclic cycloalkyl group having 4 to 10 carbon atoms, a substituted or unsubstituted aromatic hydrocarbon group having 6 to 30 carbon atoms, or a substituted or unsubstituted heteroaromatic hydrocarbon group having 2 to 30 carbon atoms, and the hydrogen may be deuterium in General Formula (G1).

Thus, an agent containing water can be used in the manufacturing process of the display apparatus. An increase in the driving voltage of the light-emitting device due to the use of the agent containing water can be inhibited. A microfabrication technique using the agent containing water can be employed, for example. The second intermediate layer can be separated from the first intermediate layer by the microfabrication technique. Current flowing between the first intermediate layer and the second intermediate layer can be reduced. Occurrence of a phenomenon in which the second light-emitting device that is adjacent to the first light-emitting device unintentionally emits light in accordance with the operation of the first light-emitting device can be inhibited. A display apparatus with a low driving voltage can be provided. A display apparatus with low power consumption can be provided. As a result, a novel display apparatus that is highly convenient, useful, or reliable can be provided.

(5) Another embodiment of the present invention is the display apparatus including a first functional layer and a second functional layer.

The first functional layer overlaps with the second functional layer, and the first functional layer includes a first pixel circuit and a second pixel circuit. The second functional layer includes the first light-emitting device and the second light-emitting device.

The first light-emitting device is electrically connected to the first pixel circuit, and the second light-emitting device is electrically connected to the second pixel circuit.

(6) Another embodiment of the present invention is the display apparatus including a first pixel and a second pixel.

The first pixel is adjacent to the second pixel, the first pixel includes the first light-emitting device and a first pixel circuit, and the second pixel includes the second light-emitting device and a second pixel circuit.

The first light-emitting device is electrically connected to the first pixel circuit, and the second light-emitting device is electrically connected to the second pixel circuit.

(7) Another embodiment of the present invention is an electronic device including the display apparatus and a sensor, an operation button, a speaker, or a microphone.

Although a block diagram in which components are classified by their functions and shown as independent blocks is shown in the drawing attached to this specification, it is difficult to completely separate actual components according to their functions and one component can relate to a plurality of functions.

Note that the light-emitting apparatus in this specification includes, in its category, an image display device that uses a light-emitting device. The light-emitting apparatus may also include a module in which a light-emitting device is provided with a connector such as an anisotropic conductive film or a TCP (Tape Carrier Package), a module in which a printed wiring board is provided at the end of a TCP, and a module in which an IC (integrated circuit) is directly mounted on a light-emitting device by a COG (Chip On Glass) method. Furthermore, a lighting device or the like may include the light-emitting apparatus.

### Effect of the Invention

According to one embodiment of the present invention, a novel display apparatus that is highly convenient, useful, or reliable can be provided. According to one embodiment of the present invention, a novel electronic device that is highly convenient, useful, or reliable can be provided. Alternatively, a novel display apparatus can be provided. Alternatively, a novel electronic device can be provided.

Note that the description of these effects does not preclude the presence of other effects. Note that one embodiment of the present invention does not need to have all the effects. Note that other effects will be apparent from the description of the specification, the drawings, the claims, and the like, and other effects can be derived from the description of the specification, the drawings, the claims, and the like.

### BRIEF DESCRIPTION OF THE DRAWINGS

FIG. TA and FIG. 1B are diagrams illustrating structures of a light-emitting device of an embodiment.

FIG. 2A and FIG. 2B are diagrams illustrating a structure of a light-emitting device of an embodiment.

FIG. 3 is a diagram illustrating a structure of a display apparatus of an embodiment.

FIG. 4 is a diagram illustrating a structure of a display apparatus of an embodiment.

FIG. 5A to FIG. 5C are diagrams illustrating a structure of a display apparatus of an embodiment.

FIG. 6 is a diagram illustrating a structure of a display apparatus of an embodiment.

FIG. 7A to FIG. 7C are diagrams illustrating structures of a display apparatus of an embodiment.

FIG. 8A and FIG. 8B are diagrams illustrating an active matrix light-emitting apparatus of an embodiment.

FIG. 9A and FIG. 9B are diagrams illustrating an active matrix light-emitting apparatus of an embodiment.

FIG. 10 is a diagram illustrating an active matrix light-emitting apparatus of an embodiment;

FIG. 11A and FIG. 11B are diagrams illustrating a passive matrix light-emitting apparatus of an embodiment.

FIG. 12A and FIG. 12B are diagrams illustrating a lighting apparatus of an embodiment.

FIG. 13A to FIG. 13D are diagrams illustrating electronic devices of an embodiment.

FIG. 14A to FIG. 14C are diagrams illustrating electronic devices of an embodiment.

FIG. 15 is a diagram illustrating a lighting apparatus of an embodiment.

FIG. 16 is a diagram illustrating a lighting apparatus of an embodiment.

FIG. 17 is a diagram illustrating in-vehicle display apparatuses and lighting apparatuses of an embodiment.

FIG. 18A to FIG. 18C are diagrams illustrating an electronic device of an embodiment.

FIG. 19A and FIG. 19B are diagrams illustrating a structure of a display apparatus of Example.

FIG. 20 is a graph showing current density-luminance characteristics of light-emitting devices of Example.

FIG. 21 is a graph showing luminance-current efficiency characteristics of light-emitting devices of Example.

FIG. 22 is a graph showing voltage-luminance characteristics of light-emitting devices of Example.

FIG. 23 is a graph showing voltage-current characteristics of light-emitting devices of Example.

FIG. 24 is a graph showing emission spectra of light-emitting devices of Example.

FIG. 25A and FIG. 25B are diagrams illustrating a structure of a display apparatus of Example.

FIG. 26A and FIG. 26B are diagrams illustrating a structure of a display apparatus of Example.

FIG. 27 is a graph showing current density-luminance characteristics of light-emitting devices of Example.

FIG. 28 is a graph showing luminance-current efficiency characteristics of light-emitting devices of Example.

FIG. 29 is a graph showing voltage-luminance characteristics of light-emitting devices of Example.

FIG. 30 is a graph showing voltage-current characteristics of light-emitting devices of Example.

FIG. 31 is a graph showing emission spectra of light-emitting devices of Example.

FIG. 32A and FIG. 32B are diagrams illustrating a structure of a display apparatus of Example.

FIG. 33A and FIG. 33B are diagrams illustrating a structure of a display apparatus of Example.

FIG. 34 is a graph showing current density-luminance characteristics of a light-emitting device of Example.

FIG. 35 is a graph showing luminance-current efficiency characteristics of a light-emitting device of Example.

FIG. 36 is a graph showing voltage-luminance characteristics of a light-emitting device of Example.

FIG. 37 is a graph showing voltage-current characteristics of a light-emitting device of Example.

FIG. 38 is a graph showing an emission spectrum of a light-emitting device of Example.

FIG. 39 is a graph showing driving voltages of light-emitting devices of Example.

FIG. 40 is a graph showing current density-luminance characteristics of light-emitting devices of Example.

FIG. 41 is a graph showing luminance-current efficiency characteristics of light-emitting devices of Example.

FIG. 42 is a graph showing voltage-luminance characteristics of light-emitting devices of Example.

FIG. 43 is a graph showing voltage-current characteristics of light-emitting devices of Example.

FIG. 44 is a graph showing emission spectra of light-emitting devices of Example.

FIG. 45 is a graph showing temporal changes in normalized luminance of light-emitting devices of Example.

### MODE FOR CARRYING OUT THE INVENTION

A display apparatus of one embodiment of the present invention includes a first light-emitting device and a second light-emitting device. The first light-emitting device includes a first electrode, a second electrode, a first unit, a second unit, and a first intermediate layer. The first unit is sandwiched between the first electrode and the second electrode. The first unit contains a first light-emitting material. The second unit is sandwiched between the second electrode and the first unit, and the second unit contains a second light-emitting material. The first intermediate layer is sandwiched between the second unit and the first unit. The first intermediate layer includes a first layer and a second layer. The first layer is sandwiched between the second unit and the second layer. The first layer contains an organic compound including a halogen group or a cyano group or a transition metal oxide. The second layer contains an organic compound exhibiting an electron-injection property.

The second light-emitting device is adjacent to the first light-emitting device. The second light-emitting device includes a third electrode, a fourth electrode, a third unit, a fourth unit, and a second intermediate layer. A gap is included between the third electrode and the first electrode. The third unit is sandwiched between the third electrode and the fourth electrode. The third unit contains a third light-emitting material. The fourth unit is sandwiched between the fourth electrode and the third unit. The fourth unit contains a fourth light-emitting material. The second intermediate layer is sandwiched between the fourth unit and the third unit. A region is included between the second intermediate layer and the first intermediate layer. The first intermediate layer and the second intermediate layer are separated from each other by the region, and the region overlaps with the gap.

The second intermediate layer includes a third layer and a fourth layer. The third layer is sandwiched between the fourth unit and the fourth layer. The third layer contains an organic compound having a halogen group or a cyano group or a transition metal oxide. The fourth layer contains the organic compound exhibiting an electron-injection property. The organic compound exhibiting an electron-injection property is represented by General Formula (G0).

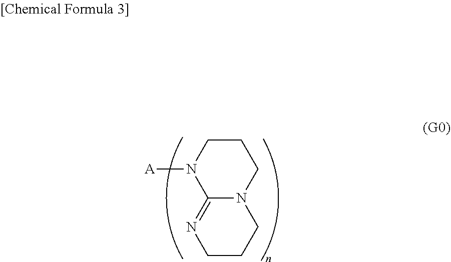

Note that A is a substituted or unsubstituted aryl skeleton having 6 to 30 carbon atoms or a substituted or unsubstituted heteroaryl skeleton having 2 to 30 carbon atoms, and n is an integer greater than or equal to 1 and less than or equal to 4.

Accordingly, electrons can be supplied from the second layer to the first unit. In addition, holes can be supplied from the first layer to the second unit. Carriers can move in the second layer. The second layer with high film quality can be provided. An agent containing water can be used in the manufacturing process of the display apparatus. An increase in the driving voltage of the light-emitting device due to the use of the agent containing water can be inhibited. A microfabrication technique using the agent containing water can be employed, for example. The second intermediate layer can be separated from the first intermediate layer by using the microfabrication technique. Current flowing between the first intermediate layer and the second intermediate layer can be reduced. Occurrence of a phenomenon in which the second light-emitting device that is adjacent to the first light-emitting device unintentionally emits light in accordance with the operation of the first light-emitting device can be inhibited. As a result, a novel display apparatus that is highly convenient, useful, or reliable can be provided.

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

In this embodiment, a structure of a light-emitting device 550X of one embodiment of the present invention will be described with reference to FIG. 1.

FIG. 1A is a cross-sectional view illustrating a structure of the light-emitting device 550X of one embodiment of the present invention. FIG. 1B is a cross-sectional view illustrating a structure of the light-emitting device 550X of one embodiment of the present invention, which is different from the structure described with reference to FIG. 1A.

### Structure Example 1 of Light-Emitting Device 550X

The light-emitting device 550X described in this embodiment includes an electrode 551X, an electrode 552X, a unit 103X, a unit 103X2, and an intermediate layer 106X (see FIG. 1A). The unit 103X is sandwiched between the electrode 551X and the electrode 552X, and the unit 103X contains a first light-emitting material EM1. The intermediate layer 106X is sandwiched between the unit 103X2 and the unit 103X.

The unit 103X2 is sandwiched between the electrode 552X and the unit 103X, and the unit 103X2 contains a second light-emitting material EM2.

### Structure Example of Intermediate Layer 106X

The intermediate layer 106X has a function of supplying electrons to the anode side and supplying holes to the cathode side by applying voltages. The intermediate layer 106X can be referred to as a charge-generation layer.

The intermediate layer 106X includes a layer 106X1 and a layer 106X2. The layer 106X1 is sandwiched between the unit 103X2 and the layer 106X2.

### Structure Example of Layer 106X1

For example, a material having a hole mobility lower than or equal to 1×10⁻³ cm²/Vs when the square root of the electric field strength [V/cm] is 600 can be used for the layer 106X1. A film having an electrical resistivity greater than or equal to 1×10⁴ [Ω cm] and less than or equal to 1×10⁷ [Ω cm] can be used as the layer 106X1. The layer 106X1 preferably has an electrical resistivity greater than or equal to 5×10⁴ [Ω cm] and less than or equal to 1×10⁷ [Ω cm], further preferably greater than or equal to 1×10⁵ [Ω cm] and less than or equal to 1×10⁷ [Ω cm].

Specifically, a substance AM1 having an electron-accepting property can be used for the layer 106X1.

### [Substance AM1 Having Electron-Accepting Property]

An organic compound and an inorganic compound can be used as the substance AM1 having an electron-accepting property. The substance AM1 having an electron-accepting property can extract electrons from an adjacent hole-transport layer or an adjacent material having a hole-transport property by the application of an electric field.

For example, a compound having an electron-withdrawing group (a halogen group or a cyano group) can be used as the substance AM1 having an electron-accepting property. Note that an organic compound having an electron-accepting property is easily evaporated and deposited. As a result, the productivity of the light-emitting device 550X can be increased.

Specifically, it is possible to use, for example, 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), or 2-(7-dicyanomethylen-1,3,4,5,6,8,9,10-octafluoro-7H-pyren-2-ylidene)malononitrile.

A compound in which electron-withdrawing groups are bonded to a condensed aromatic ring having a plurality of heteroatoms, such as HAT-CN, is particularly preferable because it is thermally stable.

Alternatively, a [3] radialene derivative having an electron-withdrawing group (in particular, a cyano group or a halogen group such as a fluoro group) is preferable because it has a very high electron-accepting property.

Specifically, it is possible to use, for example, α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], or α,α′,α″-1,2,3-cyclopropanetriylidenetris[2,3,4,5,6-pentafluorobenzeneacetonitrile].

As the substance AM1 having an electron-accepting property, a transition metal oxide such as molybdenum oxide, vanadium oxide, ruthenium oxide, tungsten oxide, or manganese oxide can be used.

Alternatively, it is possible to use phthalocyanine (abbreviation: H₂Pc), a phthalocyanine-based compound or complex compound such as copper phthalocyanine (abbreviation: CuPc), and compounds having an aromatic amine skeleton such as 4,4′-bis[N-(4-diphenylaminophenyl)-N-phenylamino]biphenyl (abbreviation: DPAB) and N,N-bis[4-bis(3-methylphenyl)aminophenyl]-N,N-diphenyl-4,4′-diaminophenyl (abbreviation: DNTPD).

Furthermore, it is possible to use, for example, a high molecular compound such as poly(3,4-ethylenedioxythiophene)/polystyrenesulfonic acid (abbreviation: PEDOT/PSS).

### Structure Example 1 of Composite Material

For example, a composite material containing the substance AM1 having an electron-accepting property and a material having a hole-transport property can be used for the layer 106X1.

As the material having a hole-transport property in the composite material, for example, a compound having an aromatic amine skeleton, a carbazole derivative, an aromatic hydrocarbon, an aromatic hydrocarbon having a vinyl group, a high molecular compound (such as an oligomer, a dendrimer, or a polymer), or the like can be used. A material having a hole mobility of 1×10⁻⁶ cm²/Vs or higher can be suitably used as the material having a hole-transport property in the composite material. For example, a material having a hole-transport property usable for a layer 112X that will be described in Embodiment 2 can be used as the composite material.

Furthermore, a substance having a relatively deep highest occupied molecular orbital (HOMO) level can be suitably used as the material having a hole-transport property in the composite material. Specifically, the HOMO level is preferably higher than or equal to −5.7 eV and lower than or equal to −5.4 eV. In that case, hole injection to the unit 103X2 can be facilitated. Alternatively, the reliability of the light-emitting device 550X can be increased.

As the compound having an aromatic amine skeleton, it is possible to use, for example, N,N-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), DNTPD, or 1,3,5-tris[N-(4-diphenylaminophenyl)-N-phenylamino]benzene (abbreviation: DPA3B).

As the carbazole derivative, it is possible to use, for example, 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthracenyl)phenyl]-9H-carbazole (abbreviation: CzPA), or 1,4-bis[4-(N-carbazolyl)phenyl]-2,3,5,6-tetraphenylbenzene.

As the aromatic hydrocarbon, it is possible to use, for example, 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, pentacene, or coronene.

As the aromatic hydrocarbon having a vinyl group, it is possible to use, for example, 4,4′-bis(2,2-diphenylvinyl)biphenyl (abbreviation: DPVBi) or 9,10-bis[4-(2,2-diphenylvinyl)phenyl]anthracene (abbreviation: DPVPA).

As the high molecular compound, it is possible to use, for example, poly(N-vinylcarbazole) (abbreviation: PVK), poly(4-vinyl)triphenylamine) (abbreviation: PVTPA), poly[N-(4-{N-[4-(4-diphenylamino)phenyl]phenyl-N-phenylamino}phenyl)methacrylamide](abbreviation: PTPDMA), or poly[N,N-bis(4-butylphenyl)-N,N-bis(phenyl)benzidine](abbreviation: Poly-TPD).

As another example, a substance having any of a carbazole skeleton, a dibenzofuran skeleton, a dibenzothiophene skeleton, and an anthracene skeleton can be favorably used as the material having a hole-transport property in the composite material. Moreover, as the material having a hole-transport property in the composite material, it is possible to use a substance including any of an aromatic amine having a substituent that includes a dibenzofuran ring or a dibenzothiophene ring, an aromatic monoamine that includes a naphthalene ring, and an aromatic monoamine in which a 9-fluorenyl group is bonded to nitrogen of amine through an arylene group. With the use of a substance including an N,N-bis(4-biphenyl)amino group, the reliability of the light-emitting device 550X can be increased.

As these materials, it is possible to use, for example, N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyl)triphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyl)triphenylamine (abbreviation: BBAβNB), 4-[4-(2-naphthyl)phenyl]-4′,4″-diphenyl)triphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yl)triphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyl)triphenylamine (abbreviation: TPBiAβNB), 4-(3-biphenylyl)-4′-[4-(2-naphthyl)phenyl]-4″-phenyl)triphenylamine (abbreviation: mTPBiAβNBi), 4-(4-biphenylyl)-4′-[4-(2-naphthyl)phenyl]-4″-phenyl)triphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-[4′-(carbazol-9-yl)biphenyl-4-yl]-4′-(2-naphthyl)-4″-phenyl)triphenylamine (abbreviation: YGTBij3NB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi[9H-fluoren]-4-amine (abbreviation: oFBiSF), N-(4-biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, or N,N-bis(9,9-dimethyl-9H-fluoren-2-yl)-9,9′-spirobi-9H-fluoren-1-amine.

### Structure Example 2 of Composite Material

For example, a composite material containing the substance AM1 having an electron-accepting property, a material having a hole-transport property, and a fluoride of an alkali metal or a fluoride of an alkaline earth metal can be used. In particular, a composite material in which the proportion of fluorine atoms is higher than or equal to 20% can be suitably used. Thus, the refractive index of the layer 106X1 can be reduced. Alternatively, a layer with a low refractive index can be formed inside the light-emitting device 550X. Alternatively, the external quantum efficiency of the light-emitting device 550X can be improved.

### Structure Example 1 of Layer 106X2

The layer 106X2 contains an organic compound represented by General Formula (G0).

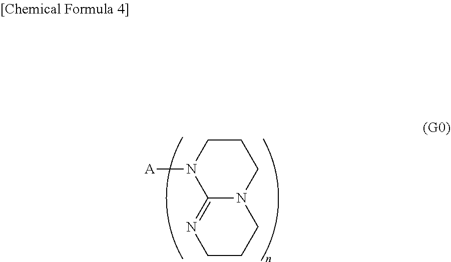

Note that in General Formula (G0), a substituent A is a substituted or unsubstituted aryl skeleton having 6 to 30 carbon atoms or a substituted or unsubstituted heteroaryl skeleton having 2 to 30 carbon atoms, and n is an integer greater than or equal to 1 and less than or equal to 4. For example, an aryl skeleton or a heteroaryl skeleton having any of skeletons represented by Structural Formula (A-1) to Structural Formula (A-30) below can be used as the substituent A.

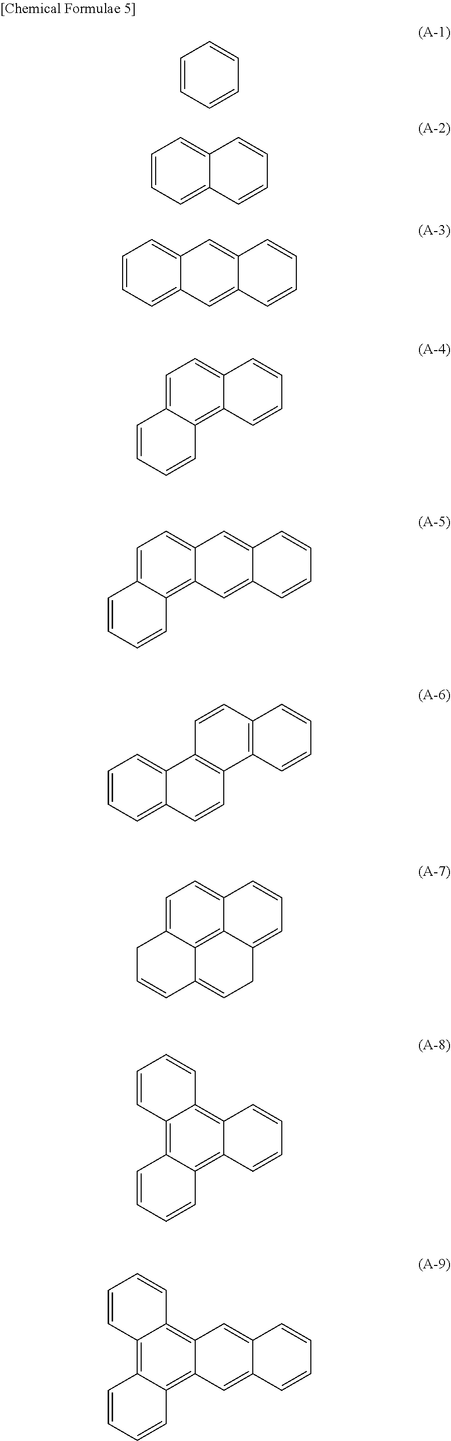

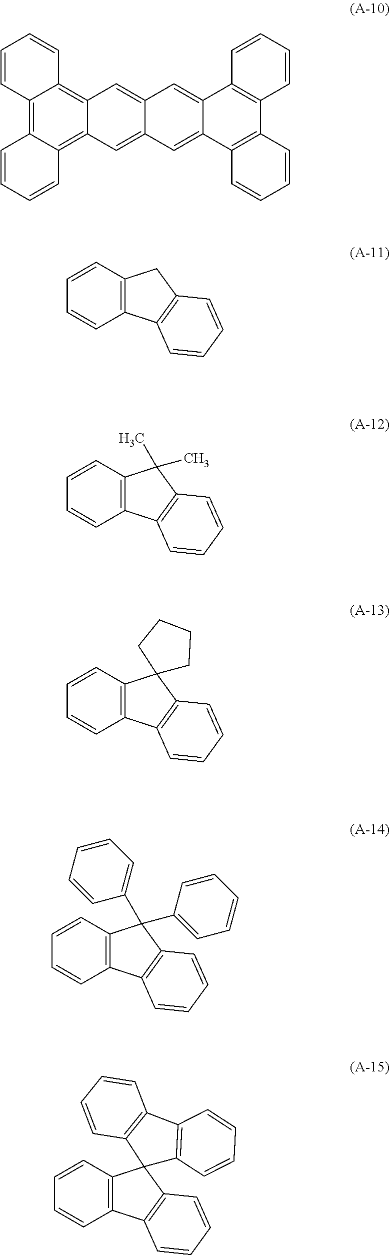

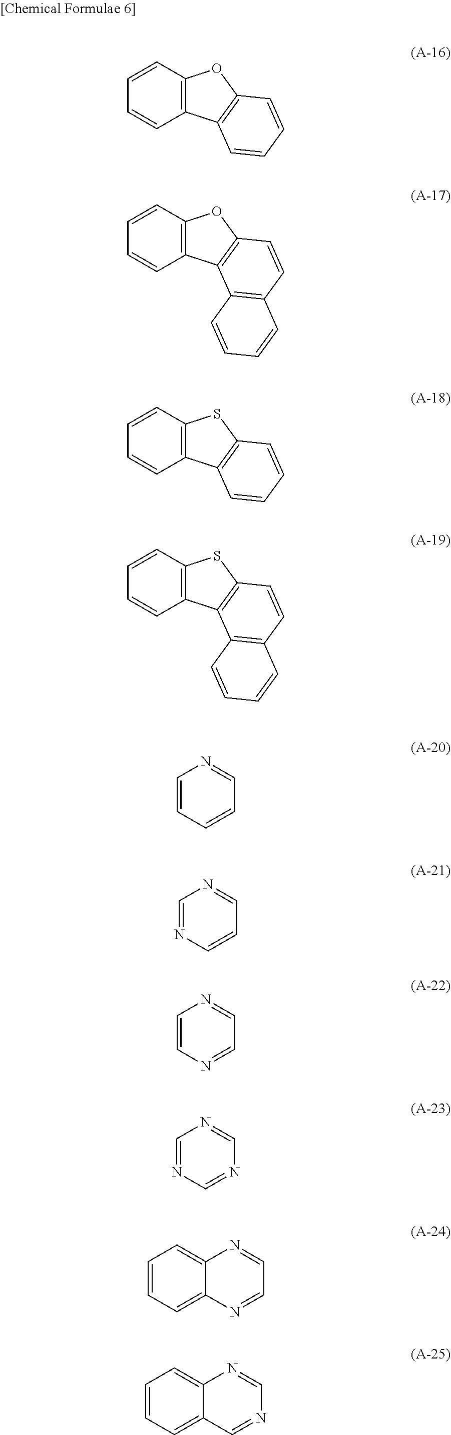

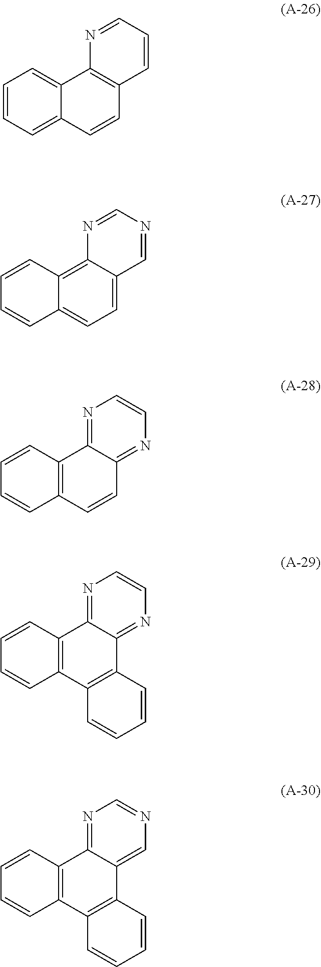 [SMILES: c1ccc2c(c1)ccc1cccnc12 ; c1ccc2c(c1)ccc1cncnc12 ; c1ccc2c(c1)ccc1nccnc12 ; c1ccc2c(c1)c1ccccc1c1nccnc21 ; c1ccc2c(c1)c1ccccc1c1ncncc21]

Thus, electrons can be supplied from the layer 106X2 to the unit 103X. The organic compound represented by General Formula (G0) can be regarded as exhibiting an electron-injection property. Furthermore, holes can be supplied from the layer 106X1 to the unit 103X2. Furthermore, carriers can move in the layer 106X2. The layer 106X2 with high film quality can be provided. As a result, a novel display apparatus that is highly convenient, useful, or reliable can be provided.

As a substituent included in the above aryl group or the above heteroaryl group, it is possible to use, for example, an alkyl group having 1 to 4 carbon atoms, a substituted or unsubstituted cycloalkyl group having 3 to 10 carbon atoms, a substituted or unsubstituted aromatic hydrocarbon group having 6 to 30 carbon atoms, or a substituted or unsubstituted heteroaromatic hydrocarbon group having 2 to 30 carbon atoms.

Note that examples of the alkyl group include a methyl group, an ethyl group, a propyl group, an isopropyl group, a butyl group, an isobutyl group, a tert-butyl group, and an n-hexyl group. Examples of the cycloalkyl group include a cyclopropyl group, a cyclobutyl group, a cyclopentyl group, a cyclohexyl group, and an adamantyl group. Examples of the aryl group include a phenyl group, a naphthyl group, a biphenyl group, a fluorenyl group, and a spirofluorenyl group.

As the aromatic hydrocarbon group, a substituted or unsubstituted aromatic hydrocarbon group having 6 to 30 carbon atoms can be used, and examples thereof include a phenyl group, a naphthyl group, a biphenyl group, a fluorenyl group, and a spirofluorenyl group.

As the heteroaromatic hydrocarbon group, a substituted or unsubstituted heteroaromatic ring having 1 to 30 carbon atoms can be used. Examples thereof include a pyridine ring, a diazine ring (a pyrimidine ring, a pyrazine ring, or a pyridazine ring), a triazine ring, a quinoline ring, a quinoxaline ring, a quinazoline ring, a benzoquinazoline ring, a phenanthroline ring, an azafluoranthene ring, an imidazole ring, an oxazole ring, an oxadiazole ring, and a triazole ring.

[Example 1 of organic compound]A solubility of the organic compound represented by General Formula (G0) in water is preferably less than or equal to 1/10, further preferably less than or equal to 1/100 of a solubility of 1,1′-pyridine-2,6-diyl-bis(1,3,4,6,7,8-hexahydro-2H-pyrimido[1,2-a]pyrimidine) (abbreviation: hpp2Py) in water at a pressure of one atmosphere and a temperature of 300 K. A structural formula of hpp2Py is shown below.

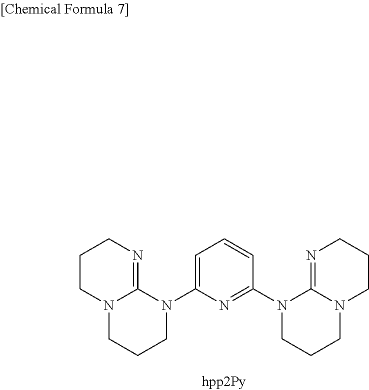 [SMILES: c1cc(N2CCCN3CCCN=C32)nc(N2CCCN3CCCN=C32)c1]

### Example 2 of Organic Compound

The organic compound represented by General Formula (G0) preferably has a solubility in water of greater than 0 and less than 4.0×10⁻⁴, further preferably greater than 0 and less than 2.2×10⁻⁵ at a weight fraction at a pressure of one atmosphere and a temperature of 300 K. Note that the solubility in this specification refers to a value obtained by dividing the weight of a solute by the weight of a solution.

### Structure Example 2 of Layer 106X2

The layer 106X2 contains an organic compound represented by General Formula (G1).

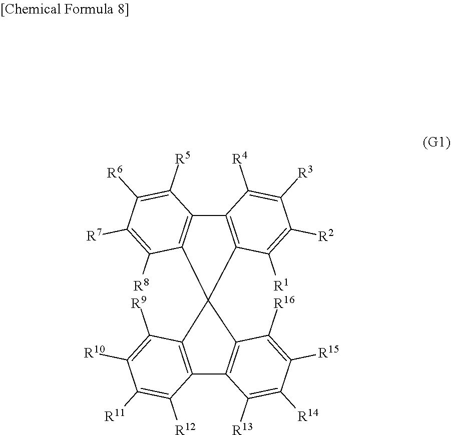

Note that in General Formula (G1) above, one or more and four or less of R¹ to R¹⁶ each include a substituted or unsubstituted 1,3,4,6,7,8-hexahydro-2H-pyrimido[1,2-a]pyrimidino group, and the others are each hydrogen, a substituted or unsubstituted alkyl group having 1 to 6 carbon atoms, a substituted or unsubstituted cycloalkyl group having 3 to 10 carbon atoms, a substituted or unsubstituted polycyclic cycloalkyl group having 4 to 10 carbon atoms, a substituted or unsubstituted aromatic hydrocarbon group having 6 to 30 carbon atoms, or a substituted or unsubstituted heteroaromatic hydrocarbon group having 2 to 30 carbon atoms, and the hydrogen may be deuterium in General Formula (G1).

Thus, electrons can be supplied from the layer 106X2 to the unit 103X. Holes can be supplied from the layer 106X1 to the unit 103X2. Carriers can move in the layer 106X2. The layer 106X2 with high film quality can be provided. An agent containing water can be used in the manufacturing process of the light-emitting device. An increase in the driving voltage of the light-emitting device due to the use of the agent containing water can be inhibited. A microfabrication technique using the agent containing water can be employed, for example. A display apparatus with a low driving voltage can be provided. A display apparatus with low power consumption can be provided. As a result, a novel display apparatus that is highly convenient, useful, or reliable can be provided. For example, an agent containing water and phosphoric acid, an agent containing water and tetramethyl ammonium hydroxide, or the like can be used in the manufacturing process.

Specifically, organic compounds represented by structural formulae below, such as 1-(9,9′-spirobi[9H-fluoren]-2-yl)-1,3,4,6,7,8-hexahydro-2H-pyrimido[1,2-a]pyrimidine (abbreviation: 2hppSF) and 1,1′-(9,9′-spirobi[9H-fluoren]-2,7-diyl)bis(1,3,4,6,7,8-hexahydro-2H-pyrimido[1,2-a]pyrimidine) (abbreviation: 2,7hpp2SF), and the like can be used for the layer 106X2.

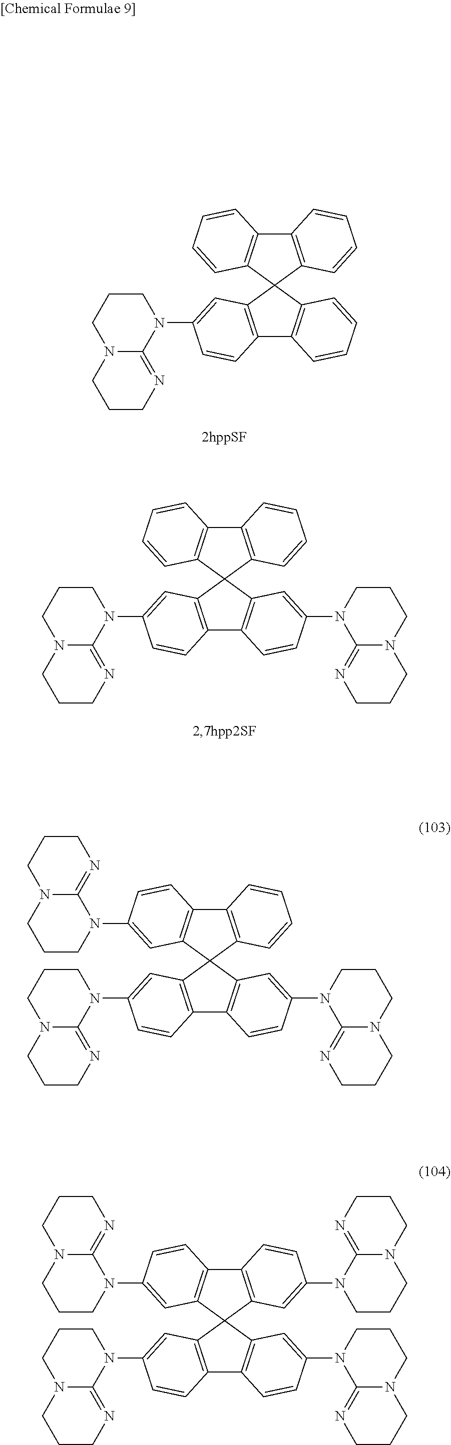 [SMILES: c1ccc2c(c1)-c1ccccc1C21c2ccccc2-c2ccc(N3CCCN4CCCN=C43)cc21 ; c1ccc2c(c1)-c1ccccc1C21c2cc(N3CCCN4CCCN=C43)ccc2-c2ccc(N3CCCN4CCCN=C43)cc21 ; c1ccc2c(c1)-c1ccc(N3CCCN4CCCN=C43)cc1C21c2cc(N3CCCN4CCCN=C43)ccc2-c2ccc(N3CCCN4CCCN=C43)cc21 ; c1cc2c(cc1N1CCCN3CCCN=C31)C1(c3cc(N4CCCN5CCCN=C54)ccc3-2)c2cc(N3CCCN4CCCN=C43)ccc2-c2ccc(N3CCCN4CCCN=C43)cc21]

### Structure Example 3 of Layer 106X2

The layer 106X2 includes a layer 106X21 and a layer 106X22 (see FIG. 1B). The layer 106X21 is sandwiched between the layer 106X22 and the unit 103X.

The layer 106X21 contains an organic compound represented by General Formula (G0).

The layer 106X22 contains a metal. For example, a Group 13 element or the like can be used for the layer 106X22. Specifically, aluminum can be used for the layer 106X22.

For example, aluminum can be used for the layer 106X22.

### Structure Example 2 of Intermediate Layer 106X

The intermediate layer 106X includes a layer 106X3, and the layer 106X3 is sandwiched between the layer 106X1 and the layer 106X2 (see FIG. 1A and FIG. 1B).

The layer 106X3 contains a material having an electron-transport property.

### Structure Example of Layer 106X3

The layer 106X3 can be referred to as an electron-relay layer. With the use of the layer 106X3, a layer that is in contact with the anode side of the layer 106X3 can be distanced from a layer that is in contact with the cathode side of the layer 106X3. It is possible to reduce interaction between the layer in contact with the anode side of the layer 106X3 and the layer in contact with the cathode side of the layer 106X3. Electrons can be smoothly supplied to the layer in contact with the anode side of the layer 106X3.

A substance whose lowest unoccupied molecular orbital (LUMO) level is between the LUMO level of the substance AM1 that has an electron-accepting property and is contained in the layer 106X1 and the LUMO level of the substance contained in the layer 106X2 can be suitably used for the layer 106X3.

For example, a material that has a LUMO level higher than or equal to −5.0 eV, preferably higher than or equal to −5.0 eV and lower than or equal to −3.0 eV can be used for the layer 106X3.

Specifically, a phthalocyanine-based material can be used for the layer 106X3. For example, copper phthalocyanine (abbreviation: CuPc) or a metal complex having a metal-oxygen bond and an aromatic ligand can be used for the layer 106X3.

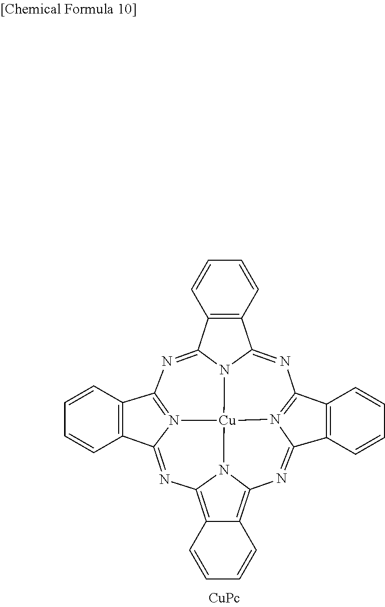

Note that this embodiment can be combined with any of the other embodiments described in this specification as appropriate.

### Embodiment 2

In this embodiment, a structure of the light-emitting device 550X of one embodiment of the present invention will be described with reference to FIG. 1.

### Structure Example 1 of Light-Emitting Device 550X

The light-emitting device 550X described in this embodiment includes the electrode 551X, the electrode 552X, the unit 103X, the unit 103X2, and the intermediate layer 106X (see FIG. 1A).

The unit 103X is sandwiched between the electrode 552X and the electrode 551X, and the unit 103X contains the light-emitting material EM1. Note that the unit 103X has a function of emitting light ELX1. Although FIG. 1A illustrates an example where the light ELX1 is emitted from the electrode 552X side, the light ELX1 may be emitted from the electrode 551X side.

The unit 103X2 is sandwiched between the electrode 552X and the unit 103X, and the unit 103X2 contains the light-emitting material EM2. Note that the unit 103X2 has a function of emitting light ELX2.

In other words, the light-emitting device 550X includes the stacked units between the electrode 551X and the electrode 552X. Note that the number of stacked units is not limited to two, and three or more units can be stacked. A structure including the stacked units sandwiched between the electrode 551X and the electrode 552X and the intermediate layer 106X sandwiched between the units is referred to as a stacked light-emitting device or a tandem light-emitting device in some cases.

This structure can provide light emission at high luminance while the current density is kept low. Alternatively, the reliability can be improved. Alternatively, the driving voltage can be reduced as compared to other structures with the same luminance. Alternatively, power consumption can be reduced.

### Structure Example 1 of Unit 103X

The unit 103X has a single-layer structure or a stacked-layer structure. For example, the unit 103X includes a layer 111X, the layer 112X, and a layer 113X (see FIG. 1A). The layer 111X is sandwiched between the layer 112X and the layer 113X.

For example, a layer selected from functional layers such as a light-emitting layer, a hole-transport layer, an electron-transport layer, and a carrier-blocking layer can be used in the unit 103X. Moreover, a layer selected from functional layers such as a hole-injection layer, an electron-injection layer, an exciton-blocking layer, and a charge-generation layer can be used in the unit 103X.

### Structure Example of Layer 112X

For example, a material having a hole-transport property can be used for the layer 112X. The layer 112X can be referred to as a hole-transport layer. A material having a wider band gap than the light-emitting material contained in the layer 111X is preferably used for the layer 112X. In that case, energy transfer from excitons generated in the layer 111X to the layer 112X can be inhibited.

### [Material Having Hole-Transport Property]

A material having a hole mobility higher than or equal to 1×10⁻⁶ cm²/Vs can be suitably used as the material having a hole-transport property.

As the material having a hole-transport property, an amine compound or an organic compound having a π-electron rich heteroaromatic ring skeleton can be used, for example. Specifically, a compound having an aromatic amine skeleton, a compound having a carbazole skeleton, a compound having a thiophene skeleton, a compound having a furan skeleton, or the like can be used. The compound having an aromatic amine skeleton and the compound having a carbazole skeleton are particularly preferable because these compounds are highly reliable and have high hole-transport properties to contribute to a reduction in driving voltage.

As the compound having an aromatic amine skeleton, for example, 4,4′-bis[N-(1-naphthyl)-N-phenylamino]biphenyl (abbreviation: NPB), N,N-diphenyl-N,N-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]-9,9′-spirobi[9H-fluoren]-2-amine (abbreviation: PCBASF), or the like can be used.

As the compound having a carbazole skeleton, for example, 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), or the like can be used.

As the compound having a thiophene skeleton, for example, 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), 4-[4-(9-phenyl-9H-fluoren-9-yl)phenyl]-6-phenyldibenzothiophene (abbreviation: DBTFLP-IV), or the like can be used.

As the compound having a furan skeleton, for example, 4,4′,4″-(benzene-1,3,5-triyl)tri(dibenzofuran) (abbreviation: DBF3P-II), 4-{3-[3-(9-phenyl-9H-fluoren-9-yl)phenyl]phenyl}dibenzofuran (abbreviation: mmDBFFLBi-II), or the like can be used.

### Structure Example of Layer 113X

A material having an electron-transport property, a material having an anthracene skeleton, or a mixed material can be used for the layer 113X, for example. The layer 113X can be referred to as an electron-transport layer. Note that a material having a wider band gap than the light-emitting material contained in the layer 111X is preferably used for the layer 113X. In that case, energy transfer from excitons generated in the layer 111X to the layer 113X can be inhibited.

### [Material Having Electron-Transport Property]

A material having an electron mobility higher than or equal to 1×10⁻⁷ cm²/Vs and lower than or equal to 5×10⁻⁵ cm²/Vs in a condition where the square root of the electric field strength [V/cm] is 600 can be favorably used as the material having an electron-transport property. Thus, the electron-transport property in the electron-transport layer can be inhibited. Alternatively, the amount of electrons injected into the light-emitting layer can be controlled. Alternatively, the light-emitting layer can be prevented from having excess electrons.

For example, a metal complex or an organic compound having a 7t-electron deficient heteroaromatic ring skeleton can be used as the material having an electron-transport property.

As the metal complex, for example, bis(10-hydroxybenzo[h]quinolinato)beryllium(II) (abbreviation: BeBq₂), bis(2-methyl-8-quinolinolato) (4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), bis[2-(2-benzothiazolyl)phenolato]zinc(II) (abbreviation: ZnBTZ), or the like can be used.

As the organic compound having a π-electron deficient heteroaromatic ring skeleton, for example, a heterocyclic compound having a polyazole skeleton, a heterocyclic compound having a diazine skeleton, a heterocyclic compound having a pyridine skeleton, a heterocyclic compound having a triazine skeleton, or the like can be used. In particular, the heterocyclic compound having a diazine skeleton or the heterocyclic compound having a pyridine skeleton has favorable reliability and thus is preferable. In addition, the heterocyclic compound having a diazine (pyrimidine or pyrazine) skeleton has a high electron-transport property to contribute to a reduction in driving voltage.

As the heterocyclic compound having a polyazole skeleton, for example, 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-TH-benzimidazole) (abbreviation: TPBI), 2-[3-(dibenzothiophen-4-yl)phenyl]-1-phenyl-TH-benzimidazole (abbreviation: mDBTBIm-II), or the like can be used.

As the heterocyclic compound having a diazine skeleton, for example, 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,8-bis[3-(dibenzothiophen-4-yl)phenyl]benzo[h]quinazoline (abbreviation: 4,8mDBtP2Bqn), or the like can be used.

As the heterocyclic compound having a pyridine skeleton, for example, 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), or the like can be used.

As the heterocyclic compound having a triazine skeleton, for example, 2-[3′-(9,9-dimethyl-9H-fluoren-2-yl)biphenyl-3-yl]-4,6-diphenyl-1,3,5-triazine (abbreviation: mFBPTzn), 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), or the like can be used.

### [Material Having Anthracene Skeleton]

An organic compound having an anthracene skeleton can be used for the layer 113X. In particular, an organic compound having both an anthracene skeleton and a heterocyclic skeleton can be suitably used.

For example, an organic compound having both an anthracene skeleton and a nitrogen-containing five-membered ring skeleton can be used for the layer 113X. Alternatively, an organic compound having both an anthracene skeleton and a nitrogen-containing five-membered ring skeleton where two heteroatoms are included in a ring can be used for the layer 113X. Specifically, a pyrazole ring, an imidazole ring, an oxazole ring, a thiazole ring, or the like can be favorably used as the heterocyclic skeleton.

For example, an organic compound having both an anthracene skeleton and a nitrogen-containing six-membered ring skeleton can be used for the layer 113X. Alternatively, an organic compound having both an anthracene skeleton and a nitrogen-containing six-membered ring skeleton where two heteroatoms are included in a ring can be used for the layer 113X. Specifically, a pyrazine ring, a pyrimidine ring, a pyridazine ring, or the like can be favorably used as the heterocyclic skeleton.

### Structure Example of Mixed Material

A material in which a plurality of kinds of substances are mixed can be used for the layer 113X. Specifically, a mixed material that contains a substance having an electron-transport property and any of an alkali metal, an alkali metal compound, and an alkali metal complex can be used for the layer 113X. Note that it is further preferable that the HOMO level of the material having an electron-transport property be −6.0 eV or higher.

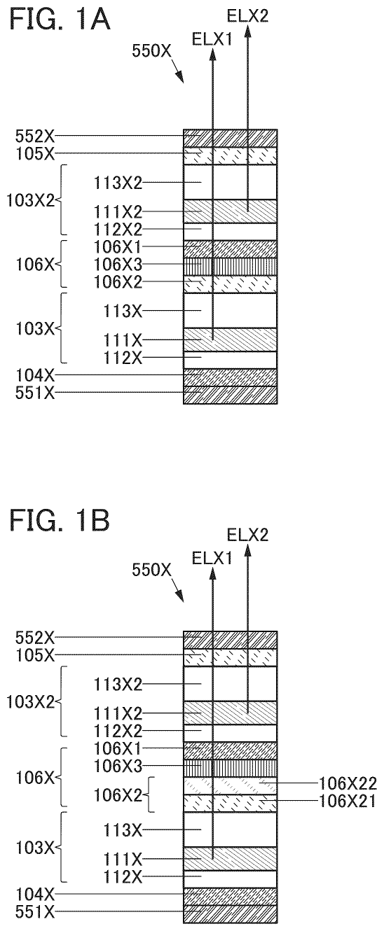

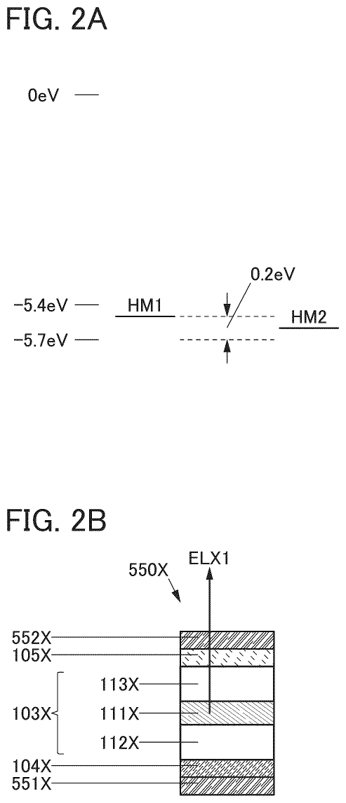

The mixed material can be suitably used for the layer 113X in combination with a structure using a composite material, which is described later, for the layer 104X. For example, a composite material of a substance having an electron-accepting property and a material having a hole-transport property can be used for the layer 104X. Specifically, a composite material of a substance having an electron-accepting property and a substance having a relatively deep HOMO level HM1, which is greater than or equal to −5.7 eV and lower than or equal to −5.4 eV, can be used for the layer 104X (see FIG. 2A). Using the mixed material for the layer 113X in combination with the structure using such a composite material for the layer 104X, whereby the reliability of the light-emitting device can be improved.

Furthermore, a structure using a material having a hole-transport property for the layer 112X is preferably combined with the structure using the mixed material for the layer 113X and the composite material for the layer 104X. For example, a substance having a HOMO level HM2, which is within the range of −0.2 eV to 0 eV from the relatively deep HOMO level HM1, can be used for the layer 112X (see FIG. 2A). As a result, the reliability of the light-emitting device can be increased. Note that in this specification and the like, the structure of the above light-emitting device is referred to as a Recombination-Site Tailoring Injection structure (ReSTI structure) in some cases.

The concentration of the alkali metal, the alkali metal compound, or the alkali metal complex preferably differs in the thickness direction of the layer 113X (including the case where the concentration is 0).

For example, a metal complex having an 8-hydroxyquinolinato structure can be used. A methyl-substituted product of the metal complex having an 8-hydroxyquinolinato structure (e.g., a 2-methyl-substituted product or a 5-methyl-substituted product) or the like can also be used.

As the metal complex having an 8-hydroxyquinolinato structure, 8-hydroxyquinolinato-lithium (abbreviation: Liq), 8-hydroxyquinolinato-sodium (abbreviation: Naq), or the like can be used. In particular, a complex of a monovalent metal ion, especially a complex of lithium is preferable, and Liq is further preferable.

### Structure Example 1 of Layer 111X>>

A light-emitting material or a light-emitting material and a host material can be used for the layer 111X, for example. The layer 111X can be referred to as a light-emitting layer. The layer 111X is preferably provided in a region where holes and electrons are recombined. In that case, energy generated by recombination of carriers can be efficiently converted into light and emitted.

Furthermore, the layer 111X is preferably provided apart from a metal used for the electrode or the like. In that case, a quenching phenomenon caused by the metal used for the electrode or the like can be inhibited.

It is preferable that a distance from an electrode or the like having a reflective property to the layer 111X be adjusted and the layer 111X be provided in an appropriate position in accordance with an emission wavelength. Thus, the amplitude can be increased by utilizing an interference phenomenon between light reflected by the electrode or the like and light emitted from the layer 111X. Light of a predetermined wavelength can be intensified and the spectrum of the light can be narrowed. In addition, bright light emission colors with high intensity can be obtained. In other words, the layer 111X is provided in an appropriate position, for example, between electrodes and the like, and thus a microcavity structure (microcavity) can be formed.

For example, a fluorescent substance, a phosphorescent substance, or a substance exhibiting thermally activated delayed fluorescence (TADF) (also referred to as a TADF material) can be used as the light-emitting material. Thus, energy generated by recombination of carriers can be released as the light ELX1 from the light-emitting material (see FIG. 1A).

### [Fluorescent Substance]

A fluorescent substance can be used for the layer 111X. For example, any of the following fluorescent substances can be used for the layer 11TX. Note that without being limited to the following ones, any of a variety of known fluorescent substances can be used for the layer 111X.

Specifically, it is possible to use, for example, 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis(N,N,N-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N,N-(pyrene-1,6-diyl)bis[(6,N-diphenylbenzo[b]naphtho[1,2-d]furan)-8-amine](abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), or 3,10-bis[N-(dibenzofuran-3-yl)-N-phenylamino]naphtho[2,3-b;6,7-b′]bisbenzofuran (abbreviation: 3,10FrA2Nbf(IV)-02).

Condensed aromatic diamine compounds typified by pyrenediamine compounds such as 1,6FLPAPrn, 1,6mMemFLPAPrn, and 1,6BnfAPm-03 are particularly preferable because of their high hole-trapping properties, high emission efficiency, or high reliability.

In addition, it is possible to use, for example, N-[4-(9,10-diphenyl-2-anthryl)phenyl]-N,N,N-triphenyl-1,4-phenylenediamine (abbreviation: 2DPAPPA), N,N,N,N,N′,N′,N″,N″-octaphenyldibenzo[g,p] chrysene-2,7,10,15-tetraamine (abbreviation: DBC1), coumarin 30, 9,10-diphenyl-2-[N-phenyl-N-(9-phenyl-carbazol-3-yl)-amino]-anthracene (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N,N-triphenyl-1,4-phenylenediamine (abbreviation: 2DPAPA), N-[9,10-bis(biphenyl-2-yl)-2-anthryl]-N,N,N-triphenyl-1,4-phenylenediamine (abbreviation: 2DPABPhA), 9,10-bis(biphenyl-2-yl)-N-[4-(9H-carbazol-9-yl)phenyl]-N-phenylanthracene-2-amine (abbreviation: 2YGABPhA), N,N,9-triphenylanthracene-9-amine (abbreviation: DPhAPhA), coumarin 545T, N,N-diphenylquinacridone (abbreviation: DPQd), rubrene, or 5,12-bis(1,1′-biphenyl-4-yl)-6,11-diphenyltetracene (abbreviation: BPT).

Furthermore, it is possible to use, for example, 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N,N-tetrakis(4-methylphenyl)tetracene-5,11-diamine (abbreviation: p-mPhTD), 7,14-diphenyl-N,N,N,N-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[iy]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), or 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM).

### [Phosphorescent Substance]

A phosphorescent substance can be used for the layer 111X. For example, any of the following phosphorescent substances can be used for the layer 111X. Note that without being limited to the following ones, any of a variety of known phosphorescent substances can be used for the layer 111X.

For the layer 111X, it is possible to use, for example, an organometallic iridium complex having a 4H-triazole skeleton, an organometallic iridium complex having a 1H-triazole skeleton, an organometallic iridium complex having an imidazole skeleton, an organometallic iridium complex having a phenylpyridine derivative with an electron-withdrawing group as a ligand, an organometallic iridium complex having a pyrimidine skeleton, an organometallic iridium complex having a pyrazine skeleton, an organometallic iridium complex having a pyridine skeleton, a rare earth metal complex, or a platinum complex.

### [Phosphorescent Substance (Blue)]

As the organometallic iridium complex having a 4H-triazole skeleton or the like, for example, tris{2-[5-(2-methylphenyl)-4-(2,6-dimethylphenyl)-4H-1,2,4-triazol-3-yl-κN2]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), or the like can be used.

As the organometallic iridium complex having a 1H-triazole skeleton or the like, for example, tris[3-methyl-1-(2-methylphenyl)-5-phenyl-1H-1,2,4-triazolato]iridium(III) (abbreviation: [Ir(Mptz1-mp)₃]), tris(1-methyl-5-phenyl-3-propyl-1H-1,2,4-triazolato}iridium(III) (abbreviation: [Ir(Prptzl-Me)₃]), or the like can be used.

As the organometallic iridium complex having an imidazole skeleton or the like, for example, fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), or the like can be used.

As the organometallic iridium complex having a phenylpyridine derivative with an electron-withdrawing group as a ligand, or the like, for example, bis[2-(4′,6′-difluorophenyl)pyridinato-N,C²′]iridium(III) tetrakis(1-pyrazolyl)borate (abbreviation: FIr6), bis[2-(4′,6′-difluorophenyl)pyridinato-N,C²′]iridium(III) picolinate (abbreviation: FIrpic), bis{2-[3′,5′-bis(trifluoromethyl)phenyl]pyridinato-N,C²′}iridium(III) picolinate (abbreviation: [Ir(CF₃ppy)₂(pic)]), bis[2-(4′,6′-difluorophenyl)pyridinato-N,C²′]iridium(III) acetylacetonate (abbreviation: FIracac), or the like can be used.

Note that these are compounds exhibiting blue phosphorescence and are compounds having an emission wavelength peak at 440 nm to 520 nm.

### [Phosphorescent Substance (Green)]

As the organometallic iridium complex having a pyrimidine skeleton or the like, it is possible to use, for example, tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis(4,6-diphenylpyrimidinato)iridium(III) (abbreviation: [Ir(dppm)₂(acac)]), or the like.

As the organometallic iridium complex having a pyrazine skeleton or the like, for example, (acetylacetonato)bis(3,5-dimethyl-2-phenylpyrazinato)iridium(III) (abbreviation: [Ir(mppr-Me)2(acac)]), (acetylacetonato)bis(5-isopropyl-3-methyl-2-phenylpyrazinato)iridium(III) (abbreviation: [Ir(mppr-iPr)₂(acac)]), or the like can be used.

As the organometallic iridium complex having a pyridine skeleton or the like, it is possible to use, for example, tris(2-phenylpyridinato-N,C²′)iridium(III) (abbreviation: [Ir(ppy)₃]), bis(2-phenylpyridinato-N,C²′)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), bis(2-phenylquinolinato-N,C²′)iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: [Ir(5mppy-d₃)₂(mbfpypy-d₃)]), [2-d3-methyl-(2-pyridinyl-κN)benzofuro[2,3-b]pyridine-κC]bis[2-(2-pyridinyl-KN)phenyl-κC]iridium(III) (abbreviation: [Ir(ppy)₂(mbfpypy-d₃)]), or the like.

An example of the rare earth metal complex is tris(acetylacetonato) (monophenanthroline)terbium(III) (abbreviation: [Tb(acac)₃(Phen)]).

Note that these are compounds mainly exhibiting green phosphorescence and have an emission wavelength peak at 500 nm to 600 nm. An organometallic iridium complex having a pyrimidine skeleton excels particularly in reliability or emission efficiency.

### [Phosphorescent Substance (Red)]

As the organometallic iridium complex having a pyrimidine skeleton or the like, for example, (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), bis[4,6-di(naphthalen-1-yl)pyrimidinato](dipivaloylmethanato)iridium(III) (abbreviation: [Ir(dlnpm)₂(dpm)]), or the like can be used.

As the organometallic iridium complex having a pyrazine skeleton or the like, for example, (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), (acetylacetonato)bis[2,3-bis(4-fluorophenyl)quinoxalinato]iridium(III) (abbreviation: [Ir(Fdpq)₂(acac)]), or the like can be used.

As the organometallic iridium complex having a pyridine skeleton or the like, for example, tris(1-phenylisoquinolinato-N,C²′)iridium(III) (abbreviation: [Ir(piq)₃]), bis(1-phenylisoquinolinato-N,C²′)iridium(III) acetylacetonate (abbreviation: [Ir(piq)₂(acac)]), or the like can be used.

As the rare earth metal complex or the like, for example, tris(1,3-diphenyl-1,3-propanedionato)(monophenanthroline)europium(III) (abbreviation: [Eu(DBM)₃(Phen)]), tris[1-(2-thenoyl)-3,3,3-trifluoroacetonato](monophenanthroline)europium(III) (abbreviation: [Eu(TTA)₃(Phen)]), or the like can be used.

As the platinum complex or the like, 2,3,7,8,12,13,17,18-octaethyl-21H,23H-porphyrin platinum(II) (abbreviation: PtOEP) or the like can be used.

Note that these are compounds exhibiting red phosphorescence and have an emission peak at 600 nm to 700 nm. Furthermore, from the organometallic iridium complex having a pyrazine skeleton, red light emission with chromaticity favorably used for display apparatuses can be obtained.

### [Substance Exhibiting Thermally Activated Delayed Fluorescence (TADF)]

A TADF material can be used for the layer 111X. When a TADF material is used as a light-emitting substance, the S1 level of the host material is preferably higher than that of the TADF material. In addition, the T1 level of the host material is preferably higher than that of the TADF material.

For example, any of the TADF materials given below can be used as the light-emitting material. Note that without being limited thereto, any of a variety of known TADF materials can be used.

In the TADF material, the difference between the S1 level and the T1 level is small, and reverse intersystem crossing (upconversion) from the triplet excited state into the singlet excited state can be achieved by a little thermal energy. Thus, the singlet excited state can be efficiently generated from the triplet excited state. In addition, the triplet excitation energy can be converted into light.

An exciplex whose excited state is formed of two kinds of substances has an extremely small difference between the S1 level and the T1 level and functions as a TADF material capable of converting triplet excitation energy into singlet excitation energy.

A phosphorescence spectrum observed at a low temperature (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between the S1 level and the T1 level of the TADF material is preferably smaller than or equal to 0.3 eV, further preferably smaller than or equal to 0.2 eV.

Examples of the TADF material include a fullerene, a derivative thereof, an acridine, a derivative thereof, and an eosin derivative. Furthermore, porphyrin containing a metal such as magnesium (Mg), zinc (Zn), cadmium (Cd), tin (Sn), platinum (Pt), indium (In), or palladium (Pd) can be also used for the TADF material.

Specifically, any of the following materials whose structural formulae are shown below can be used: a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), an octaethylporphyrin-platinum chloride complex (PtCl₂OEP), and the like.

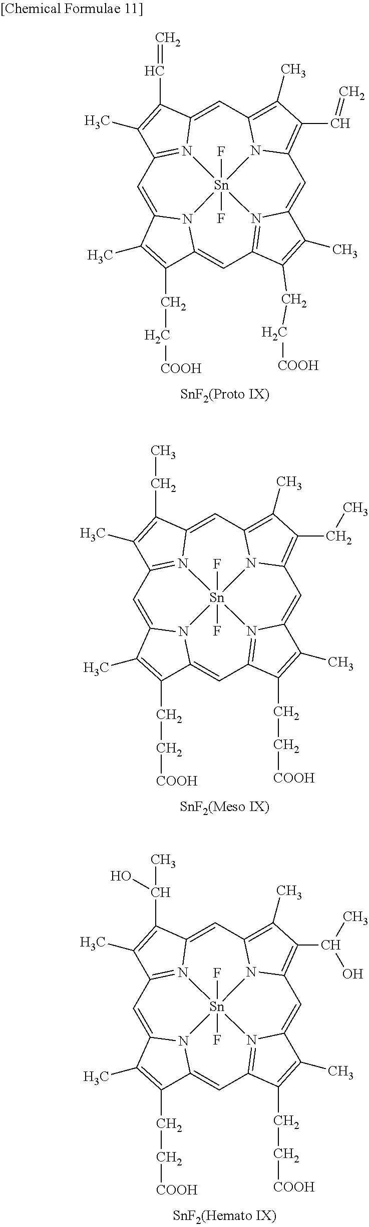

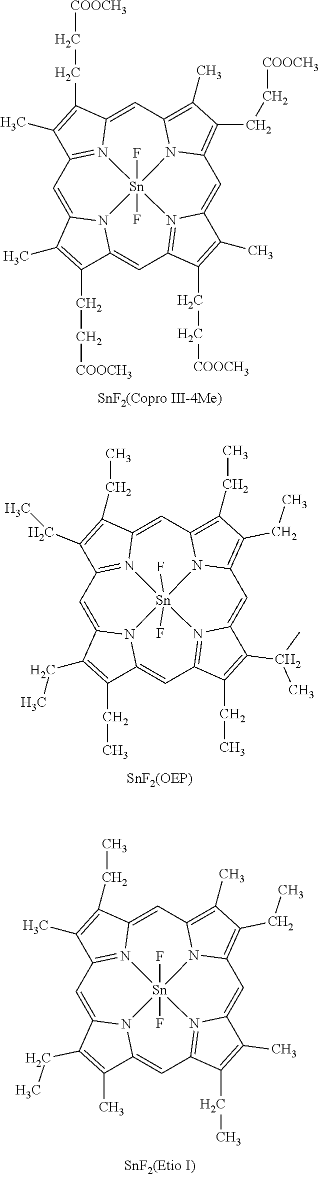

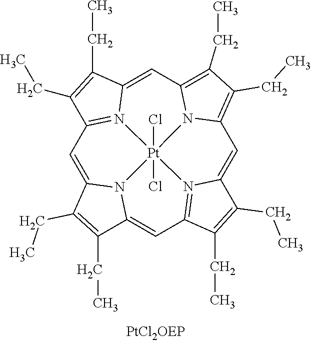

Furthermore, a heterocyclic compound including one or both of a 7t-electron rich heteroaromatic ring and a 7t-electron deficient heteroaromatic ring can be used for the TADF material, for example.

Specifically, any of the following materials whose structural formulae are shown below can be used: 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(1OH-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-1OH,10′H-spiro[acridin-9,9′-anthracen]-10′-one (abbreviation: ACRSA), and the like.

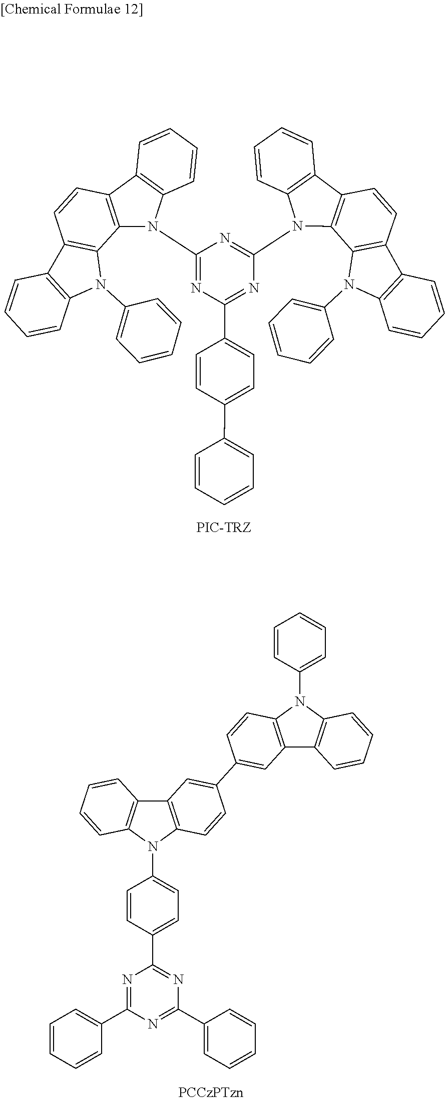 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

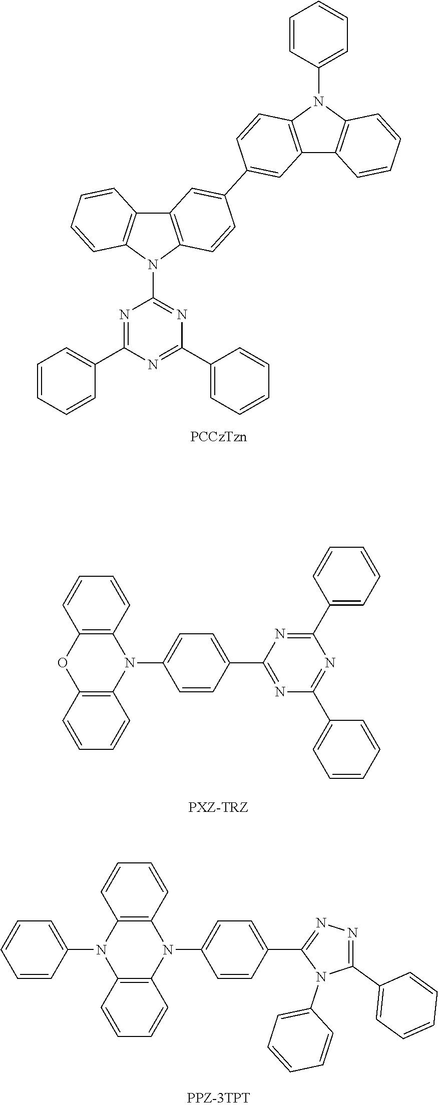 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1]

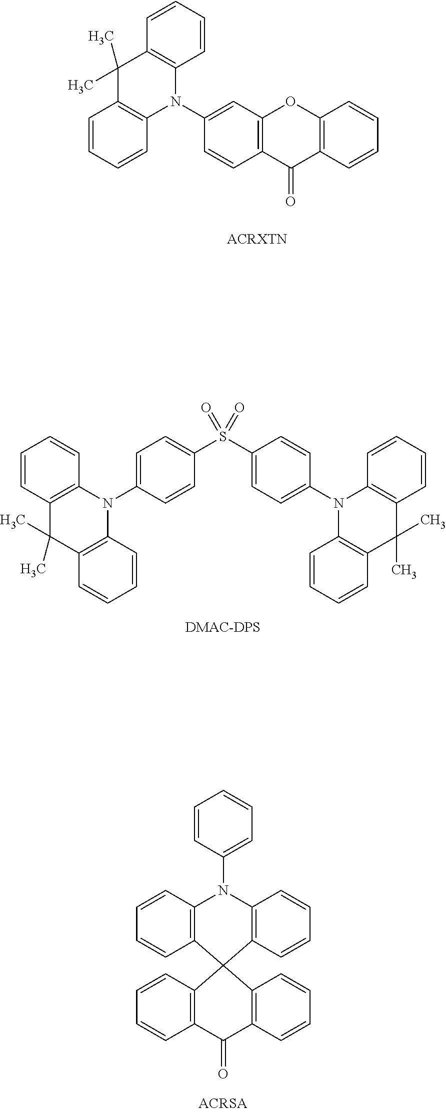 [SMILES: CC1(C)c2ccccc2N(c2ccc3c(=O)c4ccccc4oc3c2)c2ccccc21 ; CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Such a heterocyclic compound is preferable because of having a high electron-transport property and a high hole-transport property owing to a 7t-electron rich heteroaromatic ring and a π-electron deficient heteroaromatic ring. Among skeletons having the 7t-electron deficient heteroaromatic ring, in particular, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high electron-accepting properties and reliability.

Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable.

Note that a substance in which the π-electron rich heteroaromatic ring is directly bonded to the π-electron deficient heteroaromatic ring is particularly preferable because the electron-donating property of the π-electron rich heteroaromatic ring and the electron-accepting property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used.

As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring having a nitrile group or a cyano group such as benzonitrile or cyanobenzene, a carbonyl skeleton such as benzophenone, a phosphine oxide skeleton, a sulfone skeleton, or the like can be used.

As described above, a 7t-electron deficient skeleton and a π-electron rich skeleton can be used instead of at least one of the 7t-electron deficient heteroaromatic ring and the 7t-electron rich heteroaromatic ring.

### Structure Example 2 of Layer 111X>>

A material having a carrier-transport property can be used as the host material. For example, a material having a hole-transport property, a material having an electron-transport property, a substance exhibiting thermally activated delayed fluorescence (TADF), a material having an anthracene skeleton, or a mixed material can be used as the host material. A material having a wider band gap than the light-emitting material contained in the layer 111X is preferably used as the host material. In that case, energy transfer from excitons generated in the layer 111X to the host material can be inhibited.

[Material Having Hole-Transport Property]A material having a hole mobility higher than or equal to 1×10⁻⁶ cm²/Vs can be suitably used as the material having a hole-transport property. For example, the material having a hole-transport property that can be used for the layer 112X can be used as the host material.

### [Material Having Electron-Transport Property]

A metal complex or an organic compound having a π-electron deficient heteroaromatic ring skeleton can be used as the material having an electron-transport property. For example, the material having an electron-transport property that can be used for the layer 113X can be used as the host material.

### [Material Having Anthracene Skeleton]

An organic compound having an anthracene skeleton can be used as the host material. In particular, when a fluorescent substance is used as the light-emitting substance, an organic compound having an anthracene skeleton is suitable. In that case, a light-emitting device with high emission efficiency and high durability can be obtained.

As the organic compound having an anthracene skeleton, an organic compound having a diphenylanthracene skeleton, in particular, a 9,10-diphenylanthracene skeleton is chemically stable and thus is preferable. The host material preferably has a carbazole skeleton, in which case the hole-injection and hole-transport properties are improved. In particular, the host material preferably has a dibenzocarbazole skeleton, in which case the HOMO level thereof is shallower than that of carbazole by approximately 0.1 eV, so that holes enter the host material easily, the hole-transport property is improved, and the heat resistance is increased. Note that in terms of the hole-injection and hole-transport properties, a benzofluorene skeleton or a dibenzofluorene skeleton may be used instead of a carbazole skeleton.

Thus, a substance having both a 9,10-diphenylanthracene skeleton and a carbazole skeleton, a substance having both a 9,10-diphenylanthracene skeleton and a benzocarbazole skeleton, or a substance having both a 9,10-diphenylanthracene skeleton and a dibenzocarbazole skeleton is preferable as the host material.

For example, it is possible to use 6-[3-(9,10-diphenyl-2-anthryl)phenyl]-benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: aN-PNPAnth), 9-phenyl-3-[4-(10-phenyl-9-anthryl)phenyl]-9H-carbazole (abbreviation: PCzPA), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), or 3-[4-(1-naphthyl)-phenyl]-9-phenyl-9H-carbazole (abbreviation: PCPN).

In particular, CzPA, cgDBCzPA, 2mBnfPPA, and PCzPA have excellent characteristics.

### [Substance Exhibiting Thermally Activated Delayed Fluorescence (TADF)]

A TADF material can be used as the host material. When the TADF material is used as the host material, triplet excitation energy generated in the TADF material can be converted into singlet excitation energy by reverse intersystem crossing. Moreover, excitation energy can be transferred to the light-emitting substance. In other words, the TADF material functions as an energy donor, and the light-emitting substance functions as an energy acceptor. Thus, the emission efficiency of the light-emitting device can be increased.

This is very effective in the case where the light-emitting substance is a fluorescent substance. In that case, the S1 level of the TADF material is preferably higher than that of the fluorescent substance in order that high emission efficiency can be achieved. Furthermore, the T1 level of the TADF material is preferably higher than the S1 level of the fluorescent substance. Therefore, the T1 level of the TADF material is preferably higher than that of the fluorescent substance.

It is also preferable to use a TADF material that emits light whose wavelength overlaps with the wavelength on a lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protecting group around a luminophore (a skeleton which causes light emission) of the fluorescent substance. As the protecting group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protecting groups. The substituents having no π bond are poor in carrier-transport performance, whereby the TADF material and the luminophore of the fluorescent substance can be made away from each other with little influence on carrier transport or carrier recombination.

Here, the luminophore refers to an atomic group (skeleton) that causes light emission in a fluorescent substance. The luminophore is preferably a skeleton having a π bond, further preferably includes an aromatic ring, still further preferably includes a condensed aromatic ring or a condensed heteroaromatic ring.

Examples of the condensed aromatic ring or the condensed heteroaromatic ring include a phenanthrene skeleton, a stilbene skeleton, an acridone skeleton, a phenoxazine skeleton, and a phenothiazine skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

For example, the TADF material that can be used as the light-emitting material can be used as the host material.

### Structure Example 1 of Mixed Material

A material in which a plurality of kinds of substances are mixed can be used as the host material. For example, a material having an electron-transport property and a material having a hole-transport property can be used as the mixed material. The weight ratio between the material having a hole-transport property and the material having an electron-transport property contained in the mixed material may be (the material having a hole-transport property/the material having an electron-transport property)=( 1/19) or more and (19/1) or less. Accordingly, the carrier-transport property of the layer 111X can be easily adjusted. In addition, a recombination region can be controlled easily.

### Structure Example 2 of Mixed Material

A material mixed with a phosphorescent substance can be used as the host material. When a fluorescent substance is used as the light-emitting substance, a phosphorescent substance can be used as an energy donor for supplying excitation energy to the fluorescent substance.

### Structure Example 3 of Mixed Material

A mixed material containing a material to form an exciplex can be used as the host material. For example, a material forming an exciplex whose emission spectrum overlaps with the wavelength of the absorption band on the lowest energy side of the light-emitting substance can be used as the host material. This enables smooth energy transfer and improves emission efficiency. Alternatively, the driving voltage can be reduced. With such a structure, light emission can be efficiently obtained by ExTET (Exciplex-Triplet Energy Transfer), which is energy transfer from the exciplex to the light-emitting substance (phosphorescent material).

A phosphorescent substance can be used as at least one of the materials forming an exciplex. Accordingly, reverse intersystem crossing can be used. Alternatively, triplet excitation energy can be efficiently converted into singlet excitation energy.

A combination of materials forming an exciplex is preferably such that the HOMO level of a material having a hole-transport property is higher than or equal to the HOMO level of a material having an electron-transport property. Alternatively, the LUMO level of the material having a hole-transport property is preferably higher than or equal to the LUMO level of the material having an electron-transport property. In that case, an exciplex can be efficiently formed. Note that the LUMO levels and the HOMO levels of the materials can be derived from the electrochemical characteristics (the reduction potentials and the oxidation potentials). Specifically, the reduction potentials and the oxidation potentials can be measured by cyclic voltammetry (CV).

The formation of an exciplex can be confirmed by a phenomenon in which the emission spectrum of a mixed film in which the material having a hole-transport property and the material having an electron-transport property are mixed is shifted to a longer wavelength than the emission spectrum of each of the materials (or has another peak on the longer wavelength side) observed in comparison of the emission spectrum of the material having a hole-transport property, the emission spectrum of the material having an electron-transport property, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed in comparison of the transient PL of the material having a hole-transport property, the transient PL of the material having an electron-transport property, and the transient PL of the mixed film of these materials. The transient PL can be rephrased as transient electroluminescence (EL). That is, the formation of an exciplex can also be confirmed by a difference in transient response observed in comparison of the transient EL of the material having a hole-transport property, the transient EL of the material having an electron-transport property, and the transient EL of the mixed film of these materials.

### Structure Example 1 of Unit 103X2

The unit 103X2 includes a layer 111X2, a layer 112X2, and a layer 113X2. The layer 111X2 is sandwiched between the layer 112X2 and the layer 113X2.

The structure that can be used for the unit 103X can be used for the unit 103X2. For example, the same structure as the unit 103X can be used for the unit 103X2.

### Structure Example 2 of Unit 103X2

Alternatively, a structure different from that of the unit 103X can be used for the unit 103X2. For example, the structure emitting light whose hue is different from that of light emitted from the unit 103X can be used for the unit 103X2.

Specifically, a stack of the unit 103X that emits red light and green light and the unit 103X2 that emits blue light can be used. Accordingly, a light-emitting device that emits light of a desired color can be provided. For example, a light-emitting device that emits white light can be provided.

### <Method for Manufacturing Light-Emitting Device 550X>

For example, each layer of the electrode 551X, the electrode 552X, the unit 103X, the intermediate layer 106X, and the unit 103X2 can be formed by a dry process, a wet process, an evaporation method, a droplet discharge method, a coating method, a printing method, or the like. Different methods can be used to form the components.

Specifically, the light-emitting device 550X can be manufactured with a vacuum evaporation apparatus, an inkjet apparatus, a coating apparatus such as a spin coater, a gravure printing apparatus, an offset printing apparatus, a screen printing apparatus, or the like.

For example, the electrode can be formed by a wet process or a sol-gel method using a paste of a metal material. An indium oxide-zinc oxide film can be formed by a sputtering method using a target obtained by adding, to indium oxide, zinc oxide at higher than or equal to 1 wt % and lower than or equal to 20 wt %. An indium oxide film containing tungsten oxide and zinc oxide (IWZO) can be formed by a sputtering method using a target containing, with respect to indium oxide, tungsten oxide at higher than or equal to 0.5 wt % and lower than or equal to 5 wt % and zinc oxide at higher than or equal to 0.1 wt % and lower than or equal to 1 wt %.

Note that this embodiment can be combined with any of the other embodiments described in this specification as appropriate.

### Embodiment 3

In this embodiment, a structure of the light-emitting device 550X of one embodiment of the present invention will be described with reference to FIG. TA.

### Structure Example of Light-Emitting Device 550X

The light-emitting device 550X described in this embodiment includes the electrode 551X, the electrode 552X, the unit 103X, the unit 103X2, and the intermediate layer 106X (see FIG. 1A). For example, any of the structures described in Embodiment 1 and Embodiment 2 can be used for the unit 103X, the unit 103X2, and the intermediate layer 106X.

The light-emitting device 550X includes the layer 104X, and the layer 104X is sandwiched between the electrode 551X and the unit 103X.

### Structure Example of Electrode 551X

For example, a conductive material can be used for the electrode 551X. Specifically, a single layer or a stacked layer of a metal, an alloy, or a film containing a conductive compound can be used for the electrode 551X.

For example, a film that efficiently reflects light can be used for the electrode 551X. Specifically, an alloy containing silver, copper, and the like, an alloy containing silver, palladium, and the like, or a metal film of aluminum or the like can be used for the electrode 551X.

Alternatively, for example, a metal film that transmits part of light and reflects the other part of the light can be used as the electrode 551X. Thus, a microcavity structure (microcavity) can be provided in the light-emitting device 550X. Light of a predetermined wavelength can be extracted more efficiently than other light. Light with a narrow half width of a spectrum can be extracted. Light of a bright color can be extracted.

A film having a property of transmitting visible light can be used as the electrode 551X, for example. Specifically, a single layer or a stacked layer of a metal film, an alloy film, a conductive oxide film, or the like that is thin enough to transmit light can be used as the electrode 551X.

In particular, a material having a work function higher than or equal to 4.0 eV can be suitably used for the electrode 551X.

For example, a conductive oxide containing indium can be used. Specifically, indium oxide, indium oxide-tin oxide (abbreviation: ITO), indium oxide-tin oxide containing silicon or silicon oxide (abbreviation: ITSO), indium oxide-zinc oxide, indium oxide containing tungsten oxide and zinc oxide (abbreviation: IWZO), or the like can be used.

Furthermore, for example, a conductive oxide containing zinc can be used. Specifically, zinc oxide, zinc oxide to which gallium is added, zinc oxide to which aluminum is added, or the like can be used.

Furthermore, for example, gold (Au), platinum (Pt), nickel (Ni), tungsten (W), chromium (Cr), molybdenum (Mo), iron (Fe), cobalt (Co), copper (Cu), palladium (Pd), a nitride of a metal material (e.g., titanium nitride), or the like can be used. Alternatively, graphene can be used.

### Structure Example 1 of Layer 104X>>

A material having a hole-injection property can be used for the layer 104X. The layer 104X can be referred to as a hole-injection layer. This can facilitate injection of holes from the electrode 551X, for example. Alternatively, the driving voltage of the light-emitting device 550X can be lowered.

### [Substance Having Electron-Accepting Property]

An organic compound and an inorganic compound can be used as the substance having an electron-accepting property. The substance having an electron-accepting property can extract electrons from an adjacent hole-transport layer or an adjacent material having a hole-transport property by the application of an electric field. For example, the substance AM1 having an electron-accepting property that can be used for the layer 106X1 can be used for the layer 104X.

### Structure Example 1 of Composite Material

For example, a composite material containing a substance having an electron-accepting property and a material having a hole-transport property can be used for the layer 104X. Thus, not only a material having a high work function, but also a material having a low work function can be used for the electrode 551X. Alternatively, a material used for the electrode 551X can be selected from a wide range of materials regardless of its work function.

As the material having a hole-transport property in the composite material, for example, a compound having an aromatic amine skeleton, a carbazole derivative, an aromatic hydrocarbon, an aromatic hydrocarbon having a vinyl group, a high molecular compound (such as an oligomer, a dendrimer, or a polymer), or the like can be used. A material having a hole mobility of 1×10⁻⁶ 30 cm²/Vs or higher can be suitably used as the material having a hole-transport property in the composite material. For example, the material having a hole-transport property that can be used for the layer 112X can be used as the composite material.

A substance having a relatively deep HOMO level can be suitably used as the material having a hole-transport property in the composite material. Specifically, the HOMO level is preferably higher than or equal to −5.7 eV and lower than or equal to −5.4 eV. In that case, hole injection to the unit 103X can be facilitated. Alternatively, hole injection to the layer 112X can be facilitated. Alternatively, the reliability of the light-emitting device 550X can be increased. For example, the composite material that can be used for the layer 106X1 can be used for the layer 104X.

### Structure Example 2 of Composite Material

For example, a composite material containing a substance having an electron-accepting property, a material having a hole-transport property, and a fluoride of an alkali metal or a fluoride of an alkaline earth metal can be used as the material having a hole-injection property. In particular, a composite material in which the proportion of fluorine atoms is higher than or equal to 20% can be suitably used. Thus, the refractive index of the layer 104X can be reduced. Alternatively, a layer with a low refractive index can be formed inside the light-emitting device 550X. Alternatively, the external quantum efficiency of the light-emitting device 550X can be improved.

Note that this embodiment can be combined with any of the other embodiments described in this specification as appropriate.

### Embodiment 4

In this embodiment, a structure of the light-emitting device 550X of one embodiment of the present invention will be described with reference to FIG. 1 and FIG. 2.

### Structure Example 1 of Light-Emitting Device 550X

The light-emitting device 550X described in this embodiment includes the electrode 551X, the electrode 552X, the unit 103X, the unit 103X2, and the intermediate layer 106X (see FIG. 1A). For example, any of the structures described in Embodiment 1 and Embodiment 2 can be used for the unit 103X, the unit 103X2, and the intermediate layer 106X.

The light-emitting device 550X includes a layer 105X, and the layer 105X is sandwiched between the electrode 552X and the unit 103X2.

### Structure Example of Electrode 552X

A conductive material can be used for the electrode 552X, for example. Specifically, a single layer or a stacked layer of a metal, an alloy, or a material containing a conductive compound can be used for the electrode 552X.

For example, the material that can be used for the electrode 551X described in Embodiment 3 can be used for the electrode 552X. In particular, a material having a lower work function than the electrode 551X can be favorably used for the electrode 552X. Specifically, a material having a work function lower than or equal to 3.8 eV is preferable.

For example, an element belonging to Group 1 of the periodic table, an element belonging to Group 2 of the periodic table, a rare earth metal, or an alloy containing any of these elements can be used for the electrode 552X.

Specifically, lithium (Li), cesium (Cs), or the like; magnesium (Mg), calcium (Ca), strontium (Sr), or the like; europium (Eu), ytterbium (Yb), or the like; or an alloy containing any of these such as an alloy of magnesium and silver or an alloy of aluminum and lithium can be used for the electrode 552X.

### Structure Example 1 of Layer 105X>>

A material having an electron-injection property can be used for the layer 105X, for example. The layer 105X can be referred to as an electron-injection layer.

Specifically, a substance having an electron-donating property can be used for the layer 105X. Alternatively, a material in which a substance having an electron-donating property and a material having an electron-transport property are combined can be used for the layer 105X. Alternatively, electrode can be used for the layer 105X. This can facilitate injection of electrons from the electrode 552X, for example. Alternatively, besides a material having a low work function, a material having a high work function can also be used for the electrode 552X. Alternatively, a material used for the electrode 552X can be selected from a wide range of materials regardless of its work function. Specifically, Al, Ag, ITO, indium oxide-tin oxide containing silicon or silicon oxide, or the like can be used for the electrode 552X. Alternatively, the driving voltage of the light-emitting device 550X can be lowered.

### [Substance Having Electron-Donating Property]

For example, an alkali metal, an alkaline earth metal, a rare earth metal, or a compound thereof (an oxide, a halide, a carbonate, or the like) can be used as the substance having an electron-donating property. Alternatively, an organic compound such as tetrathianaphthacene (abbreviation: TTN), nickelocene, or decamethylnickelocene can be used as the substance having an electron-donating property.

As an alkali metal compound (including an oxide, a halide, and a carbonate), lithium oxide, lithium fluoride (LiF), cesium fluoride (CsF), lithium carbonate, cesium carbonate, 8-hydroxyquinolinato-lithium (abbreviation: Liq), or the like can be used.

As an alkaline earth metal compound (including an oxide, a halide, and a carbonate), calcium fluoride (CaF₂) or the like can be used.

### Structure Example 1 of Composite Material

A material in which a plurality of kinds of substances are combined can be used as the material having an electron-injection property. For example, a substance having an electron-donating property and a material having an electron-transport property can be used as the composite material.

### [Material Having Electron-Transport Property]

For example, a material having an electron mobility higher than or equal to 1×10⁻⁷ cm²/Vs and lower than or equal to 5×10⁵ cm²/Vs in a condition where the square root of the electric field strength [V/cm] is 600 can be favorably used as the material having an electron-transport property. Accordingly, the amount of electrons injected into the light-emitting layer can be controlled. Alternatively, the light-emitting layer can be prevented from having excess electrons.

A metal complex or an organic compound having a π-electron deficient heteroaromatic ring skeleton can be used as the material having an electron-transport property. For example, the material having an electron-transport property that can be used for the layer 113X can be used for the layer 105X.

### Structure Example 2 of Composite Material

A material including a fluoride of an alkali metal in a microcrystalline state and a material having an electron-transport property can be used as the composite material. Alternatively, a material including a fluoride of an alkaline earth metal in a microcrystalline state and a material having an electron-transport property can be used as the composite material. In particular, a composite material including a fluoride of an alkali metal or a fluoride of an alkaline earth metal at higher than or equal to 50 wt % can be suitably used. Alternatively, a composite material including an organic compound having a bipyridine skeleton can be suitably used. In that case, the refractive index of the layer 105X can be reduced. Alternatively, the external quantum efficiency of the light-emitting device 550X can be improved.

### Structure Example 3 of Composite Material

For example, a composite material containing a first organic compound having an unshared electron pair and a first metal can be used for the layer 105X. The sum of the number of electrons of the first organic compound and the number of electrons of the first metal is preferably an odd number. The molar ratio of the first metal to 1 mol of the first organic compound is preferably greater than or equal to 0.1 and less than or equal to 10, further preferably greater than or equal to 0.2 and less than or equal to 2, still further preferably greater than or equal to 0.2 and less than or equal to 0.8.

Accordingly, the first organic compound having an unshared electron pair interacts with the first metal and thus can form a singly occupied molecular orbital (SOMO). Furthermore, in the case where electrons are injected from the electrode 552X into the layer 105X, a barrier therebetween can be lowered.

For the layer 105X, a composite material that allows the spin density measured by an electron spin resonance method (ESR) to be preferably higher than or equal to 1×10¹⁶ spins/cm³, further preferably higher than or equal to 5×10¹⁶ spins/cm³, still further preferably higher than or equal to 1×10¹⁷ spins/cm³ can be used.

### [Organic Compound Having Unshared Electron Pair]

For example, a material having an electron-transport property can be used as the organic compound having an unshared electron pair. For example, a compound having an electron deficient heteroaromatic ring can be used. Specifically, a compound having at least one of a pyridine ring, a diazine ring (a pyrimidine ring, a pyrazine ring, and a pyridazine ring), and a triazine ring can be used. Accordingly, the driving voltage of the light-emitting device 550X can be lowered.

Note that the lowest unoccupied molecular orbital (LUMO) level of the organic compound having an unshared electron pair is preferably greater than or equal to −3.6 eV and less than or equal to −2.3 eV. In general, the HOMO level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), 2,2′-(1,3-phenylene)bis(9-phenyl-1,10-phenanthroline) (abbreviation: mPPhen2P), or the like can be used as the organic compound having an unshared electron pair. Note that NBPhen has a higher glass transition temperature (Tg) than BPhen and thus has high heat resistance.

Alternatively, for example, copper phthalocyanine can be used as the organic compound having an unshared electron pair. The number of electrons of the copper phthalocyanine is an odd number.

### [First Metal]

For example, when the number of electrons of the first organic compound having an unshared electron pair is an even number, a composite material of the first metal that belongs to an odd-numbered group in the periodic table and the first organic compound can be used for the layer 105X.

For example, manganese (Mn), which is a metal belonging to Group 7, cobalt (Co), which is a metal belonging to Group 9, copper (Cu), silver (Ag), and gold (Au), which are metals belonging to Group 11, and aluminum (Al) and indium (In), which are metals belonging to Group 13, are odd-numbered groups in the periodic table. Note that elements belonging to Group 11 have a lower melting point than elements belonging to Group 7 or Group 9 and thus are suitable for vacuum evaporation. In particular, Ag is preferable because of its low melting point. By using a metal having a low reactivity with water or oxygen as the first metal, the moisture resistance of the light-emitting device 550X can be improved.

The use of Ag for the electrode 552X and the layer 105X can increase the adhesion between the layer 105X and the electrode 552X.

When the number of electrons of the first organic compound having an unshared electron pair is an odd number, a composite material of the first metal that belongs to an even-numbered group in the periodic table and the first organic compound can be used for the layer 105X. For example, iron (Fe), which is a metal belonging to Group 8, is an element belonging to an even-numbered group in the periodic table.

### [Electride]

For example, a substance obtained by adding electrons at high concentration to an oxide where calcium and aluminum are mixed, or the like can be used as the material having an electron-injection property.

### Structure Example 4 of Composite Material

A material in which a plurality of kinds of substances are combined can be used as the material having an electron-injection property. For example, the structure that can be used for the layer 106X2 described in Embodiment 1 can be used for the layer 105X.

### Structure Example 2 of Light-Emitting Device 550X

The light-emitting device 550X described in this embodiment includes the electrode 551X, the electrode 552X, and the unit 103X (see FIG. 2B). The unit 103X is sandwiched between the electrode 551X and the electrode 552X. The light-emitting device 550X includes the layer 104X and the layer 105X, the layer 104X is sandwiched between the electrode 551X and the unit 103X, and the layer 105X is sandwiched between the electrode 552X and the unit 103X. Note that the light-emitting device 550X of one embodiment of the present invention described with reference to FIG. 2B does not include the intermediate layer 106X and the unit 103X2.

For example, the structure described in Embodiment 2 can be used for the unit 103X. Furthermore, the structure described in Embodiment 3 can be used for the electrode 551X and the layer 104X.

### Structure Example 4 of Layer 105X>>

A material having an electron-injection property can be used for the layer 105X. For example, the structure that can be used for the layer 106X2 described in Embodiment 1 can be used for the layer 105X.

Note that this embodiment can be combined with any of the other embodiments described in this specification as appropriate.

### Embodiment 5

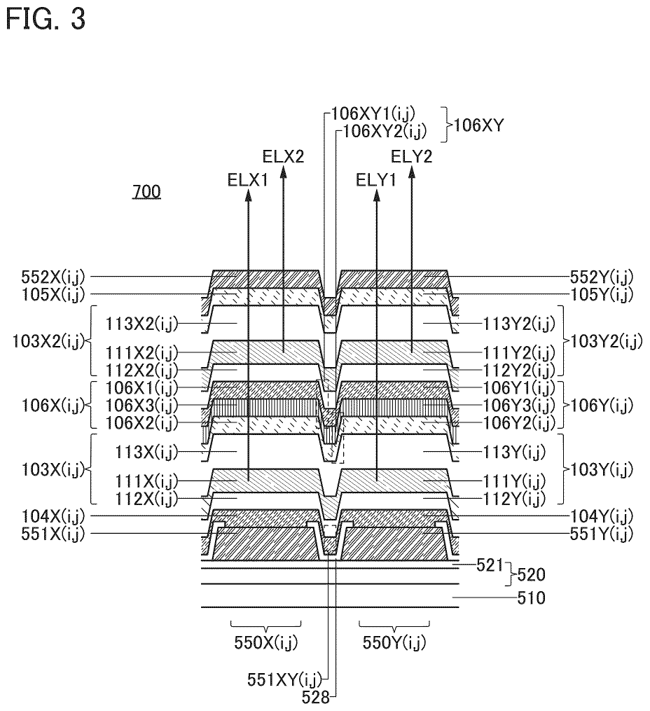

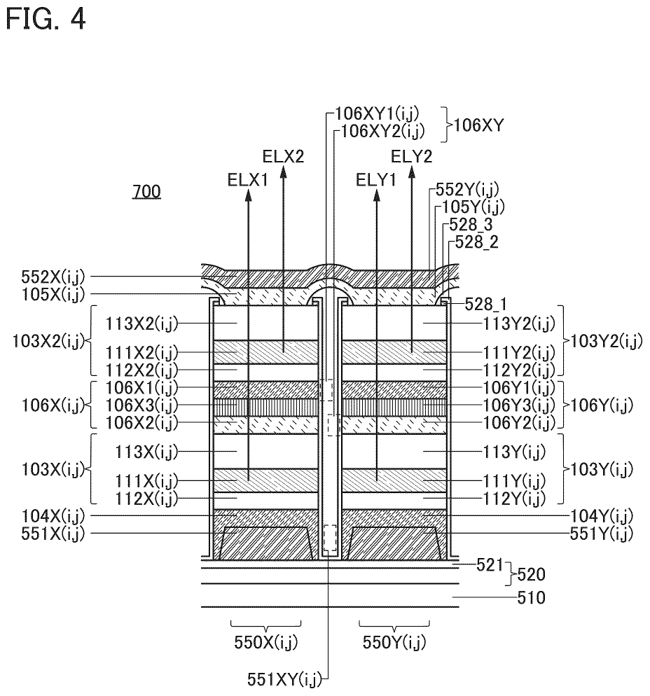

In this embodiment, a structure of a display apparatus 700 of one embodiment of the present invention will be described with reference to FIG. 3 and FIG. 4.

FIG. 3 is a cross-sectional view illustrating the structure of the display apparatus 700 of one embodiment of the present invention. FIG. 4 is a cross-sectional view illustrating a structure of the display apparatus 700 of one embodiment of the present invention different from the structure described with reference to FIG. 3.

In this specification and the like, a device manufactured using a metal mask or an FMM (fine metal mask, high-resolution metal mask) may be referred to as a device having an MM (metal mask) structure. In addition, in this specification and the like, a device manufactured without using a metal mask or an FMM is sometimes referred to as a device having an MML (metal maskless) structure.

By a formation method using a fine metal mask, it is difficult to set the distance between adjacent light-emitting devices to be less than 10 m, for example. By a formation method using a photolithography method over a glass substrate, the distance between adjacent light-emitting devices can be shortened to less than 10 m, less than or equal to 5 m, less than or equal to 3 m, less than or equal to 2 m, less than or equal to 1.5 m, less than or equal to 1 m, or even less than or equal to 0.5 m, for example. By a formation method using a photolithography method over a silicon wafer, the distance between adjacent light-emitting devices can be shortened to less than or equal to 500 nm, less than or equal to 200 nm, less than or equal to 100 nm, or even less than or equal to 50 nm with use of an exposure apparatus for LSI, for example.

Accordingly, the area of a non-light-emitting region that exists between adjacent light-emitting devices can be significantly reduced. Furthermore, the aperture ratio can be close to 100%. For example, the display apparatus of one embodiment of the present invention can have an aperture ratio higher than or equal to 40%, higher than or equal to 50%, higher than or equal to 60%, higher than or equal to 70%, higher than or equal to 80%, or higher than or equal to 900%, and lower than 100%.

### Structure Example 1 of Display Apparatus 700

The display apparatus 700 described in this embodiment includes the light-emitting device 550X(ij) and a light-emitting device 550Y(ij) (see FIG. 3).

The display apparatus 700 includes a substrate 510 and a functional layer 520. The functional layer 520 includes an insulating film 521, and the light-emitting device 550X(ij) and the light-emitting device 550Y(ij) are formed over the insulating film 521. The functional layer 520 is sandwiched between the substrate 510 and the light-emitting device 550X(ij).

### Structure Example of Light-Emitting Device 550X(Ij)

The light-emitting device 550X(ij) includes the electrode 551X(ij), the electrode 552X(ij), the unit 103X(ij), the unit 103X2(ij), and the intermediate layer 106X(ij). The light-emitting device 550X(ij) includes the layer 104X(ij) and the layer 105X(ij).

For example, the light-emitting device 550X described in Embodiment 1 to Embodiment 4 can be used as the light-emitting device 550X(ij). Specifically, the structure that can be used for the electrode 551X can be used for the electrode 551X(ij), and the structure that can be used for the electrode 552X can be used for the electrode 552X(ij). The structure that can be used for the unit 103X can be used for the unit 103X(ij), and the structure that can be used for the unit 103X2 can be used for the unit 103X2(ij). The structure that can be used for the intermediate layer 106X can be used for the intermediate layer 106X(ij). The structure that can be used for the layer 104X can be used for the layer 104X(ij), and the structure that can be used for the layer 105X can be used for the layer 105X(ij).

### Structure Example of Light-Emitting Device 550Y(Ij)

The light-emitting device 550Y(ij) is adjacent to the light-emitting device 550X(ij). The light-emitting device 550Y(ij) includes an electrode 551Y(ij), an electrode 552Y(ij), a unit 103Y(ij), a unit 103Y2(ij), and an intermediate layer 106Y(ij). The light-emitting device 550Y(ij) includes a layer 104Y(ij) and a layer 105Y(ij).

The electrode 551Y(ij) is adjacent to the electrode 551X(ij), and a gap 551XY(ij) is included between the electrode 551X(ij) and the electrode 551Y(ij). The potential supplied to the electrode 551Y(ij) may be the same as or different from the potential supplied to the electrode 551X(ij). By supplying a different potential, the light-emitting device 550Y(ij) can be driven under conditions different from those for the light-emitting device 550X(ij).

The electrode 552Y(ij) overlaps with the electrode 551Y(ij).

The unit 103Y(ij) is sandwiched between the electrode 551Y(ij) and the electrode 552Y(ij), and the unit 103Y2(ij) is sandwiched between the electrode 552Y(ij) and the unit 103Y(ij). The intermediate layer 106Y(ij) is sandwiched between the unit 103Y2(ij) and the unit 103Y(ij), and a region 106XY is included between the intermediate layer 106Y(ij) and the intermediate layer 106X(ij). The intermediate layer 106X(ij) and the intermediate layer 106Y(ij) are separated from each other by the region 106XY, and the region 106XY overlaps with the gap 551XY(ij). Note that the unit 103Y(ij) includes a layer 111Y(ij), a layer 112Y(ij), and a layer 113Y(ij). The unit 103Y2(ij) includes a layer 111Y2(ij), a layer 112Y2(ij), and a layer 113Y2(ij).

The layer 104Y(ij) is sandwiched between the unit 103Y(ij) and the electrode 551Y(ij), and the layer 105Y(ij) is sandwiched between the electrode 552Y(ij) and the unit 103Y2(ij).

For example, the structure of the light-emitting device 550X described in Embodiment 1 to Embodiment 4 can be used for the light-emitting device 550Y(ij). Specifically, the structure that can be used for the electrode 551X can be used for the electrode 551Y(ij), and the structure that can be used for the electrode 552X can be used for the electrode 552Y(ij). The structure that can be used for the unit 103X can be used for the unit 103Y(ij), and the structure that can be used for the unit 103X2 can be used for the unit 103Y2(ij). The structure that can be used for the intermediate layer 106X can be used for the intermediate layer 106Y(ij). The structure that can be used for the layer 104X can be used for the layer 104Y(ij), and the structure that can be used for the layer 105X can be used for the layer 105Y(ij).

Note that some of the components of the light-emitting device 550X(ij) can be used as some of the components of the light-emitting device 550Y(ij). For example, part of a conductive film that can be used for the electrode 552X(ij) can be used for the electrode 552Y(ij). Thus, some of the components can be used in common. Alternatively, the manufacturing process can be simplified.

A structure emitting light whose hue is different from that of light emitted from the light-emitting device 550X(ij) can be used for the light-emitting device 550Y(ij). For example, the hue of light ELY1 emitted from the unit 103Y(ij) can be different from that of the light ELX1. Furthermore, the hue of light ELY2 emitted from the unit 103Y2(ij) can be different from that of the light ELX2.

Moreover, a structure emitting light whose hue is the same as light emitted from the light-emitting device 550X(ij) can be used for the light-emitting device 550Y(ij).

For example, both the light-emitting device 550X(ij) and the light-emitting device 550Y(ij) may emit white light. A coloring layer is provided to overlap with the light-emitting device 550X(ij), whereby light of a predetermined hue can be extracted from white light. Another coloring layer is provided to overlap with the light-emitting device 550Y(ij), whereby light of another predetermined hue can be extracted from white light.

For example, both the light-emitting device 550X(ij) and the light-emitting device 550Y(ij) may emit blue light. Note that a color conversion layer is provided to overlap with the light-emitting device 550X(ij), whereby blue light can be converted into light of a predetermined hue. Another color conversion layer is provided to overlap with the light-emitting device 550Y(ij), whereby blue light can be converted into light of another predetermined hue. Blue light can be converted into green light or red light, for example.

### Structure Example 2 of Display Apparatus 700

The display apparatus 700 described in this embodiment includes an insulating film 528 (see FIG. 3).

### Structure Example of Insulating Film 528

The insulating film 528 has opening portions; one opening portion overlaps with the electrode 551X(ij) and the other opening portion overlaps with the electrode 551Y(ij). The insulating film 528 overlaps with the gap 551XY(ij).

### Structure Example of Gap 551XY(Ij)

The gap 551XY(ij) sandwiched between the electrode 551X(ij) and the electrode 551Y(ij) has a groove-like shape, for example. Thus, a step is formed along the groove. A split portion or a portion with a small film thickness is formed between a film deposited over the gap 551XY(ij) and a film deposited over the electrode 551X(ij).

For example, when an anisotropic deposition method such as a heating evaporation method is used, a split portion or a portion with a small film thickness is formed in a region 106XY1(ij) sandwiched between the layer 106X1(ij) and the layer 106Y1(ij) along the step. A split portion or a portion with a small film thickness is further formed in a region 106XY2(ij) sandwiched between the layer 106X2(ij) and the layer 106Y2(ij).

Thus, current flowing through the region 106XY can be reduced. For example, current flowing through the region 106XY1(ij) can be reduced. Moreover, current flowing between the intermediate layer 106X(ij) and the intermediate layer 106Y(ij) can be reduced. Furthermore, a phenomenon in which the light-emitting device 550Y(ij) that is adjacent to the light-emitting device 550X(ij) unintentionally emits light in accordance with the operation of the light-emitting device 550X(ij) can be inhibited.

### Structure Example 3 of Display Apparatus 700

The display apparatus 700 described in this embodiment includes the light-emitting device 550X(ij) and the light-emitting device 550Y(ij) (see FIG. 4). The light-emitting device 550Y(ij) is adjacent to the light-emitting device 550X(ij).

The display apparatus 700 is different from the display apparatus 700 described with reference to FIG. 3 in that part or all of the structures of the light-emitting device 550X(ij) or the light-emitting device 550Y(ij) is removed in a portion overlapping with the gap 551XY(ij), and an insulating film 5281, an insulating film 528_2, and an insulating film 528_3 are included instead of the insulating film 528. Different portions will be described in detail below, and the above description is referred to for portions having the same structure as the above.

### Structure Example of Insulating Film 528_1

The insulating film 528_1 has opening portions; one opening portion overlaps with the electrode 551X(ij) and the other opening portion overlaps with the electrode 551Y(ij) (see FIG. 4). The insulating film 528_1 includes an opening portion overlapping with the gap 551XY(ij).

### Structure Example of Insulating Film 528_2

The insulating film 528_2 has opening portions; one opening portion overlaps with the electrode 551X(ij) and the other opening portion overlaps with the electrode 551Y(ij). The insulating film 528_2 overlaps with the gap 551XY(ij).

The insulating film 528_2 includes a region in contact with the layer 104X(ij), the unit 103X(ij), the intermediate layer 106X(ij), and the unit 103X2(ij).

The insulating film 528_2 includes a region in contact with the layer 104Y(ij), the unit 103Y(ij), the intermediate layer 106Y(ij), and the unit 103Y2(ij).

The insulating film 528_2 includes a region in contact with the insulating film 521.

### Structure Example of Insulating Film 528_3

The insulating film 528_3 has opening portions; one opening portion overlaps with the electrode 551X(ij) and the other opening portion overlaps with the electrode 551Y(ij). The insulating film 528_3 fills the groove formed in a region overlapping with the gap 551XY(ij).

Accordingly, the intermediate layer 106X(ij) can be electrically isolated from the intermediate layer 106Y(ij), for example. Current flowing through the region 106XY can be reduced. For example, current flowing through the region 106XY1(ij) can be reduced. Furthermore, a phenomenon in which the light-emitting device 550Y(ij) that is adjacent to the light-emitting device 550X(ij) unintentionally emits light in accordance with the operation of the light-emitting device 550X(ij) can be inhibited. The size of a step generated between the top surface of the unit 103X2(ij) and the top surface of the unit 103Y2(ij) can be reduced. Occurrence of a phenomenon in which a split portion or a portion with a small film thickness due to the step is formed between the electrode 552X(ij) and the electrode 552Y(ij) can be inhibited. One conductive film can be used for the electrode 552X(ij) and the electrode 552Y(ij).

For example, part or all of the components of the light-emitting device 550X(ij) or the light-emitting device 550Y(ij) can be removed from the portion overlapping with the gap 551XY(ij) by a photolithography method.

Specifically, in Step 1, a first insulating film to be the insulating film 528_1 later is formed over a film to be the unit 103Y2(ij) later.

In Step 2, an opening portion overlapping with the gap 551XY(ij) is formed in the first insulating film by a photolithography method.

In Step 3, part or all of the components of the light-emitting device 550Y(ij) is removed from the region overlapping with the gap 551XY(ij) using the insulating film as a resist. For example, a dry etching method can be used. Therefore, the groove is formed in the region overlapping with the gap 551XY(ij).

In Step 4, for example, a second insulating film to be the insulating film 528_2 is formed by an atomic layer deposition (ALD) method.

In Step 5, for example, the insulating film 528_3 is formed using a photosensitive polymer to fill the groove formed in the region overlapping with the gap 551XY(ij).

In Step 6, the opening portion overlapping with the electrode 551Y(ij) is formed by a photolithography method in the first insulating film and the second insulating film to form the insulating film 528_1 and the insulating film 528_2.

In Step 7, the layer 105Y(ij) and the electrode 552Y(ij) are consequently formed over the unit 103Y2(ij).

Note that this embodiment can be combined with any of the other embodiments described in this specification as appropriate.

### Embodiment 6

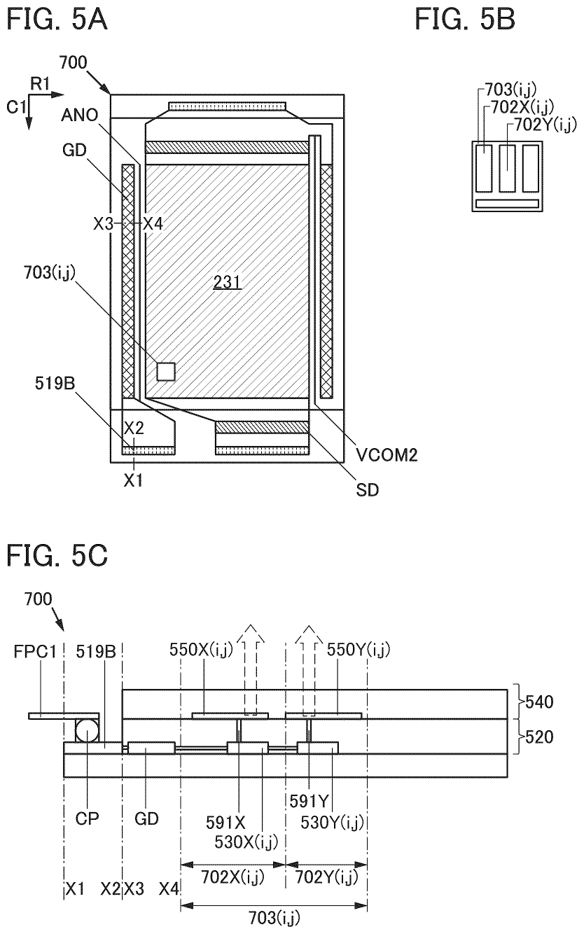

In this embodiment, a structure of an apparatus of one embodiment of the present invention will be described with reference to FIG. 5 to FIG. 7.

FIG. 5 is a diagram illustrating a structure of an apparatus of one embodiment of the present invention. FIG. 5A is a top view of the apparatus of one embodiment of the present invention, and FIG. 5B is a top view illustrating part of FIG. 5A. FIG. 5C is a cross-sectional view taken along a cutting line X1-X2, a cutting line X3-X4, and a pixel set 703(ij) in FIG. 5A.

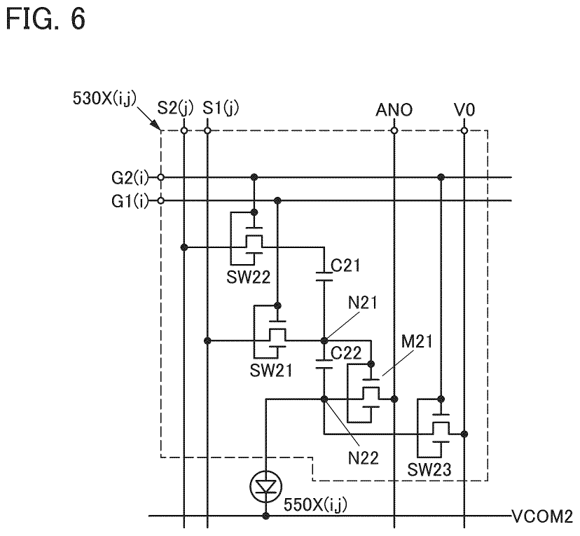

FIG. 6 is a circuit diagram illustrating a structure of an apparatus of one embodiment of the present invention.

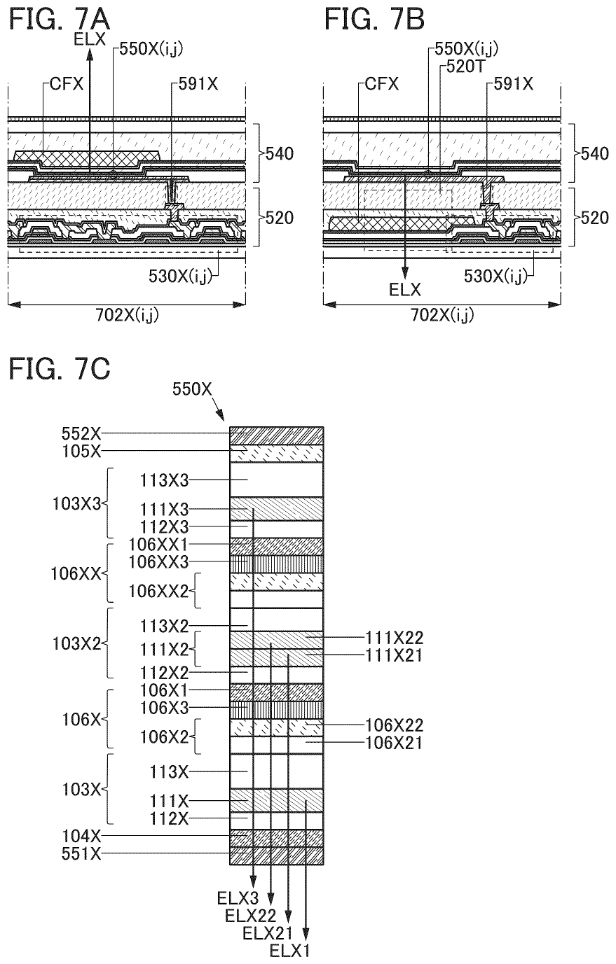

FIG. 7 is a diagram illustrating a structure of an apparatus of one embodiment of the present invention. FIG. 7A is a cross-sectional view of the apparatus of one embodiment of the present invention, and FIG. 7B is a cross-sectional view of the apparatus of one embodiment of the present invention having a structure different from the structure described with reference to FIG. 7A. FIG. 7C is a cross-sectional view of a light-emitting device that can be used for the apparatus illustrated in FIG. 7B.

Note that in this specification, an integer variable of 1 or more is sometimes used in reference numerals. For example, (p) where p is an integer variable of 1 or more is sometimes used in part of a reference numeral that specifies any of p components at a maximum. As another example, (m, n) where m and n are each an integer variable of 1 or more is sometimes used in part of a reference numeral that specifies any of m×n components at a maximum.

### Structure Example 1 of Display Apparatus 700

The display apparatus 700 of one embodiment of the present invention includes a region 231 (see FIG. 5A). The region 231 includes the pixel set 703(ij).

### Structure Example of Pixel Set 703(Ij)>>

The pixel set 703(ij) includes a pixel 702X(ij) (see FIG. 5B and FIG. 5C).

The pixel 702X(ij) includes a pixel circuit 530X(ij) and the light-emitting device 550X(ij). The light-emitting device 550X(ij) is electrically connected to the pixel circuit 530X(ij).

### Structure Example 1 of Light-Emitting Device

For example, the light-emitting device described in any of Embodiment 1 to Embodiment 4 can be used as the light-emitting device 550X(ij). The display apparatus 700 has a function of displaying an image.

### Structure Example 2 of Display Apparatus 700

The display apparatus 700 of one embodiment of the present invention includes a functional layer 540 and the functional layer 520 (see FIG. 5C). The functional layer 540 overlaps with the functional layer 520.

The functional layer 540 includes the light-emitting device 550X(ij).

The functional layer 520 includes the pixel circuit 530X(ij) and wirings (see FIG. 5C). The pixel circuit 530X(ij) is electrically connected to the wiring. For example, a conductive film provided in an opening portion 591X or an opening portion 591Y in the functional layer 520 can be used for the wiring. The wiring electrically connects a terminal 519B to the pixel circuit 530X(ij). Note that a conductive material CP electrically connects the terminal 519B to a flexible printed circuit FPC1.

### Structure Example 3 of Display Apparatus 700

The display apparatus 700 of one embodiment of the present invention includes a driver circuit GD and a driver circuit SD (see FIG. 5A).

### Structure Example of Driver Circuit GD

The driver circuit GD supplies a first selection signal and a second selection signal.

Structure example of driver circuit SD The driver circuit SD supplies a first control signal and a second control signal.

### Structure Example of Wiring

As wirings, a conductive film G1(i), a conductive film G2(i), a conductive film S1(i), a conductive film S2(j), a conductive film ANO, a conductive film VCOM2, and a conductive film V0 are included (see FIG. 6).

The conductive film G1(i) is supplied with the first selection signal, and the conductive film G2(i) is supplied with the second selection signal.

The conductive film S1(j) is supplied with the first control signal, and the conductive film S2(j) is supplied with the second control signal.

### Structure Example 1 of Pixel Circuit 530X(Ij)

The pixel circuit 530X(ij) is electrically connected to the conductive film G1(i) and the conductive film S1(j). The conductive film G1 ( ) supplies the first selection signal, and the conductive film S1(j) supplies the first control signal.

The pixel circuit 530X(ij) drives the light-emitting device 550X(ij) based on the first selection signal and the first control signal. The light-emitting device 550X(ij) emits light.

One electrode of the light-emitting device 550X(ij) is electrically connected to the pixel circuit 530X(ij), and the other electrode of the light-emitting device 550X(ij) is electrically connected to the conductive film VCOM2.

### Structure Example 2 of Pixel Circuit 530X(Ij)

The pixel circuit 530X(ij) includes a switch SW21, a switch SW22, a transistor M21, a capacitor C21, and a node N21.

The transistor M21 includes a gate electrode electrically connected to the node N21, a first electrode electrically connected to the light-emitting device 550X(ij), and a second electrode electrically connected to the conductive film ANO.

The switch SW21 includes a first terminal electrically connected to the node N21, a second terminal electrically connected to the conductive film S1(j), and a gate electrode having a function of controlling the conduction state or the non-conduction state based on the potential of the conductive film G1(i).

The switch SW22 includes a first terminal electrically connected to the conductive film S2(j) and a gate electrode having a function of controlling the conduction state or the non-conduction state based on the potential of the conductive film G2(i).

The capacitor C21 includes a conductive film electrically connected to the node N21 and a conductive film electrically connected to a second electrode of the switch SW22.

Thus, an image signal can be stored in the node N21. The potential of the node N21 can be changed using the switch SW22. Alternatively, the intensity of light emitted from the light-emitting device 550X(ij) can be controlled with the potential of the node N21. As a result, a novel apparatus that is highly convenient, useful, or reliable can be provided.

### Structure Example 3 of Pixel Circuit 530X(Ij)

The pixel circuit 530X(ij) includes a switch SW23, a node N22, and a capacitor C22.

The switch SW23 includes a first terminal electrically connected to the conductive film V0, a second terminal electrically connected to the node N22, and a gate electrode having a function of controlling the conduction state or the non-conduction state based on the potential of the conductive film G2(i).

The capacitor C22 includes a conductive film electrically connected to the node N21 and a conductive film electrically connected to the node N22.

Note that the first electrode of the transistor M21 is electrically connected to the node N22.

### Structure Example 1 of Pixel 702X(Ij)

The pixel 702X(ij) includes the light-emitting device 550X(ij) and the pixel circuit 530X(ij) (see FIG. 7A). The functional layer 540 includes the light-emitting device 550X(ij) and a coloring layer CFX, and the functional layer 520 includes the pixel circuit 530X(ij).

The light-emitting device 550X(ij) is a top-emission light-emitting device, and the light-emitting device 550X(ij) emits the light ELX to the side where the functional layer 520 is not provided.

The coloring layer CFX transmits part of light emitted from the light-emitting device 550X(ij). For example, the coloring layer CFX may transmit part of white light, so that blue light, green light, or red light can be extracted. Note that a color conversion layer can be used instead of the coloring layer CFX. Therefore, light with a short wavelength can be converted into light with a long wavelength.

### Structure Example 2 of Pixel 702X(Ij)

The pixel 702X(ij) described with reference to FIG. 7B includes a bottom-emission light-emitting device. The light-emitting device 550X(ij) emits the light ELX to the side where the functional layer 520 is provided.

The functional layer 520 includes a region 520T, and the region 520T transmits the light ELX. The functional layer 520 includes the coloring layer CFX, and the coloring layer CFX overlaps with the region 520T.

### Structure Example 2 of Light-Emitting Device

For example, a light-emitting device having the same structure as the light-emitting device 550X described with reference to FIG. 7C can be used as the light-emitting device 550X(ij).

The light-emitting device 550X described in this embodiment includes the electrode 551X, the electrode 552X, the unit 103X, the unit 103X2, a unit 103X3, the intermediate layer 106X, and an intermediate layer 106XX.

The unit 103X is sandwiched between the electrode 551X and the electrode 552X, the unit 103X2 is sandwiched between the electrode 552X and the unit 103X, and the unit 103X3 is sandwiched between the electrode 552X and the unit 103X2. The intermediate layer 106X is sandwiched between the unit 103X2 and the unit 103X, and the intermediate layer 106XX is sandwiched between the unit 103X3 and the unit 103X2.

The unit 103X has a function of emitting the light ELX1, the unit 103X2 has a function of emitting light ELX21 and light ELX22, and the unit 103X3 has a function of emitting light ELX3. The intermediate layer 106X has a function of supplying electrons to the unit 103X and supplying holes to the unit 103X2. The intermediate layer 106XX has a function of supplying electrons to the unit 103X2 and supplying holes to the unit 103X3.

Note that the structure that can be used for the light-emitting device 550X described in Embodiment 1 to Embodiment 4 can be used for the electrode 551X, the electrode 552X, the unit 103X, and the unit 103X2. The structure that can be used for the unit 103X can be used for the unit 103X3, and the structure that can be used for the intermediate layer 106X can be used for the intermediate layer 106XX. For example, a light-emitting material that emits blue light can be used for the layer 111X and a layer 111X3.

### Structure Example of Unit 103X2

For example, a layer 111X21 and a layer 111X22 can be used for the unit 103X2. The layer 111X21 and the layer 111X22 each contain alight-emitting material. For example, a light-emitting material that emits red light can be used for the layer 111X21. For example, a light-emitting material that emits yellow light can be used for the layer 111X22.

Note that this embodiment can be combined with any of the other embodiments described in this specification as appropriate.

### Embodiment 7

In this embodiment, a light-emitting apparatus that includes the light-emitting device described in any one of Embodiment 1 to Embodiment 4 will be described.

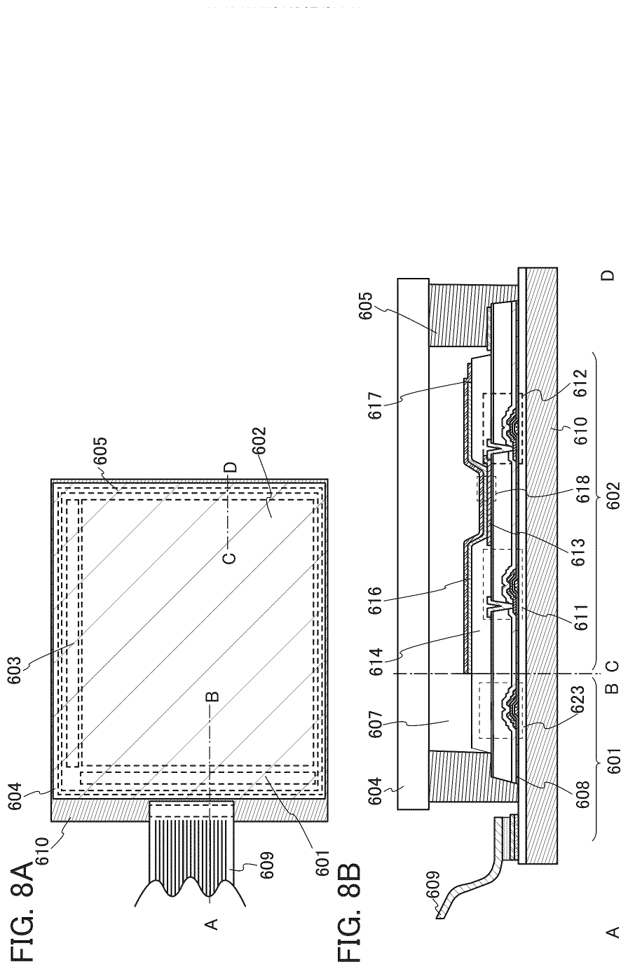

In this embodiment, a light-emitting apparatus manufactured using the light-emitting device described in any one of Embodiment 1 to Embodiment 4 is described with reference to FIG. 8. FIG. 8A is atop view illustrating the light-emitting apparatus, and FIG. 8B is a cross-sectional view taken along A-B and C-D in FIG. 8A. This light-emitting apparatus includes a pixel portion 602 and a driver circuit portion, which control light emission of the light-emitting devices, and the driver circuit portion includes a source line driver circuit 601 and a gate line driver circuit 603. The light-emitting apparatus is provided with a sealing substrate 604 and a sealant 605, and a space 607 is surrounded by the sealant 605.

A lead wiring 608 is a wiring for transmitting signals to be input to the source line driver circuit 601 and the gate line driver circuit 603 and receives a video signal, a clock signal, a start signal, a reset signal, or the like from an FPC (flexible printed circuit) serving as an external input terminal 609. Although only the FPC is illustrated here, a printed wiring board (PWB) may be attached to the FPC. The light-emitting apparatus in this specification includes, in its category, not only the light-emitting apparatus itself but also the light-emitting apparatus provided with the FPC or the PWB.

Next, a cross-sectional structure is described with reference to FIG. 8B. The driver circuit portions and the pixel portion are formed over an element substrate 610; here, the source line driver circuit 601, which is a driver circuit portion, and one pixel in the pixel portion 602 are illustrated.

The element substrate 610 may be formed using a substrate containing glass, quartz, an organic resin, a metal, an alloy, a semiconductor, or the like or a plastic substrate formed of FRP (Fiber Reinforced Plastics), PVF (polyvinyl fluoride), polyester, an acrylic resin, or the like.

There is no particular limitation on the structure of transistors used in pixels or driver circuits. For example, inverted staggered transistors may be used, or staggered transistors may be used. Furthermore, top-gate transistors or bottom-gate transistors may be used. A semiconductor material used for the transistors is not particularly limited, and for example, silicon, germanium, silicon carbide, gallium nitride, or the like can be used. Alternatively, an oxide semiconductor containing at least one of indium, gallium, and zinc, such as In—Ga—Zn-based metal oxide, may be used.

There is no particular limitation on the crystallinity of a semiconductor material used for the transistors, and an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case degradation of the transistor characteristics can be inhibited.

Here, an oxide semiconductor is preferably used for semiconductor devices such as the transistors provided in the pixels or the driver circuits and transistors used for after-mentioned touch sensors and the like. In particular, an oxide semiconductor having a wider band gap than silicon is preferably used. When an oxide semiconductor having a wider band gap than silicon is used, the off-state current of the transistors can be reduced.

The oxide semiconductor preferably contains at least indium (In) or zinc (Zn). Further preferably, the oxide semiconductor contains an oxide represented by In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and having no grain boundary between adjacent crystal parts.

The use of such materials for the semiconductor layer makes it possible to provide a highly reliable transistor in which a change in the electrical characteristics is inhibited.

Charge accumulated in a capacitor through a transistor including the above-described semiconductor layer can be held for a long time because of the low off-state current of the transistor. When such a transistor is used in a pixel, operation of a driver circuit can be stopped while a gray scale of an image displayed in each display region is maintained. As a result, an electronic device with extremely low power consumption can be obtained.

For stable characteristics or the like of the transistor, a base film is preferably provided. The base film can be formed to be a single layer or a stacked layer using an inorganic insulating film such as a silicon oxide film, a silicon nitride film, a silicon oxynitride film, or a silicon nitride oxide film. The base film can be formed by a sputtering method, a CVD (Chemical Vapor Deposition) method (e.g., a plasma CVD method, a thermal CVD method, or an MOCVD (Metal Organic CVD) method), an ALD (Atomic Layer Deposition) method, a coating method, a printing method, or the like. Note that the base film does not have to be provided if not necessary.

Note that an FET 623 is illustrated as a transistor formed in the source line driver circuit 601. The driver circuit is formed with any of a variety of circuits such as a CMOS circuit, a PMOS circuit, or an NMOS circuit. Although a driver-integrated type in which the driver circuit is formed over the substrate is described in this embodiment, the driver circuit is not necessarily formed over the substrate, and the driver circuit can be formed outside, not over the substrate.

The pixel portion 602 is formed with a plurality of pixels including a switching FET 611, a current control FET 612, and a first electrode 613 electrically connected to a drain of the current control FET 612; however, without being limited thereto, a pixel portion in which three or more FETs and a capacitor are combined may be employed.

Note that an insulator 614 is formed to cover an end portion of the first electrode 613. Here, the insulator 614 can be formed using a positive photosensitive acrylic resin film.

In order to improve the coverage with an EL layer or the like which is formed later, the insulator 614 is formed to have a curved surface with curvature at its upper end portion or lower end portion. For example, in the case where a positive photosensitive acrylic resin is used as a material for the insulator 614, only the upper end portion of the insulator 614 preferably has a curved surface with a curvature radius (greater than or equal to 0.2 m and less than or equal to 3 pm). As the insulator 614, either a negative photosensitive resin or a positive photosensitive resin can be used.

An EL layer 616 and a second electrode 617 are formed over the first electrode 613. Here, as a material used for the first electrode 613 functioning as an anode, a material having a high work function is desirably used. For example, a single-layer film of an ITO film, an indium tin oxide film containing silicon, an indium oxide film containing zinc oxide at higher than or equal to 2 wt % and lower than or equal to 20 wt %, a titanium nitride film, a chromium film, a tungsten film, a Zn film, a Pt film, or the like, a stacked layer of a titanium nitride film and a film containing aluminum as its main component, a three-layer structure of a titanium nitride film, a film containing aluminum as its main component, and a titanium nitride film, or the like can be used. The stacked-layer structure enables low wiring resistance, favorable ohmic contact, and a function as an anode.

The EL layer 616 is formed by any of a variety of methods such as an evaporation method using an evaporation mask, an inkjet method, and a spin coating method. The EL layer 616 has the structure described in any one of Embodiment 1 to Embodiment 4. As another material included in the EL layer 616, a low molecular compound or a high molecular compound (including an oligomer or a dendrimer) may be used.

As a material used for the second electrode 617, which is formed over the EL layer 616 and functions as a cathode, a material having a low work function (e.g., Al, Mg, Li, Ca, or an alloy or a compound thereof (MgAg, MgIn, AlLi, or the like)) is preferably used. Note that in the case where light generated in the EL layer 616 passes through the second electrode 617, it is preferable to use, for the second electrode 617, a stacked layer of a thin metal film with a reduced film thickness and a transparent conductive film (e.g., ITO, indium oxide containing zinc oxide at higher than or equal to 2 wt % and lower than or equal to 20 wt %, indium tin oxide containing silicon, or zinc oxide (ZnO)).

Note that a light-emitting device is formed with the first electrode 613, the EL layer 616, and the second electrode 617. The light-emitting device is the light-emitting device described in any one of Embodiment 1 to Embodiment 4. A plurality of light-emitting devices are formed in the pixel portion, and the light-emitting apparatus in this embodiment may include both the light-emitting device described in any one of Embodiment 1 to Embodiment 4 and a light-emitting device having a different structure.

Furthermore, the sealing substrate 604 is attached to the element substrate 610 with the sealant 605, so that a light-emitting device 618 is provided in the space 607 surrounded by the element substrate 610, the sealing substrate 604, and the sealant 605. The space 607 is filled with a filler; it is filled with an inert gas (e.g., nitrogen or argon) in some cases, and filled with the sealant in other cases. It is preferable that the sealing substrate have a recessed portion provided with a desiccant, in which case degradation due to the influence of moisture can be inhibited.

Note that an epoxy-based resin or glass frit is preferably used for the sealant 605. Furthermore, these materials are preferably materials that transmit moisture and oxygen as little as possible. As the material used for the sealing substrate 604, in addition to a glass substrate and a quartz substrate, a plastic substrate formed of FRP (Fiber Reinforced Plastics), PVF (polyvinyl fluoride), polyester, an acrylic resin, or the like can be used.

Although not illustrated in FIG. 8A or FIG. 8B, a protective film may be provided over the second electrode 617. The protective film is formed using an organic resin film or an inorganic insulating film. The protective film may be formed so as to cover an exposed portion of the sealant 605. The protective film can be provided to cover surfaces and side surfaces of the pair of substrates and exposed side surfaces of a sealing layer, an insulating layer, and the like.

The protective film can be formed using a material that does not easily transmit an impurity such as water. Thus, diffusion of an impurity such as water from the outside into the inside can be effectively inhibited.

As a material of the protective film, an oxide, a nitride, a fluoride, a sulfide, a ternary compound, a metal, a polymer, or the like can be used. For example, it is possible to use a material containing aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, or the like; a material containing aluminum nitride, hafnium nitride, silicon nitride, tantalum nitride, titanium nitride, niobium nitride, molybdenum nitride, zirconium nitride, gallium nitride, or the like; or a material containing a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

The protective film is preferably formed using a deposition method with favorable step coverage. One of such methods is an atomic layer deposition (ALD) method. A material that can be formed by an ALD method is preferably used for the protective film. With the use of an ALD method, a dense protective film with reduced defects such as cracks or pinholes or with a uniform thickness can be formed. Furthermore, damage caused to a process member in forming the protective film can be reduced.

By an ALD method, for example, a uniform protective film with few defects can be formed even on a surface with a complex uneven shape or upper, side, and lower surfaces of a touch panel.

As described above, the light-emitting apparatus manufactured using the light-emitting device described in any one of Embodiment 1 to Embodiment 4 can be obtained.

The light-emitting apparatus in this embodiment is manufactured using the light-emitting device described in any one of Embodiment 1 to Embodiment 4 and thus a light-emitting apparatus having favorable characteristics can be obtained. Specifically, since the light-emitting device described in any one of Embodiment 1 to Embodiment 4 has favorable emission efficiency, the light-emitting apparatus can have low power consumption.

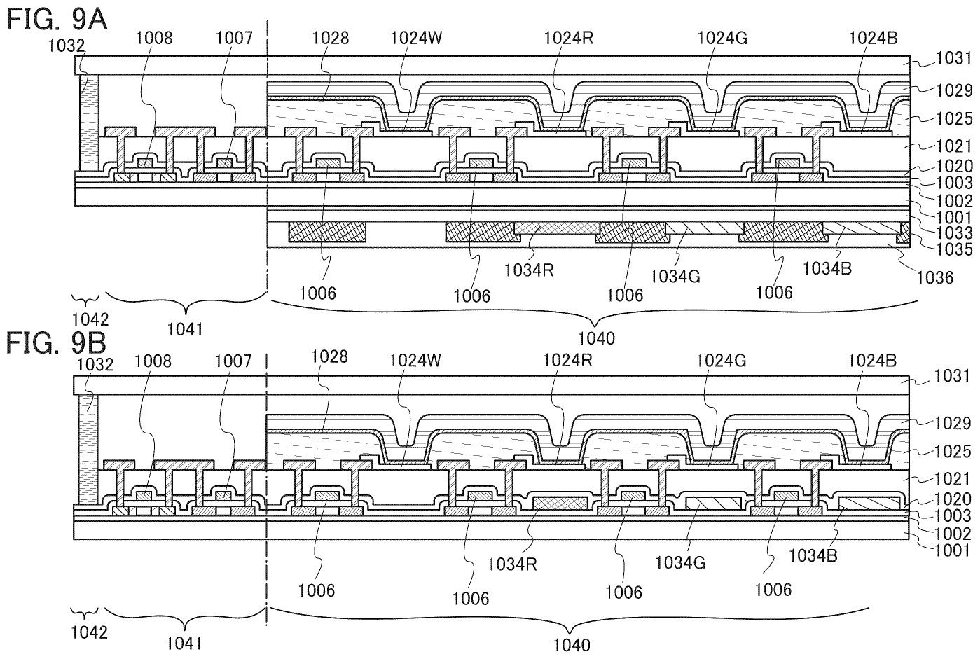

FIG. 9 illustrates examples of a light-emitting apparatus in which full color display is achieved by formation of light-emitting devices emitting white light and provision of coloring layers (color filters) and the like. FIG. 9A illustrates a substrate 1001; a base insulating film 1002; a gate insulating film 1003; a gate electrode 1006; a gate electrode 1007; a gate electrode 1008; a first interlayer insulating film 1020; a second interlayer insulating film 1021; a peripheral portion 1042; a pixel portion 1040; a driver circuit portion 1041; an electrode 1024 W, an electrode 1024R, an electrode 1024G, and an electrode 1024B of the light-emitting devices; a partition 1025; an EL layer 1028; an electrode 1029 of the light-emitting devices; a sealing substrate 1031; a sealant 1032; and the like.

In FIG. 9A, coloring layers (a red coloring layer 1034R, a green coloring layer 1034G, and a blue coloring layer 1034B) are provided on a transparent base material 1033. A black matrix 1035 may be additionally provided. The transparent base material 1033 provided with the coloring layers and the black matrix is aligned and fixed to the substrate 1001. Note that the coloring layers and the black matrix 1035 are covered with an overcoat layer 1036. In FIG. 9A, a light-emitting layer from which light is emitted to the outside without passing through the coloring layer and light-emitting layers from which light is emitted to the outside, passing through the coloring layers of the respective colors are shown. Since light that does not pass through the coloring layer is white and light that passes through the coloring layer is red, green, or blue, an image can be expressed by pixels of the four colors.

FIG. 9B illustrates an example in which the coloring layers (the red coloring layer 1034R, the green coloring layer 1034G, and the blue coloring layer 1034B) are formed between the gate insulating film 1003 and the first interlayer insulating film 1020. As in the structure, the coloring layers may be provided between the substrate 1001 and the sealing substrate 1031.

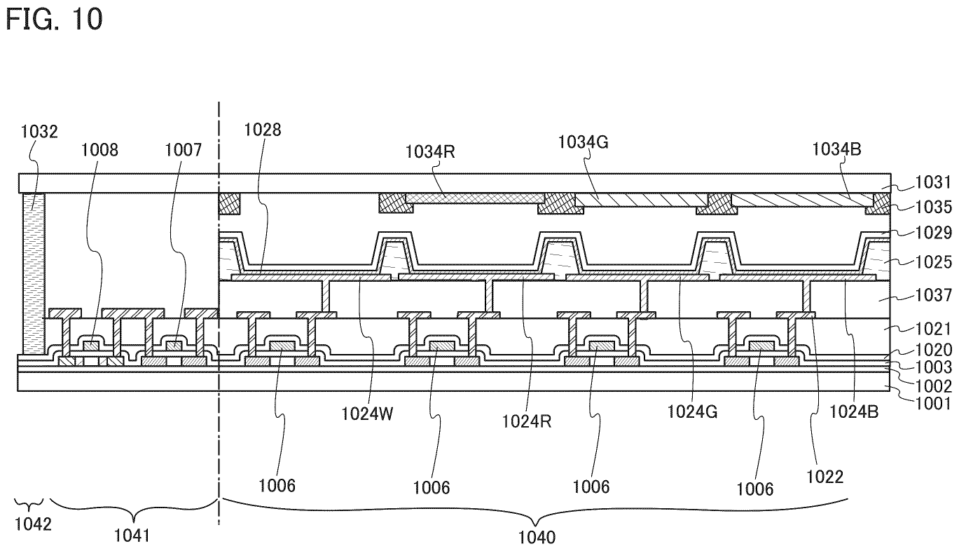

The above-described light-emitting apparatus is a light-emitting apparatus having a structure in which light is extracted from the substrate 1001 side where FETs are formed (a bottom emission structure), but may be a light-emitting apparatus having a structure in which light is extracted from the sealing substrate 1031 side (a top emission structure). FIG. 10 illustrates a cross-sectional view of atop-emission light-emitting apparatus. In this case, a substrate that does not transmit light can be used as the substrate 1001. The process up to the step of forming a connection electrode that connects the FET and the anode of the light-emitting device is performed in a manner similar to that of a bottom-emission light-emitting apparatus. Then, a third interlayer insulating film 1037 is formed to cover an electrode 1022. This insulating film may have a planarization function. The third interlayer insulating film 1037 can be formed using a material similar to that of the second interlayer insulating film, and can alternatively be formed using any of other known materials.

The electrode 1024 W, the electrode 1024R, the electrode 1024G, and the electrode 1024B of the light-emitting devices are each an anode here, but may each be a cathode. In the case of the top-emission light-emitting apparatus such as one in FIG. 10, the electrode 1024 W, the electrode 1024R, the electrode 1024G, and the electrode 1024B are preferably reflective electrodes. The structure of the EL layer 1028 is similar to the structure of the unit 103X described in any one of Embodiment 1 to Embodiment 4, and is an element structure with which white light emission can be obtained.

In the case of such a top-emission structure as in FIG. 10, sealing can be performed with the sealing substrate 1031 on which the coloring layers (the red coloring layer 1034R, the green coloring layer 1034G, and the blue coloring layer 1034B) are provided. The sealing substrate 1031 may be provided with the black matrix 1035 that is located between pixels. The coloring layers (the red coloring layer 1034R, the green coloring layer 1034G, and the blue coloring layer 1034B) or the black matrix 1035 may be covered with the overcoat layer. Note that a substrate having a light-transmitting property is used as the sealing substrate 1031. Although an example in which full color display is performed using four colors of red, green, blue, and white is described here, there is no particular limitation and full color display may be performed using four colors of red, yellow, green, and blue or three colors of red, green, and blue.

In the top-emission light-emitting apparatus, a microcavity structure can be favorably employed. A light-emitting device with a microcavity structure can be obtained with the use of a reflective electrode as the first electrode and a transflective electrode as the second electrode. The light-emitting device with a microcavity structure includes at least an EL layer between the reflective electrode and the transflective electrode, and the EL layer includes at least a light-emitting layer serving as a light-emitting region.

Note that the reflective electrode is a film having a visible light reflectance of 40% to 100%, preferably 70% to 100%, and a resistivity lower than or equal to 1×10⁻²Ω cm. In addition, the transflective electrode is a film having a visible light reflectance of 20% to 80%, preferably 40% to 70%, and a resistivity lower than or equal to 1×10⁻²Ω cm.

Light emitted from the light-emitting layer included in the EL layer is reflected and resonated by the reflective electrode and the transflective electrode.

In the light-emitting device, by changing the thickness of the transparent conductive film, the above-described composite material, the carrier-transport material, or the like, the optical path length between the reflective electrode and the transflective electrode can be changed. Thus, light with a wavelength that is resonated between the reflective electrode and the transflective electrode can be intensified while light with a wavelength that is not resonated therebetween can be attenuated.

Note that light that is reflected back by the reflective electrode (first reflected light) considerably interferes with light that directly enters the transflective electrode from the light-emitting layer (first incident light). For this reason, the optical path length between the reflective electrode and the light-emitting layer is preferably adjusted to (2n−1)λ/4 (n is a natural number greater than or equal to 1 and λ is a wavelength of light to be amplified). By adjusting the optical path length, the phases of the first reflected light and the first incident light can be aligned with each other and the light emitted from the light-emitting layer can be further amplified.

Note that in the above structure, the EL layer may include a plurality of light-emitting layers or may include a single light-emitting layer; for example, in combination with the structure of the above-described tandem light-emitting device, a plurality of EL layers each including a single or a plurality of light-emitting layer(s) may be provided in one light-emitting device with a charge-generation layer sandwiched between the EL layers.

With the microcavity structure, emission intensity with a specific wavelength in the front direction can be increased, whereby power consumption can be reduced. Note that in the case of a light-emitting apparatus that displays images with subpixels of four colors, red, yellow, green, and blue, the luminance can be increased owing to yellow light emission and each subpixel can employ a microcavity structure suitable for wavelengths of the corresponding color, so that the light-emitting apparatus can have favorable characteristics.

The light-emitting apparatus in this embodiment is manufactured using the light-emitting device described in any one of Embodiment 1 to Embodiment 4 and thus a light-emitting apparatus having favorable characteristics can be obtained. Specifically, since the light-emitting device described in any one of Embodiment 1 to Embodiment 4 has favorable emission efficiency, the light-emitting apparatus can have low power consumption.

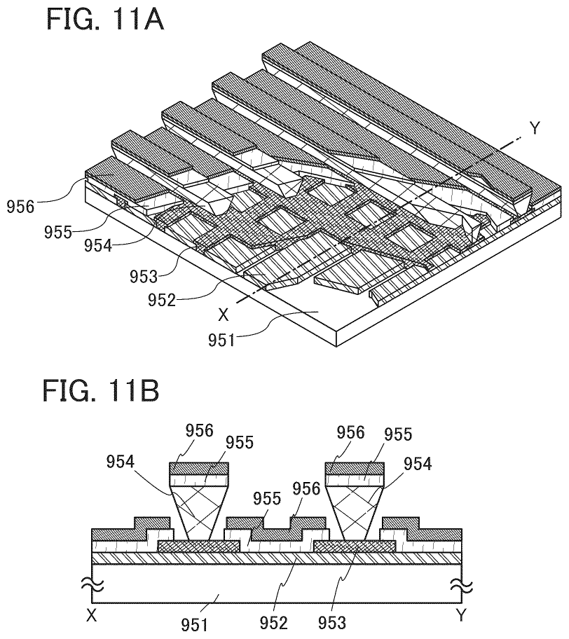

The active matrix light-emitting apparatus is described above, whereas a passive matrix light-emitting apparatus is described below. FIG. 11 illustrates a passive matrix light-emitting apparatus manufactured using the present invention. Note that FIG. 11A is a perspective view illustrating the light-emitting apparatus, and FIG. 11B is a cross-sectional view taken along X-Y in FIG. 11A. In FIG. 11, over a substrate 951, an EL layer 955 is provided between an electrode 952 and an electrode 956. An end portion of the electrode 952 is covered with an insulating layer 953. A partition layer 954 is provided over the insulating layer 953. The sidewalls of the partition layer 954 are aslope such that the distance between one sidewall and the other sidewall is gradually narrowed toward the surface of the substrate. That is, a cross section in the short side direction of the partition layer 954 has a trapezoidal shape, and the lower side (the side facing the same direction as the plane direction of the insulating layer 953 and in contact with the insulating layer 953) is shorter than the upper side (the side facing the same direction as the plane direction of the insulating layer 953, and not in contact with the insulating layer 953). The partition layer 954 thus provided can prevent defects in the light-emitting device due to static electricity or the like. The passive matrix light-emitting apparatus also uses the light-emitting device described in any one of Embodiment 1 to Embodiment 4; thus, the light-emitting apparatus can have favorable reliability or low power consumption.

In the light-emitting apparatus described above, many minute light-emitting devices arranged in a matrix can each be controlled; thus, the light-emitting apparatus can be suitably used as a display apparatus for displaying images.

This embodiment can be freely combined with any of the other embodiments.

### Embodiment 8

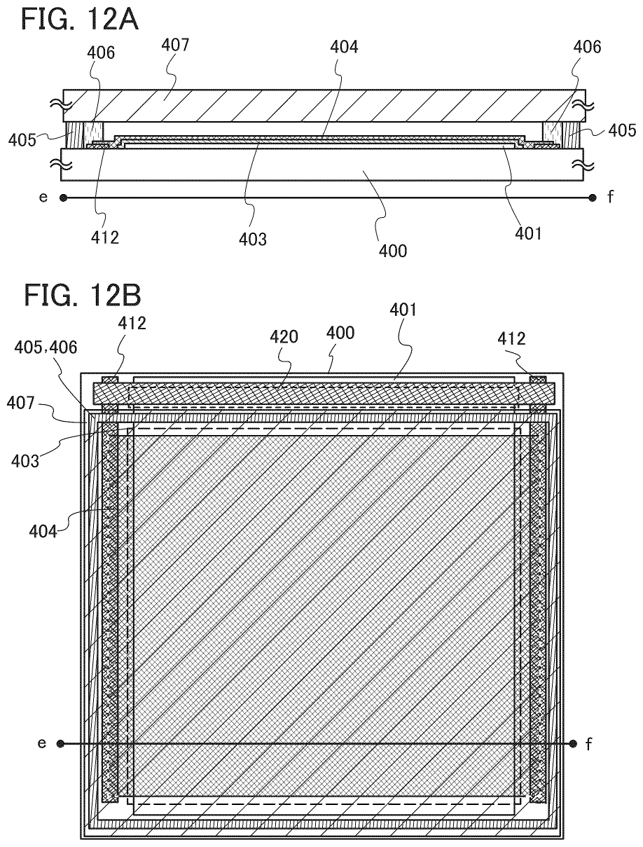

In this embodiment, an example in which the light-emitting device described in any one of Embodiment 1 to Embodiment 4 is used for a lighting apparatus will be described with reference to FIG. 12. FIG. 12B is a top view of the lighting apparatus, and FIG. 12A is a cross-sectional view taken along e-f in FIG. 12B.

In the lighting apparatus in this embodiment, a first electrode 401 is formed over a substrate 400 that is a support and has a light-transmitting property. The first electrode 401 corresponds to the electrode 551X in any one of Embodiment 1 to Embodiment 4. In the case where light emission is extracted from the first electrode 401 side, the first electrode 401 is formed using a material having a light-transmitting property.

A pad 412 for supplying a voltage to a second electrode 404 is formed over the substrate 400.

An EL layer 403 is formed over the first electrode 401. The EL layer 403 corresponds to the structure in which the layer 104X, the unit 103X, and the layer 105X are combined, the structure in which the layer 104X, the unit 103X, the intermediate layer 106X, the unit 103X2, and the layer 105X are combined, or the like in any one of Embodiment 1 to Embodiment 4. Note that for these structures, the corresponding description can be referred to.

The second electrode 404 is formed to cover the EL layer 403. The second electrode 404 corresponds to the electrode 552X in any one of Embodiment 1 to Embodiment 4. In the case where light emission is extracted from the first electrode 401 side, the second electrode 404 is formed using a material having high reflectance. The second electrode 404 is supplied with a voltage when connected to the pad 412.

As described above, the lighting apparatus described in this embodiment includes a light-emitting device including the first electrode 401, the EL layer 403, and the second electrode 404. Since the light-emitting device is a light-emitting device with high emission efficiency, the lighting apparatus in this embodiment can be a lighting apparatus with low power consumption.

The substrate 400 provided with the light-emitting device having the above structure is fixed to a sealing substrate 407 with a sealant 405 and a sealant 406 and sealing is performed, whereby the lighting apparatus is completed. It is possible to use only either the sealant 405 or the sealant 406. In addition, the inner sealant 406 (not illustrated in FIG. 12B) can be mixed with a desiccant, which enables moisture to be adsorbed, resulting in improved reliability.

When parts of the pad 412 and the first electrode 401 are provided to extend to the outside of the sealant 405 and the sealant 406, the extended parts can serve as external input terminals. An IC chip 420 mounted with a converter or the like may be provided over the external input terminals, for example.

The lighting apparatus described in this embodiment includes the light-emitting device described in any one of Embodiment 1 to Embodiment 4 as an EL element; thus, the lighting apparatus can have low power consumption.

### Embodiment 9

In this embodiment, examples of electronic devices each partly including the light-emitting device described in any one of Embodiment 1 to Embodiment 4 will be described. The light-emitting device described in any one of Embodiment 1 to Embodiment 4 is a light-emitting device with favorable emission efficiency and low power consumption. As a result, the electronic devices described in this embodiment can be electronic devices each including a light-emitting portion with low power consumption.

Examples of the electronic devices including the above light-emitting device include television devices (also referred to as TV or television receivers), monitors for computers and the like, digital cameras, digital video cameras, digital photo frames, cellular phones (also referred to as mobile phones or mobile phone devices), portable game machines, portable information terminals, audio playback devices, and large game machines such as pachinko machines. Specific examples of these electronic devices are described below.

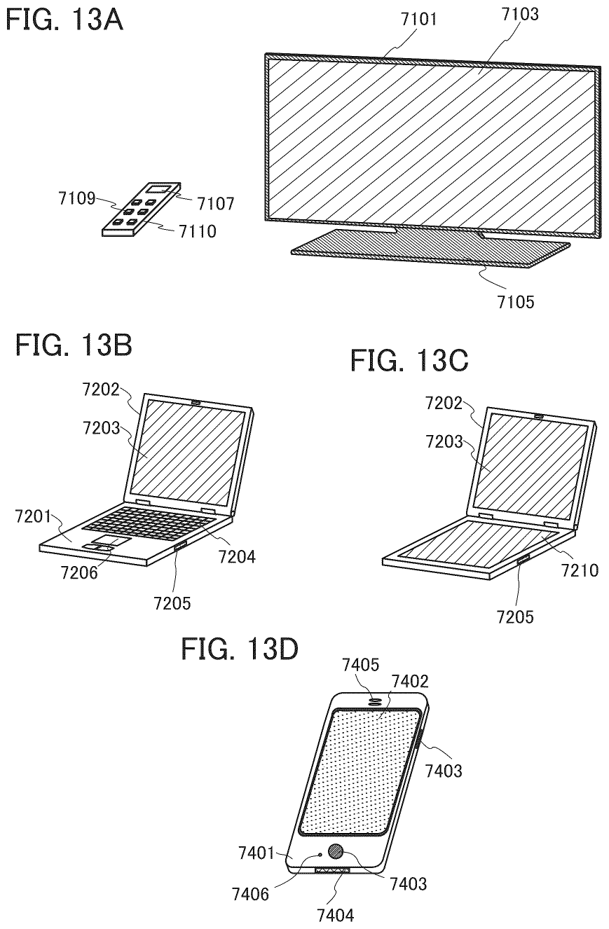

FIG. 13A illustrates an example of a television device. In the television device, a display portion 7103 is incorporated in a housing 7101. Here, the housing 7101 is supported by a stand 7105. Images can be displayed on the display portion 7103, and the light-emitting devices described in any one of Embodiment 1 to Embodiment 4 are arranged in a matrix in the display portion 7103.

The television device can be operated with an operation switch of the housing 7101 or a separate remote controller 7110. With operation keys 7109 of the remote controller 7110, channels and volume can be operated and images displayed on the display portion 7103 can be operated. Furthermore, the remote controller 7110 may be provided with a display portion 7107, on which information output from the remote controller 7110 may be displayed.

Note that the television device has a structure including a receiver, a modem, or the like. With the use of the receiver, a general television broadcast can be received, and moreover, when the television device is connected to a communication network with or without wires via the modem, one-way (from a sender to a receiver) or two-way (between a sender and a receiver or between receivers) information communication can be performed.

FIG. 13B illustrates a computer that includes a main body 7201, a housing 7202, a display portion 7203, a keyboard 7204, an external connection port 7205, a pointing device 7206, and the like. Note that this computer is manufactured using the light-emitting devices described in any one of Embodiment 1 to Embodiment 4 arranged in a matrix in the display portion 7203. The computer in FIG. 13B may be in a mode as illustrated in FIG. 13C. The computer in FIG. 13C is provided with a second display portion 7210 instead of the keyboard 7204 and the pointing device 7206. The second display portion 7210 is of a touch-panel type, and input can be performed by operating display for input displayed on the second display portion 7210 with a finger or a dedicated pen. The second display portion 7210 can also display images other than the display for input. The display portion 7203 may also be a touch panel. Connecting the two screens with a hinge can prevent troubles such as a crack in or damage to the screens caused when the computer is stored or carried.

FIG. 13D illustrates an example of a portable terminal. The portable terminal includes operation buttons 7403, an external connection port 7404, a speaker 7405, a microphone 7406, and the like in addition to a display portion 7402 incorporated in a housing 7401. Note that the portable terminal includes the display portion 7402 that is manufactured by arranging the light-emitting devices described in any one of Embodiment 1 to Embodiment 4 in a matrix.

The portable terminal illustrated in FIG. 13D can have a structure in which information can be input by touching the display portion 7402 with a finger or the like. In this case, operations such as making a call and creating an e-mail can be performed by touching the display portion 7402 with a finger or the like.

The display portion 7402 has mainly three screen modes. The first mode is a display mode mainly for displaying images. The second mode is an input mode mainly for inputting information such as text. The third mode is a display-and-input mode in which the two modes, the display mode and the input mode, are combined.

For example, in the case of making a call or creating an e-mail, the text input mode mainly for inputting text is selected for the display portion 7402 so that text displayed on the screen can be input. In this case, it is preferable to display a keyboard or number buttons on almost the entire screen of the display portion 7402.

When a detection device including a sensor such as a gyroscope sensor or an acceleration sensor for detecting inclination is provided inside the portable terminal, display on the screen of the display portion 7402 can be automatically changed by determining the orientation of the portable terminal (whether the portable terminal is placed vertically or horizontally).

The screen modes are switched by touching the display portion 7402 or operating the operation buttons 7403 of the housing 7401. Alternatively, the screen modes can be switched depending on the kind of images displayed on the display portion 7402. For example, when a signal of an image displayed on the display portion is moving image data, the screen mode is switched to the display mode. When the signal is text data, the screen mode is switched to the input mode.

Moreover, in the input mode, when input by the touch operation of the display portion 7402 is not performed for a certain period while a signal detected by an optical sensor in the display portion 7402 is sensed, the screen mode may be controlled so as to be switched from the input mode to the display mode.

The display portion 7402 can also function as an image sensor. For example, an image of a palm print, a fingerprint, or the like is taken when the display portion 7402 is touched with the palm or the finger, whereby personal authentication can be performed. Furthermore, by providing a backlight that emits near-infrared light or a sensing light source that emits near-infrared light in the display portion, an image of a finger vein, a palm vein, or the like can be taken.

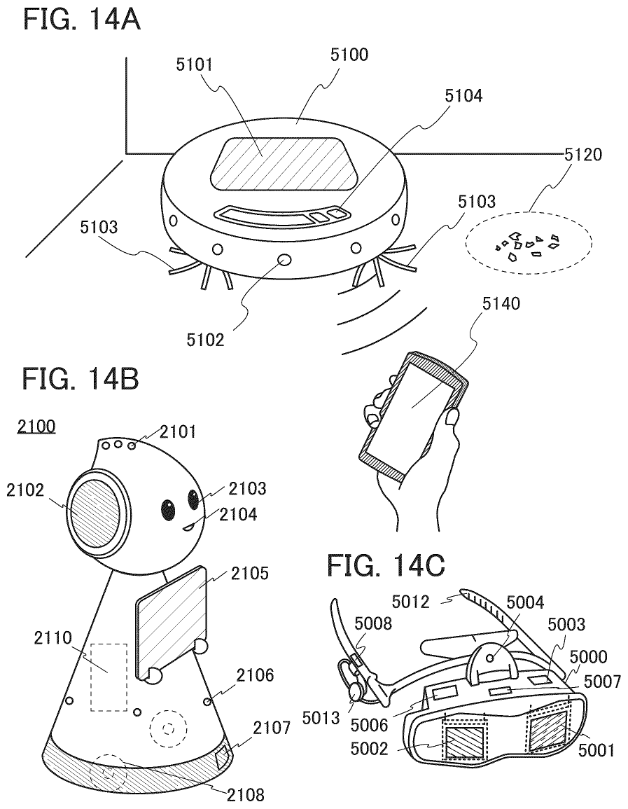

FIG. 14A is a schematic view illustrating an example of a cleaning robot.

A cleaning robot 5100 includes a display 5101 provided on its top surface, a plurality of cameras 5102 on its side surface, a brush 5103, and operation buttons 5104. Although not illustrated, the bottom surface of the cleaning robot 5100 is provided with a tire, an inlet, and the like. Furthermore, the cleaning robot 5100 includes various sensors such as an infrared sensor, an ultrasonic sensor, an acceleration sensor, a piezoelectric sensor, an optical sensor, and a gyroscope sensor. The cleaning robot 5100 has a wireless communication means.

The cleaning robot 5100 is self-propelled, senses dust 5120, and vacuums the dust through the inlet provided on the bottom surface.

The cleaning robot 5100 can determine whether there is an obstacle such as a wall, furniture, or a step by analyzing images taken by the cameras 5102. When an object that is likely to be caught in the brush 5103, such as a wire, is sensed by image analysis, the rotation of the brush 5103 can be stopped.

The display 5101 can display the remaining capacity of a battery, the amount of vacuumed dust, or the like. The display 5101 may display a path on which the cleaning robot 5100 has run. The display 5101 may be a touch panel, and the operation buttons 5104 may be provided on the display 5101.

The cleaning robot 5100 can communicate with a portable electronic device 5140 such as a smartphone. Images taken by the cameras 5102 can be displayed on the portable electronic device 5140. Accordingly, an owner of the cleaning robot 5100 can monitor his/her room even when the owner is not at home. The owner can also check the display on the display 5101 by the portable electronic device 5140 such as a smartphone.

The light-emitting apparatus of one embodiment of the present invention can be used for the display 5101.

A robot 2100 illustrated in FIG. 14B includes an arithmetic device 2110, a microphone 2102, an upper camera 2103, a speaker 2104, a display 2105, a lower camera 2106, an obstacle sensor 2107, and a moving mechanism 2108.

The microphone 2102 has a function of sensing a speaking voice of a user, an environmental sound, and the like. The speaker 2104 has a function of outputting sound. The robot 2100 can communicate with a user by using the microphone 2102 and the speaker 2104.

The display 2105 has a function of displaying various kinds of information. The robot 2100 can display information desired by a user on the display 2105. The display 2105 may be provided with a touch panel. Moreover, the display 2105 may be a detachable information terminal, in which case charging and data communication can be performed when the display 2105 is set at the home position of the robot 2100.

The upper camera 2103 and the lower camera 2106 each have a function of taking an image of the surroundings of the robot 2100. The obstacle sensor 2107 can detect an obstacle in the direction where the robot 2100 advances with the moving mechanism 2108. The robot 2100 can move safely by recognizing the surroundings with the upper camera 2103, the lower camera 2106, and the obstacle sensor 2107. The light-emitting apparatus of one embodiment of the present invention can be used for the display 2105.

FIG. 14C is a diagram illustrating an example of a goggles-type display. The goggles-type display includes, for example, a housing 5000, a display portion 5001, a speaker 5003, an LED lamp 5004, operation keys (including a power switch or an operation switch), a connection terminal 5006, a sensor 5007 (a sensor having a function of measuring force, displacement, position, speed, acceleration, angular velocity, rotational frequency, distance, light, liquid, magnetism, temperature, a chemical substance, sound, time, hardness, an electric field, current, voltage, power, radiation, flow rate, humidity, gradient, oscillation, odor, or infrared rays), a microphone 5008, a display portion 5002, a support 5012, and an earphone 5013.

The light-emitting apparatus of one embodiment of the present invention can be used for the display portion 5001 and the display portion 5002.

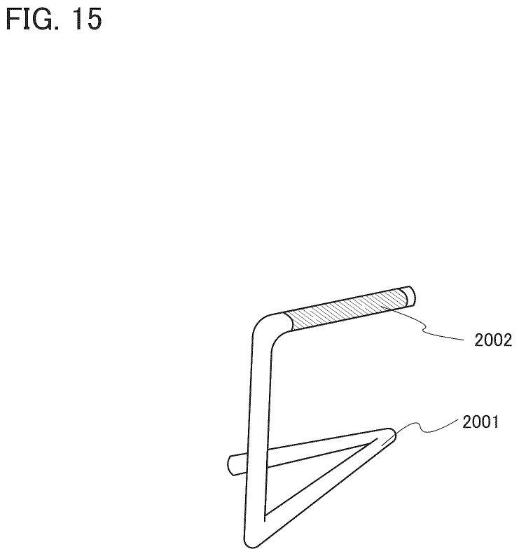

FIG. 15 illustrates an example where the light-emitting device described in any one of Embodiment 1 to Embodiment 4 is used for a table lamp which is alighting apparatus. The table lamp illustrated in FIG. 15 includes a housing 2001 and a light source 2002, and the lighting apparatus described in Embodiment 8 may be used for the light source 2002.

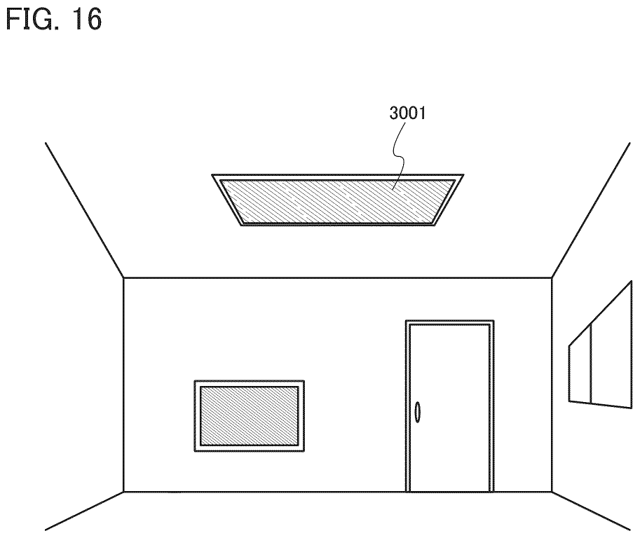

FIG. 16 illustrates an example where the light-emitting device described in any one of Embodiment 1 to Embodiment 4 is used for an indoor lighting apparatus 3001. Since the light-emitting device described in any one of Embodiment 1 to Embodiment 4 is a light-emitting device with high emission efficiency, the lighting apparatus can have low power consumption. In addition, the light-emitting device described in any one of Embodiment 1 to Embodiment 4 can have a larger area, and thus can be used for a large-area lighting apparatus. Furthermore, the light-emitting device described in any one of Embodiment 1 to Embodiment 4 is thin, and thus can be used for a lighting apparatus having a reduced thickness.

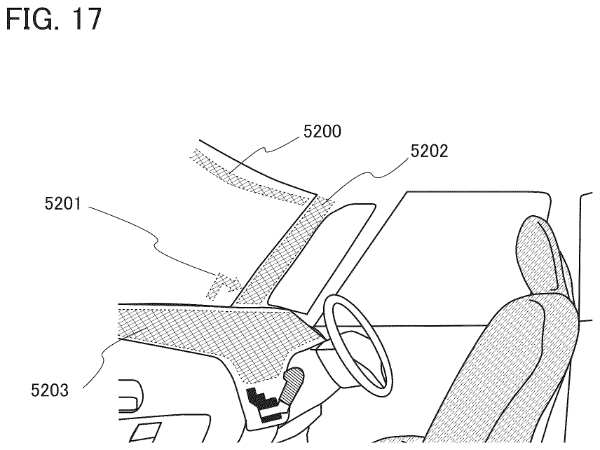

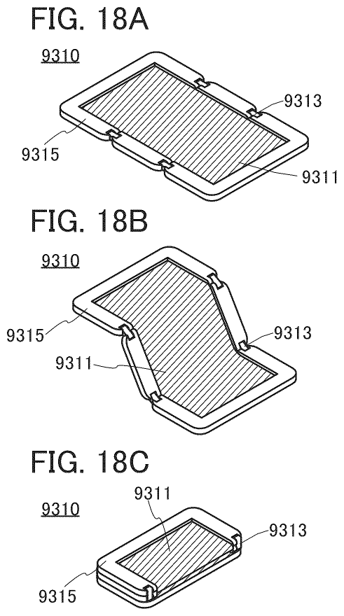

The light-emitting device described in any one of Embodiment 1 to Embodiment 4 can also be incorporated in a windshield or a dashboard of an automobile. FIG. 17 illustrates one mode in which the light-emitting device described in any one of Embodiment 1 to Embodiment 4 is used for a windshield or a dashboard of an automobile. A display region 5200 to a display region 5203 are each a display region provided using the light-emitting device described in any one of Embodiment 1 to Embodiment 4.

The display region 5200 and the display region 5201 are display apparatuses provided in the automobile windshield, in which the light-emitting devices described in any one of Embodiment 1 to Embodiment 4 are incorporated. When the light-emitting devices described in any one of Embodiment 1 to Embodiment 4 are manufactured using electrodes having light-transmitting properties as a first electrode and a second electrode, what is called see-through light-emitting devices, through which the opposite side can be seen, can be obtained. Such see-through display apparatuses can be provided even in the automobile windshield without hindering the view. Note that in the case where a driving transistor or the like is provided, a transistor having a light-transmitting property, such as an organic transistor formed using an organic semiconductor material or a transistor formed using an oxide semiconductor, is preferably used.

The display region 5202 is a display apparatus provided in a pillar portion, in which the light-emitting devices described in any one of Embodiment 1 to Embodiment 4 are incorporated. The display region 5202 can compensate for the view hindered by the pillar by displaying an image taken by an image capturing means provided in the car body. Similarly, the display region 5203 provided in the dashboard portion can compensate for the view hindered by the car body by displaying an image taken by an image capturing means provided on the outside of the automobile; thus, blind areas can be eliminated to enhance the safety. Images that compensate for the areas that a driver cannot see enable the driver to ensure safety easily and comfortably.

The display region 5203 can provide a variety of information by displaying navigation information, speed, revolutions, a mileage, a fuel level, a gearshift state, air-condition setting, and the like. The content or layout of the display can be changed freely in accordance with the preference of a user. Note that such information can also be displayed on the display region 5200 to the display region 5202. The display region 5200 to the display region 5203 can also be used as lighting apparatus.

FIG. 18A to FIG. 18C illustrate a foldable portable information terminal 9310. FIG. 18A illustrates the portable information terminal 9310 that is opened. FIG. 18B illustrates the portable information terminal 9310 that is in the state of being changed from one of an opened state and a folded state to the other. FIG. 18C illustrates the portable information terminal 9310 that is folded. The portable information terminal 9310 is excellent in portability when folded, and is excellent in display browsability when opened because of a seamless large display region.

A display panel 9311 is supported by three housings 9315 joined together by hinges 9313. Note that the display panel 9311 may be a touch panel (an input/output device) that includes a touch sensor (an input device). By folding the display panel 9311 at the hinges 9313 between two housings 9315, the portable information terminal 9310 can be reversibly changed in shape from the opened state to the folded state. The light-emitting apparatus of one embodiment of the present invention can be used for the display panel 9311.

Note that the structures described in this embodiment can be combined with any of the structures described in Embodiment 1 to Embodiment 4 as appropriate.

As described above, the application range of the light-emitting apparatus that includes the light-emitting device described in any one of Embodiment 1 to Embodiment 4 is wide, so that this light-emitting apparatus can be applied to electronic devices in a variety of fields. With the use of the light-emitting device described in any one of Embodiment 1 to Embodiment 4, an electronic device with low power consumption can be obtained.

Note that this embodiment can be combined with any of the other embodiments described in this specification as appropriate.

### Example 1

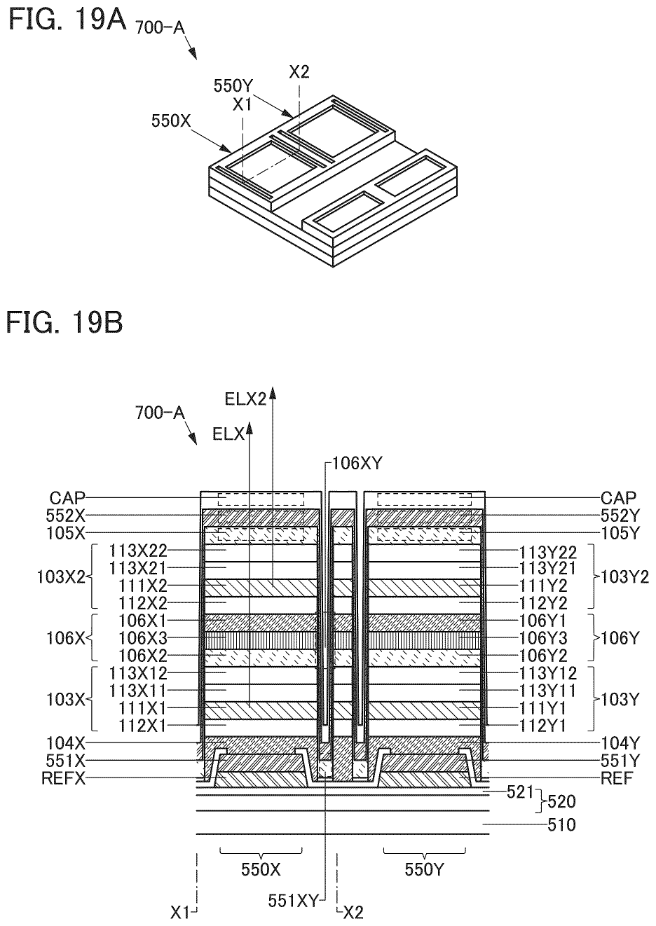

In this example, a display apparatus 700-A of one embodiment of the present invention will be described with reference to FIG. 19 to FIG. 24.

FIG. 19A is a diagram illustrating a structure of the display apparatus 700-A, and FIG. 19B is a diagram illustrating a structure of the light-emitting device 550X.

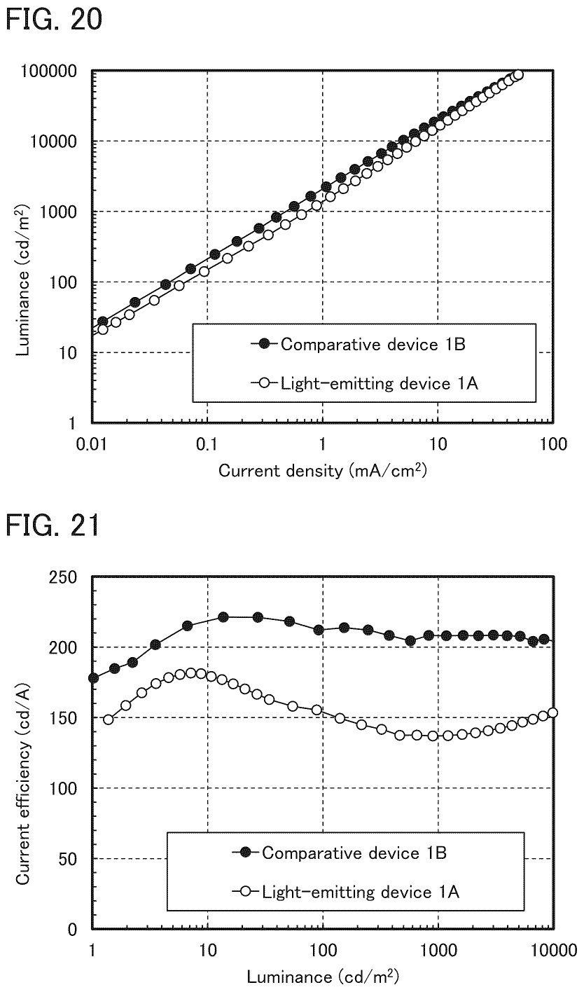

FIG. 20 is a graph showing current density-luminance characteristics of a light-emitting device TA.

FIG. 21 is a graph showing luminance-current efficiency characteristics of the light-emitting device TA.

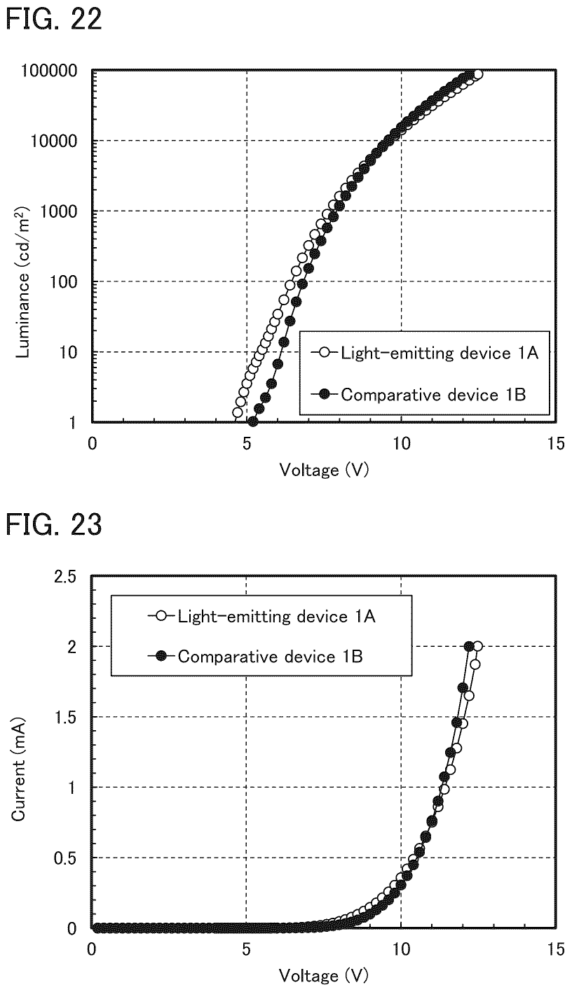

FIG. 22 is a graph showing voltage-luminance characteristics of the light-emitting device TA.

FIG. 23 is a graph showing voltage-current characteristics of the light-emitting device 1A.

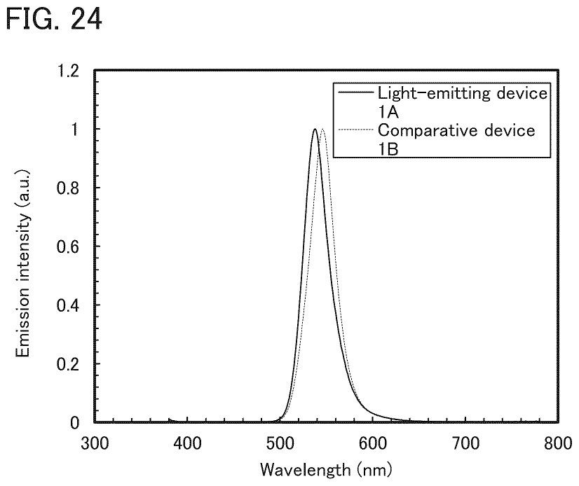

FIG. 24 is a graph showing an emission spectrum of the light-emitting device TA emitting light at a luminance of 1000 cd/m².

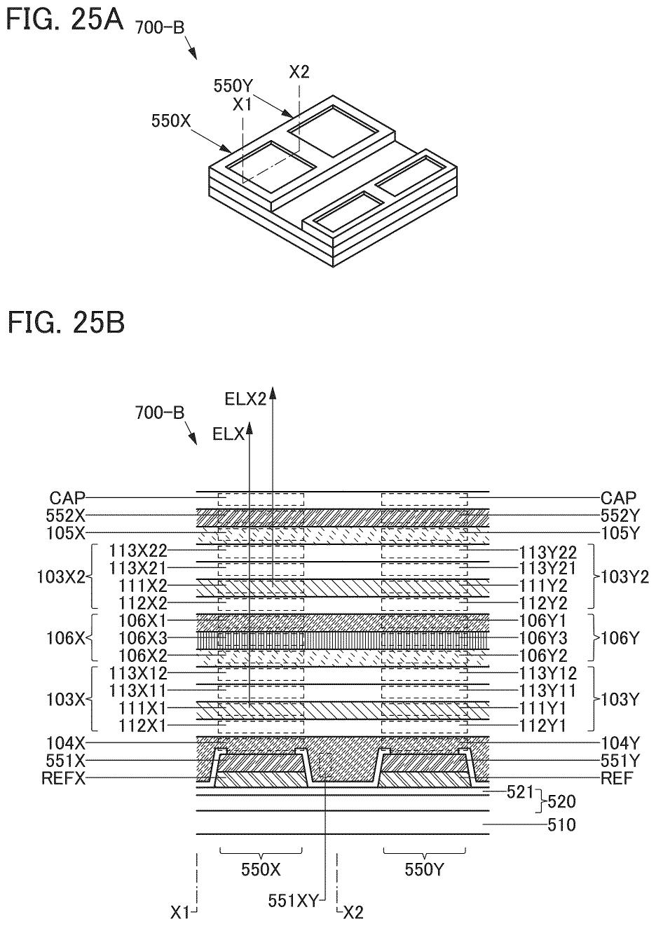

FIG. 25A is a diagram illustrating a structure of a display apparatus 700-B, and FIG. 25B is a diagram illustrating a structure of the light-emitting device 550X.

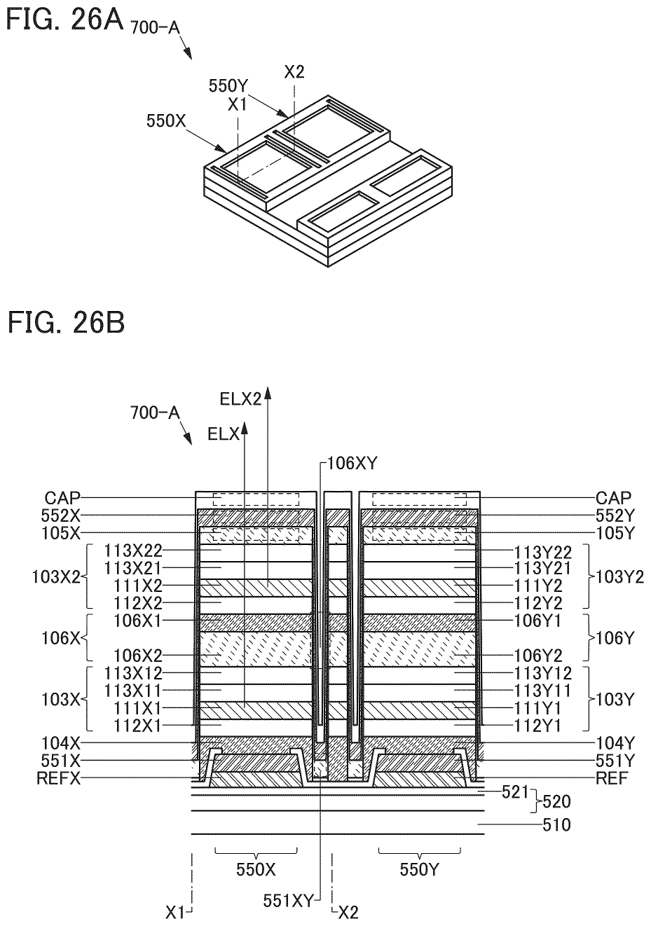

FIG. 26A is a diagram illustrating a structure of the display apparatus 700-A, and FIG. 26B is a diagram illustrating a structure of the light-emitting device 550X.

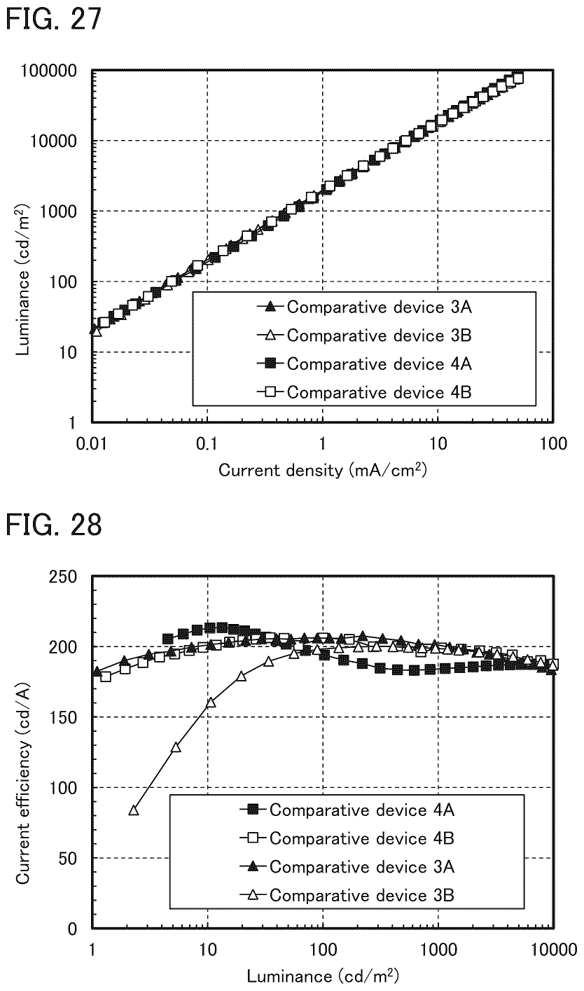

FIG. 27 is a graph showing current density-luminance characteristics of comparative devices.

FIG. 28 is a graph showing luminance-current efficiency characteristics of comparative devices.

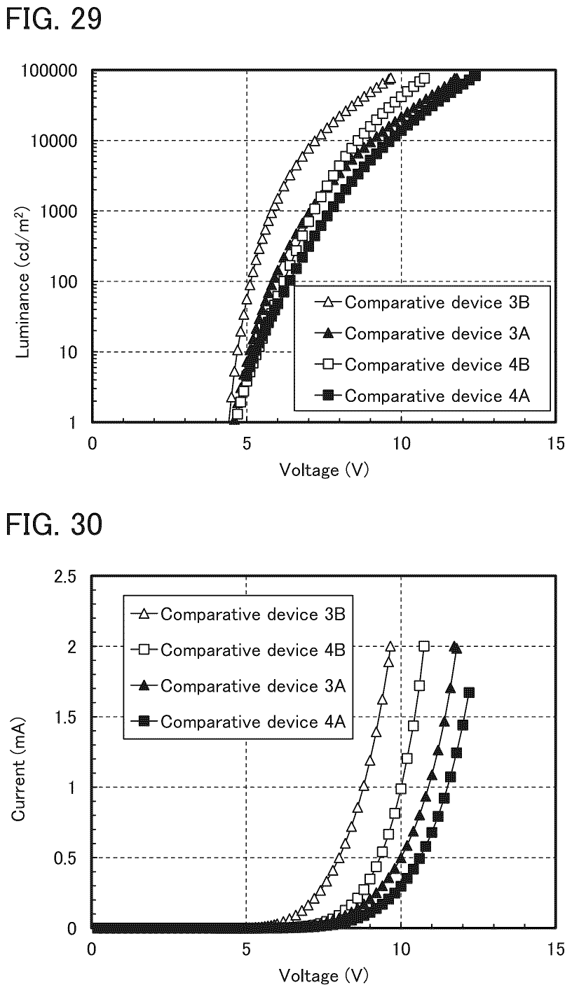

FIG. 29 is a graph showing voltage-luminance characteristics of comparative devices.

FIG. 30 is a graph showing voltage-current characteristics of comparative devices.

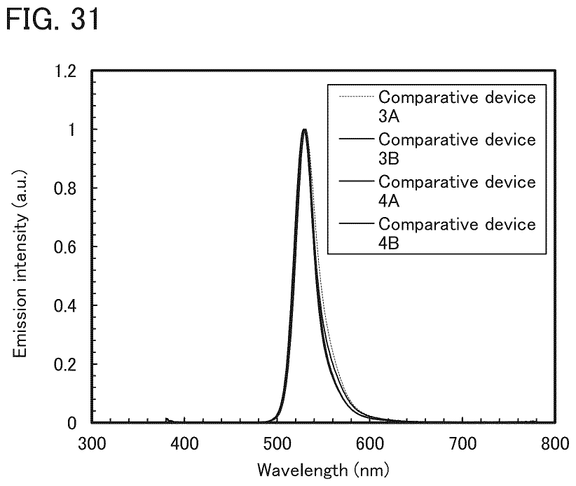

FIG. 31 is a graph showing emission spectra of comparative devices emitting light at a luminance of 1000 cd/m².

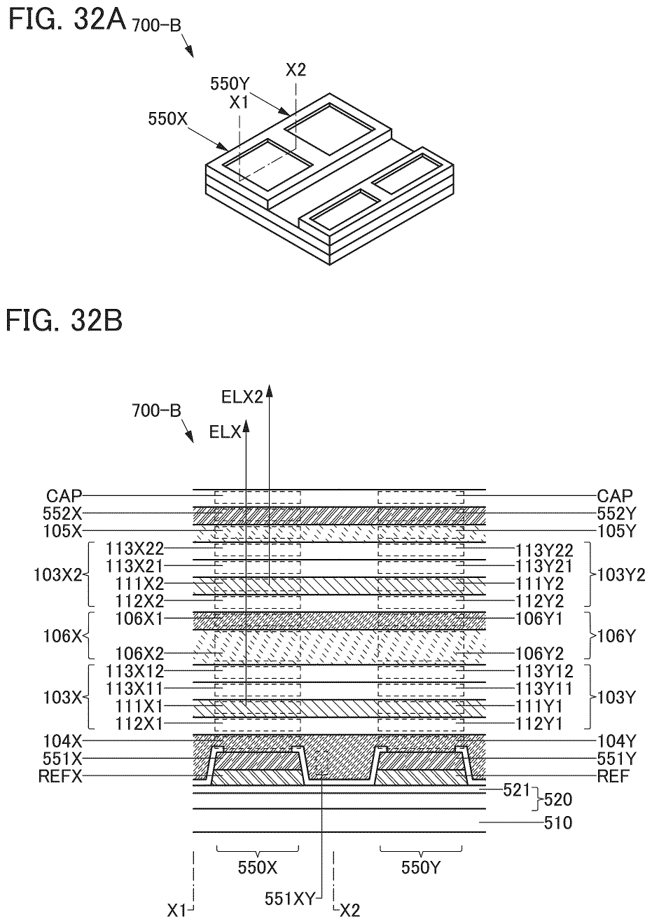

FIG. 32A is a diagram illustrating a structure of the display apparatus 700-B, and FIG. 32B is a diagram illustrating a structure of the light-emitting device 550X.

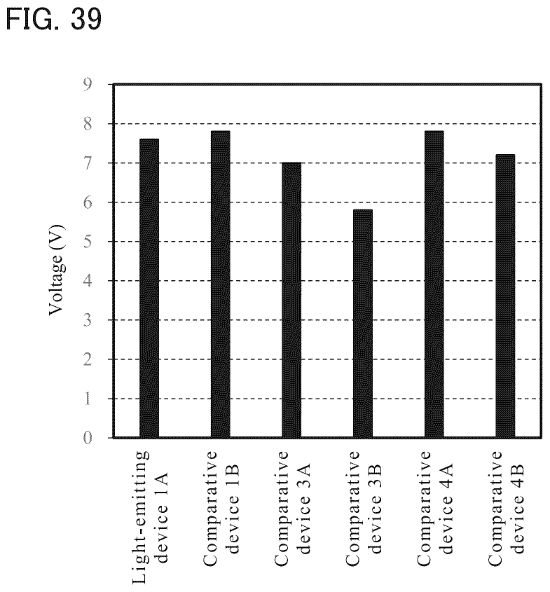

FIG. 39 is a graph showing driving voltages of the light-emitting devices in Example.

### <Display Apparatus 700-A>

The display apparatus 700-A described in this example includes the light-emitting device 550X and the light-emitting device 550Y (see FIG. 19A and FIG. 19B). The light-emitting device 550Y is adjacent to the light-emitting device 550X and includes a gap between the light-emitting device 550Y and the light-emitting device 550X.

The light-emitting device 550X includes the electrode 551X, the electrode 552X, the unit 103X, the unit 103X2, and the intermediate layer 106X. The unit 103X is sandwiched between the electrode 551X and the electrode 552X, the unit 103X2 is sandwiched between the electrode 552X and the unit 103X, the intermediate layer 106X is sandwiched between the unit 103X2 and the unit 103X, and the unit 103X is adjacent to the intermediate layer 106X. The light-emitting device 550X includes the layer 105X, and the layer 105X is sandwiched between the electrode 552X and the unit 103X2.

The light-emitting device 550Y includes the electrode 551Y, the electrode 552Y, the unit 103Y, the unit 103Y2, and the intermediate layer 106Y. The gap 551XY is included between the electrode 551Y and the electrode 551X, the unit 103Y is sandwiched between the electrode 551Y and the electrode 552Y, the unit 103Y2 is sandwiched between the electrode 552Y and the unit 103Y, the intermediate layer 106Y is sandwiched between the unit 103Y2 and the unit 103Y, and the unit 103Y is in contact with the intermediate layer 106Y. The light-emitting device 550Y includes the layer 105Y, and the layer 105Y is sandwiched between the electrode 552Y and the unit 103Y2.

A gap is included between the unit 103Y and the unit 103X, and the gap overlaps with the gap 551XY.

### <Light-Emitting Device 1A>

The fabricated light-emitting device 1A described in this example has a structure similar to that of the light-emitting device 550X (see FIG. 19B).

### Structure of Light-Emitting Device 1A>>

Table 1 shows a structure of the light-emitting device 1A. Structural formulae of materials used for the light-emitting device described in this example are shown below. Note that in the tables in this example, subscript characters and superscript characters are written in ordinary size for convenience. For example, subscript characters in abbreviations and superscript characters in units are written in ordinary size in the tables. Such notations in the tables can be replaced by referring to the description in the specification.

TABLE 1

| | Reference | | Composition | Thickness/ |
|---|---|---|---|---|
| Structure | numeral | Material | ratio | nm |
| Layer | CAP | DBT3P-II | | 70 |
| Electrode | 552X | Ag:Mg | 1:0.1 | 15 |
| Layer | 105X | LiF:Yb | 2:1 | 1.5 |
| Layer | 113X22 | mPPhen2P | | 20 |
| Layer | 113X21 | 2mPCCzPDBq | | 20 |
| Layer | 111X2 | 4,8mDBtP2Bfpm:βNCCP:Ir(ppy)2(mbfpypy-d3) | 0.5:0.5:0.1 | 40 |
| Layer | 112X2 | PCBBiF | | 40 |
| Layer | 106X1 | PCBBiF:OCHD-003 | 1:0.15 | 10 |
| Layer | 106X3 | CuPc | | 2 |
| Layer | 106X2 | mPPhen2P:2,7hpp2SF | 1:1 | 5 |
| Layer | 113X12 | mPPhen2P | | 15 |
| Layer | 113X11 | 2mPCCzPDBq | | 10 |
| Layer | 111X | 4,8mDBtP2Bfpm:βNCCP:Ir(ppy)2(mbfpypy-d3) | 0.5:0.5:0.1 | 40 |
| Layer | 112X1 | PCBBiF | | 60 |
| Layer | 104X | PCBBiF:OCHD-003 | 1:0.03 | 10 |
| Electrode | 551X | ITSO | | 100 |
| Reflective film | REFX | APC | | 100 |

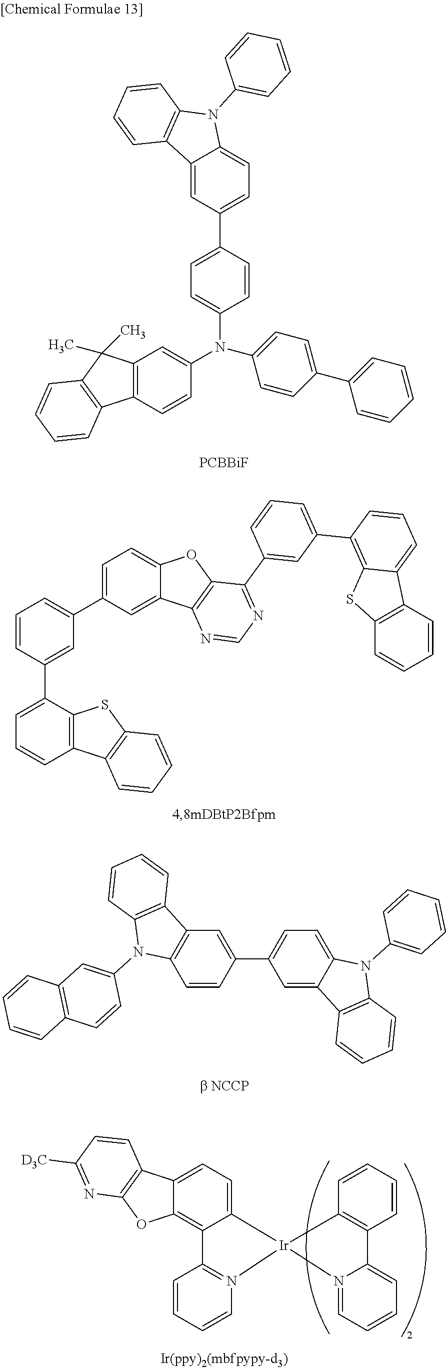

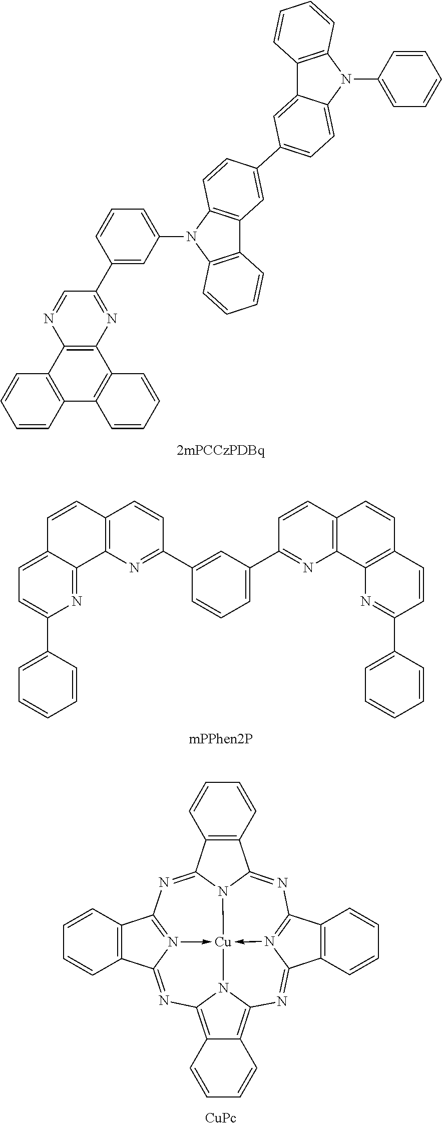

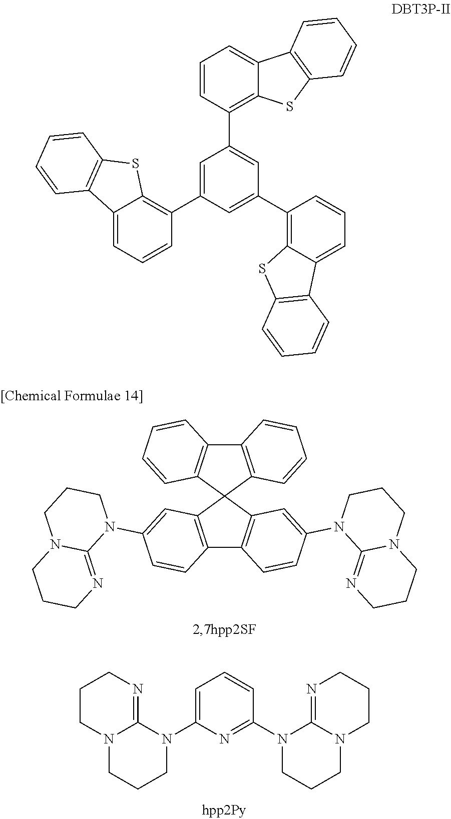 [SMILES: c1ccc2c(c1)sc1c(-c3cc(-c4cccc5c4sc4ccccc45)cc(-c4cccc5c4sc4ccccc45)c3)cccc12 ; c1ccc2c(c1)-c1ccccc1C21c2cc(N3CCCN4CCCN=C43)ccc2-c2ccc(N3CCCN4CCCN=C43)cc21 ; c1cc(N2CCCN3CCCN=C32)nc(N2CCCN3CCCN=C32)c1]

### Fabrication Method of Light-Emitting Device 1A

The light-emitting device 1A described in this example was fabricated using a method including the following steps.

### [Step 1]

In Step 1, a reflective film REFX was formed. Specifically, the reflective film REFX was formed by a sputtering method using an alloy containing silver (Ag), palladium (Pd), and copper (Cu) (abbreviation: APC) as a target.

The reflective film REFX contains APC and has a thickness of 100 nm.

### [Step 2]

In Step 2, the electrode 551X was formed over the reflective film REFX. Specifically, the electrode 551X was formed by a sputtering method using indium oxide-tin oxide containing silicon or silicon oxide (abbreviation: ITSO) as a target.

Note that the electrode 551X contains ITSO and has a thickness of 100 nm and an area of 4 mm² (2 mm×2 mm).

Next, a base material over which the electrode 551X was formed was washed with water, baked at 200° C. for an hour, and then subjected to UV ozone treatment for 370 seconds. After that, the base material was transferred into a vacuum evaporation apparatus where the inside pressure was reduced to approximately 10-4 Pa, and vacuum baking was performed at 170° C. for 30 minutes in a heating chamber of the vacuum evaporation apparatus. Then, the base material was cooled down for approximately 30 minutes.

### [Step 3]

In Step 3, the layer 104X was formed over the electrode 551X. Specifically, materials were co-evaporated by a resistance heating method.

Note that the layer 104X contains N-(1,1′-biphenyl-4-yl)-N-[4-(9-phenyl-9H-carbazol-3-yl)phenyl]-9,9-dimethyl-9H-fluoren−2-amine (abbreviation: PCBBiF) and an electron-accepting material (abbreviation: OCHD-003) at PCBBiF: OCHD-003=1: 0.03 (weight ratio) and has a thickness of 10 nm. Note that OCHD-003 contains fluorine and has a molecular weight of 672.

### [Step 4]

In Step 4, a layer 112X1 was formed over the layer 104X. Specifically, a material was evaporated by a resistance heating method.

Note that the layer 112X1 contains PCBBiF and has a thickness of 60 nm.

### [Step 5]

In Step 5, the layer 111X was formed over the layer 112X1. Specifically, materials were co-evaporated by a resistance heating method.

The layer 111X contains 4,8-bis[3-(dibenzothiophen−4-yl)phenyl]-[1]benzofuro[3,2-d]pyrimidine (abbreviation: 4,8mDBtP2Bfpm), 9-(2-naphthyl)-9′-phenyl-9H,9′H-3,3′-bicarbazole (abbreviation: βNCCP), and [2-d₃-methyl-(2-pyridinyl-κN)benzofuro[2,3-b]pyridine-κC]bis[2-(2-pyridinyl-KN)phenyl-κC]iridium(III) (abbreviation: Ir(ppy)₂(mbfpypy-d₃)) at 4,8mDBtP2Bfpm: βNCCP: Ir(ppy)₂(mbfpypy-d₃)=0.5: 0.5: 0.1 (weight ratio) and has a thickness of 40 nm.

### [Step 6]

In Step 6, a layer 113X11 was formed over the layer 111X. Specifically, a material was evaporated by a resistance heating method.

The layer 113X11 contains 2-{3-[3-(N-phenyl-9H-carbazol-3-yl)-9H-carbazol-9-yl]phenyl}dibenzo[f,h]quinoxaline (abbreviation: 2mPCCzPDBq) and has a thickness of 10 nm.

[Step 7]In Step 7, a layer 113X12 was formed over the layer 113X11. Specifically, a material was evaporated by a resistance heating method.

The layer 113X12 contains 2,2′-(1,3-phenylene)bis(9-phenyl-1,10-phenanthroline) (abbreviation: mPPhen2P) and has a thickness of 15 nm.

### [Step 8]

In Step 8, the layer 106X2 was formed over the layer 113X12. Specifically, materials were co-evaporated by a resistance heating method.

The layer 106X2 contains mPPhen2P and 1,1′-(9,9′-spirobi[9H-fluoren]-2,7-diyl)bis(1,3,4,6,7,8-hexahydro-2H-pyrimido[1,2-a]pyrimidine) (abbreviation: 2,7hpp2SF) at mPPhen2P: 2,7hpp2SF=1: 1 (weight ratio) and has a thickness of 5 nm.

[Step 9]In Step 9, the layer 106X3 was formed over the layer 106X2. Specifically, a material was evaporated by a resistance heating method.

The layer 106X3 contains copper phthalocyanine (abbreviation: CuPc) and has a thickness of 2 nm.

### [Step 10]

In Step 10, the layer 106X1 was formed over the layer 106X3. Specifically, materials were co-evaporated by a resistance heating method.

The layer 106X1 contains PCBBiF and OCHD-003 at PCBBiF: OCHD-003=1: 0.15 (weight ratio) and has a thickness of 10 nm.

### [Step 11]

In Step 11, the layer 112X2 was formed over the layer 106X1. Specifically, a material was evaporated by a resistance heating method.

The layer 112X2 contains PCBBiF and has a thickness of 40 nm.

### [Step 12]

In Step 12, the layer 111X2 was formed over the layer 112X2. Specifically, materials were co-evaporated by a resistance heating method.

The layer 111X2 contains 4,8mDBtP2Bfpm, βNCCP, and Ir(ppy)₂(mbfpypy-d₃) at 4,8mDBtP2Bfpm: βNCCP: Ir(ppy)₂(mbfpypy-d₃)=0.5: 0.5: 0.1 (weight ratio) and has a thickness of 40 nm.

### [Step 13]

In Step 13, a layer 113X21 was formed over the layer 111X2. Specifically, a material was evaporated by a resistance heating method.

Note that the layer 113X21 contains 2mPCCzPDBq and has a thickness of 20 nm.

### [Step 14]

In Step 14, a layer 113X22 was formed over the layer 113X21. Specifically, a material was evaporated by a resistance heating method.

The layer 113X22 contains mPPhen2P and has a thickness of 20 nm.

### [Step 15-1]

After a sample was taken out from the vacuum evaporation apparatus and exposed to the air, a sacrificial layer SCR1 was formed over the layer 113X22 in Step 15-1. Specifically, deposition was performed by an ALD method using trimethylaluminum (abbreviation: TMA) as a precursor and water vapor as an oxidizing agent.

Note that the sacrificial layer SCR1 contains aluminum oxide and has a thickness of 30 nm.

### [Step 15-2]

In Step 15-2, a sacrificial layer SCR2 was formed over the sacrificial layer SCR1. Specifically, deposition was performed by a sputtering method using a composite oxide containing indium, gallium, zinc, and oxygen (abbreviation: IGZO) as a target.

Note that the sacrificial layer SCR2 contains IGZO and has a thickness of 50 nm.

### [Step 15-3]

In Step 15-3, a resist was formed using a photoresist over the sacrificial layer SCR2, and the sacrificial layer SCR2, the sacrificial layer SCR1, the layer 113X22, the layer 113X21, the layer 111X2, the layer 112X2, the layer 106X1, the layer 106X3, the layer 106X2, the layer 113X12, the layer 113X11, the layer 111X1, the layer 112X1, and the layer 104X were processed into predetermined shapes by a lithography method.

Specifically, the sacrificial layer SCR2 was processed by etching using an agent containing water and phosphoric acid, and then the sacrificial layer SCR1 was processed using an etching gas containing trifluoromethane (abbreviation: CHF₃) and helium (He) at CHF₃: He=1: 9 (flow rate ratio). After that, the etching conditions were changed, and the stacked films from the layer 104X up to the layer 113X22 were processed into a predetermined shape. Specifically, the processing was performed using an etching gas containing oxygen (abbreviation: 02).

As the predetermined shape, a shape in which a slit is formed in a region of the stacked films that does not overlap with the electrode 551X was employed. Specifically, a slit having a width of 3 m was formed in a position that is 3.5 m apart from the end portion of the electrode 551X and in a region overlapping with the gap 551XY between the electrode 551X and the electrode 551Y (see FIG. 19B). Accordingly, a gap is formed in the region 106XY.

### [Step 15-4]

In Step 15-4, the sacrificial layer SCR2, the sacrificial layer SCR1, and the resist were removed, whereby the layer 113X22 was processed to be exposed.

Next, the base material was transferred into a vacuum evaporation apparatus where the inside pressure was reduced to approximately 10-4 Pa, and vacuum baking was performed at 110° C. for an hour in a heating chamber of the vacuum evaporation apparatus. Then, the base material was cooled down for approximately 30 minutes.

### [Step 16]

In Step 16, the layer 105X was formed over the layer 113X22. Specifically, materials were co-evaporated by a resistance heating method.

Note that the layer 105X contains lithium fluoride (abbreviation: LiF) and ytterbium (abbreviation: Yb) at LiF: Yb=2: 1 (volume ratio) and has a thickness of 1.5 nm.

### [Step 17]

In Step 17, the electrode 552X was formed over the layer 105X. Specifically, materials were co-evaporated by a resistance heating method.

Note that the electrode 552X contains silver (abbreviation: Ag) and magnesium (abbreviation: Mg) at Ag: Mg=1: 0.1 (volume ratio) and has a thickness of 15 nm.

### [Step 18]

In Step 18, a layer CAP was formed over the electrode 552X. Specifically, a material was evaporated by a resistance heating method.

The layer CAP contains 4,4′,4″-(benzene-1,3,5-triyl)tri(dibenzothiophene) (abbreviation: DBT3P-II) and has a thickness of 70 nm.

Operation characteristics of light-emitting device TA When supplied with electric power, the light-emitting device TA emitted the light ELX and the light ELX2 (see FIG. 19B). The operation characteristics of the light-emitting device TA were measured at room temperature (see FIG. 20 to FIG. 24). The luminance, CIE chromaticity, and emission spectrum were measured using a spectroradiometer (SR-UL1R, manufactured by TOPCON TECHNOHOUSE CORPORATION).

Table 2 shows main initial characteristics of the fabricated light-emitting device emitting light at a luminance of approximately 1000 cd/m².

TABLE 2

| | | | Current | | | Current |
|---|---|---|---|---|---|---|
| | Voltage | Current | density | | | efficiency |
| | (V) | (mA) | (mA/cm2) | Chromaticity x | Chromaticity y | (cd/A) |
| Light-emitting | 7.6 | 0.03 | 0.7 | 0.28 | 0.70 | 136.9 |
| device 1A | | | | | | |
| Comparative | 7.8 | 0.02 | 0.4 | 0.30 | 0.68 | 208.2 |
| device 1B | | | | | | |
| Comparative | 7.0 | 0.02 | 0.5 | 0.24 | 0.72 | 201.5 |
| device 3A | | | | | | |
| Comparative | 5.8 | 0.02 | 0.5 | 0.22 | 0.74 | 198.8 |
| device 3B | | | | | | |
| Comparative | 7.8 | 0.02 | 0.6 | 0.23 | 0.73 | 184.4 |
| device 4A | | | | | | |
| Comparative | 7.2 | 0.02 | 0.5 | 0.23 | 0.73 | 199.0 |
| device 4B | | | | | | |

The light-emitting device TA was found to have favorable characteristics. For example, the driving voltage of the light-emitting device TA was approximately the same as that of a comparative device 1B described in the following section of this example, Reference Example 1. In comparison with the comparative device 1B fabricated not through Step 15-1 to Step 15-4, an increase in driving voltage was not observed in the light-emitting device TA fabricated through Step 15-1 to Step 15-4 (see FIG. 39). The light-emitting device TA is highly resistant to atmospheric components to which the light-emitting device TA is exposed in Step 15-1 to Step 15-4. The intermediate layer containing 2,7hpp2SF is highly resistant to the microfabrication technique used in Step 15-1 to Step 15-4. The intermediate layer containing 2,7hpp2SF is highly resistant to the agent containing water and phosphoric acid to which the intermediate layer is exposed in Step 15-3, for example.

### Reference Example 1

The fabricated comparative display apparatus 700-B described in this reference example includes the light-emitting device 550X and the light-emitting device 550Y (see FIG. 25A). The light-emitting device 550Y is adjacent to the light-emitting device 550X. Note that the display apparatus 700-B is different from the display apparatus 700-A described in Example 1 in that a gap is not included between the light-emitting device 550Y and the light-emitting device 550X.

### <Comparative Device 1B>

The fabricated comparative device 1B has a structure similar to that of the light-emitting device 550X (see FIG. 25B).

### Structure of Comparative Device 1B>>

The structure of the comparative device 1B is the same as that of the light-emitting device TA except that a gap is not formed between the comparative device 1B and its adjacent comparative device (see Table 1).

### Fabrication Method of Comparative Device 1B

The comparative device 1B described in this reference example was fabricated using a method including the following steps. Note that the fabrication method of the comparative device 1B is different from the fabrication method of the light-emitting device TA in that the layer 105X was formed over the unit 103X2 not through the step of forming a slit between the unit 103X2 and the unit 103Y2. In other words, a method was employed in which Step 15-1 to Step 15-4 are not performed and the process goes to Step 16 after Step 14.

### Reference Example 2

The fabricated comparative display apparatus 700-A described in this reference example includes the light-emitting device 550X and the light-emitting device 550Y (see FIG. 26A). The light-emitting device 550Y is adjacent to the light-emitting device 550X and includes a gap between the light-emitting device 550Y and the light-emitting device 550X.

### <Comparative Device 3A>

The fabricated comparative device 3A described in this reference example has a structure similar to that of the light-emitting device 550X (see FIG. 26B).

### Structure of Comparative Device 3A

The structure of the comparative device 3A is shown in Table 3. Note that the structure of the comparative device 3A is different from that of the light-emitting device 1A in the intermediate layer 106X and the layer 106X2. Specifically, the comparative device 3A is different from the light-emitting device 1A in that the intermediate layer 106X does not include the layer 106X3 and the layer 106X2 contains Li instead of 2,7hpp2SF.

TABLE 3

| | Reference | | Composition | Thickness/ |
|---|---|---|---|---|
| Structure | numeral | Material | ratio | nm |
| Layer | CAP | DBT3P-II | | 70 |
| Electrode | 552X | Ag:Mg | 1:0.1 | 15 |
| Layer | 105X | LiF:Yb | 2:1 | 1.5 |
| Layer | 113X22 | mPPhen2P | | 20 |
| Layer | 113X21 | 2mPCCzPDBq | | 20 |
| Layer | 111X2 | 4,8mDBtP2Bfpm:βNCCP:Ir(ppy)2(mbfpypy-d3) | 0.5:0.5:0.1 | 40 |
| Layer | 112X2 | PCBBiF | | 40 |
| Layer | 106X1 | PCBBiF:OCHD-003 | 1:0.15 | 10 |
| Layer | 106X2 | mPPhen2P:Li | 1:0.01 | 20 |
| Layer | 113X11 | 2mPCCzPDBq | | 10 |
| Layer | 111X | 4,8mDBtP2Bfpm:βNCCP:Ir(ppy)2(mbfpypy-d3) | 0.5:0.5:0.1 | 40 |
| Layer | 112X1 | PCBBiF | | 70 |
| Layer | 104X | PCBBiF:OCHD-003 | 1:0.03 | 10 |
| Electrode | 551X | ITSO | | 100 |
| Reflective film | REFX | APC | | 100 |

### Fabrication Method of Comparative Device 3A

The comparative device 3A described in this reference example was fabricated using a method including the following steps. Note that the fabrication method of the comparative device 3A is different from the fabrication method of the light-emitting device 1A in that mPPhen2P and Li were used instead of mPPhen2P and 2,7hpp2SF in Step 8 and the layer 106X1 was formed over the layer 106X2 not through the step of forming the layer 106X3 in Step 9. In other words, a method was employed in which the process goes to Step 10 after Step 8. Different portions are described in detail here, and the above description is referred to for portions formed by a similar method.

### [Step 8]

In Step 8, the layer 106X2 was formed over the layer 113X12. Specifically, materials were co-evaporated by a resistance heating method.

The layer 106X2 contains mPPhen2P and Li at mPPhen2P: Li=1: 0.01 (weight ratio) and has a thickness of 20 nm.

### [Step 10]

In Step 10, the layer 106X1 was formed over the layer 106X2. Specifically, materials were co-evaporated by a resistance heating method.

The layer 106X1 contains PCBBiF and OCHD-003 at PCBBiF: OCHD-003=1: 0.15 (weight ratio) and has a thickness of 10 nm.

### Operation Characteristics of Comparative Device 3A>>

When supplied with electric power, the comparative device 3A emitted the light ELX and the light ELX2 (see FIG. 26B). The operation characteristics of the comparative device 3A were measured at room temperature (see FIG. 27 to FIG. 31). The luminance, CIE chromaticity, and emission spectrum were measured using a spectroradiometer (SR-UL1R, manufactured by TOPCON TECHNOHOUSE CORPORATION).

Table 2 shows main initial characteristics of the fabricated comparative device emitting light at a luminance of approximately 1000 cd/m².

The comparative device 3A has a higher driving voltage than the comparative device 3B. In comparison with the comparative device 3B, an increase in driving voltage due to Step 15-1 to Step 15-4 was observed in the comparative device 3A. The comparative device 3A has low resistance to atmospheric components to which the comparative device 3A is exposed in Step 15-1 to Step 15-4. The intermediate layer formed using mPPhen2P and Li cannot be regarded as having sufficient resistance to the microfabrication technique used in Step 15-1 to Step 15-4.

### Reference Example 3

The fabricated comparative display apparatus 700-B described in this reference example includes the light-emitting device 550X and the light-emitting device 550Y (see FIG. 32A). The light-emitting device 550Y is adjacent to the light-emitting device 550X. Note that the comparative display apparatus 700-B is different from the display apparatus 700-A described in Reference Example 2 in that a gap is not included between the light-emitting device 550Y and the light-emitting device 550X.

### <Comparative Device 3B>

The fabricated comparative device 3B has a structure similar to that of the light-emitting device 550X (see FIG. 32B).

### Structure of Comparative Device 3B>>

The structure of the comparative device 3B is the same as that of the comparative device 3A except that a gap is not formed between the comparative device 3B and its adjacent comparative device (see Table 3).

### Fabrication Method of Comparative Device 3B

The comparative device 3B described in this reference example was fabricated using a method including the following steps. Note that the fabrication method of the comparative device 3B is different from the fabrication method of the comparative device 3A in that the layer 105X was formed over the unit 103X2 not through the step of forming a slit between the unit 103X2 and the unit 103Y2. In other words, a method was employed in which Step 15-1 to Step 15-4 are not performed and the process goes to Step 16 after Step 14.

### Reference Example 4

The fabricated comparative display apparatus 700-A described in this reference example includes the light-emitting device 550X and the light-emitting device 550Y (see FIG. 19A). The light-emitting device 550Y is adjacent to the light-emitting device 550X and includes a gap between the light-emitting device 550Y and the light-emitting device 550X.

### <Comparative Device 4A>

The fabricated comparative device 4A described in this reference example has a structure similar to that of the light-emitting device 550X (see FIG. 19B).

### Structure of Comparative Device 4A

Table 4 shows the structure of the comparative device 4A. Note that the structure of the comparative device 4A is different from that of the light-emitting device 1A in the layer 106X2. Specifically, the comparative device 4A is different from the light-emitting device 1A in that the layer 106X2 contains 1,1′-pyridine-2,6-diyl-bis(1,3,4,6,7,8-hexahydro-2H-pyrimido[1,2-a]pyrimidine) (abbreviation: hpp2Py) and mPPhen2P instead of 2,7hpp2SF.

TABLE 4

| | Reference | | Composition | Thickness/ |
|---|---|---|---|---|
| Structure | numeral | Material | ratio | nm |
| Layer | CAP | DBT3P-II | | 70 |
| Electrode | 552X | Ag:Mg | 1:0.1 | 15 |
| Layer | 105X | LiF:Yb | 2:1 | 2 |
| Layer | 113X22 | mPPhen2P | | 20 |
| Layer | 113X21 | 2mPCCzPDBq | | 20 |
| Layer | 111X2 | 4,8mDBtP2Bfpm:βNCCP:Ir(ppy)2(mbfpypy-d3) | 0.5:0.5:0.1 | 40 |
| Layer | 112X2 | PCBBiF | | 40 |
| Layer | 106X1 | PCBBiF:OCHD-003 | 1:0.15 | 10 |
| Layer | 106X3 | CuPc | | 2 |
| Layer | 106X2 | mPPhen2P:hpp2Py | 1:1 | 5 |
| Layer | 113X12 | mPPhen2P | | 15 |
| Layer | 113X11 | 2mPCCzPDBq | | 10 |
| Layer | 111X | 4,8mDBtP2Bfpm:βNCCP:Ir(ppy)2(mbfpypy-d3) | 0.5:0.5:0.1 | 40 |
| Layer | 112X1 | PCBBiF | | 70 |
| Layer | 104X | PCBBiF:OCHD-003 | 1:0.03 | 10 |
| Electrode | 551X | ITSO | | 100 |
| Reflective film | REFX | APC | | 100 |

### Fabrication Method of Comparative Device 4A

The comparative device 4A described in this reference example was fabricated using a method including the following steps. Note that the fabrication method of the comparative device 4A is different from the fabrication method of the light-emitting device 1A in that mPPhen2P and hpp2Py were used instead of mPPhen2P and 2,7hpp2SF in Step 8. Different portions are described in detail here, and the above description is referred to for portions formed by a similar method.

### [Step 8]

In Step 8, the layer 106X2 was formed over the layer 113X12. Specifically, materials were co-evaporated by a resistance heating method.

The layer 106X2 contains mPPhen2P and hpp2Py at mPPhen2P: hpp2Py=1: 1 (weight ratio) and has a thickness of 5 nm.

### Operation Characteristics of Comparative Device 4A>>

When supplied with electric power, the comparative device 4A emitted the light ELX and the light ELX2 (see FIG. 19B). The operation characteristics of the light-emitting device 1A were measured at room temperature (see FIG. 27 to FIG. 31). The luminance, CIE chromaticity, and emission spectrum were measured using a spectroradiometer (SR-UL1R, manufactured by TOPCON TECHNOHOUSE CORPORATION).

Table 2 shows main initial characteristics of the fabricated comparative device emitting light at a luminance of approximately 1000 cd/m².

The comparative device 4A has a higher driving voltage than the comparative device 4B. In comparison with the comparative device 4B, an increase in driving voltage due to Step 15-1 to Step 15-4 was observed in the comparative device 4A. The comparative device 4A has low resistant to atmospheric components to which the comparative device 4A is exposed in Step 15-1 to Step 15-4. In addition, the intermediate layer using mPPhen2P and hpp2Py cannot be regarded as having sufficient resistance to the microfabrication technique used in Step 15-1 to Step 15-4.

### Reference Example 5

The fabricated comparative display apparatus 700-B described in this reference example includes the light-emitting device 550X and the light-emitting device 550Y (see FIG. 25A). The light-emitting device 550Y is adjacent to the light-emitting device 550X. Note that the comparative display apparatus 700-B is different from the display apparatus 700-A described in Reference Example 4 in that a gap is not included between the light-emitting device 550Y and the light-emitting device 550X.

### <Comparative Device 4B>

The fabricated comparative device 4B has a structure similar to that of the light-emitting device 550X (see FIG. 25B).

### Structure of Comparative Device 4B>>

The structure of the comparative device 4B is the same as that of the comparative device 4A except that a gap is not formed between the comparative device 4B and its adjacent comparative device (see Table 4).

### Fabrication Method of Comparative Device 4B

The comparative device 4B described in this reference example was fabricated using a method including the following steps. Note that the fabrication method of the comparative device 4B is different from the fabrication method of the comparative device 4A in that the layer 105X was formed over the unit 103X2 not through the step of forming a slit between the unit 103X2 and the unit 103Y2. In other words, a method was employed in which Step 15-1 to Step 15-4 are not performed and the process goes to Step 16 after Step 14.

### Example 2

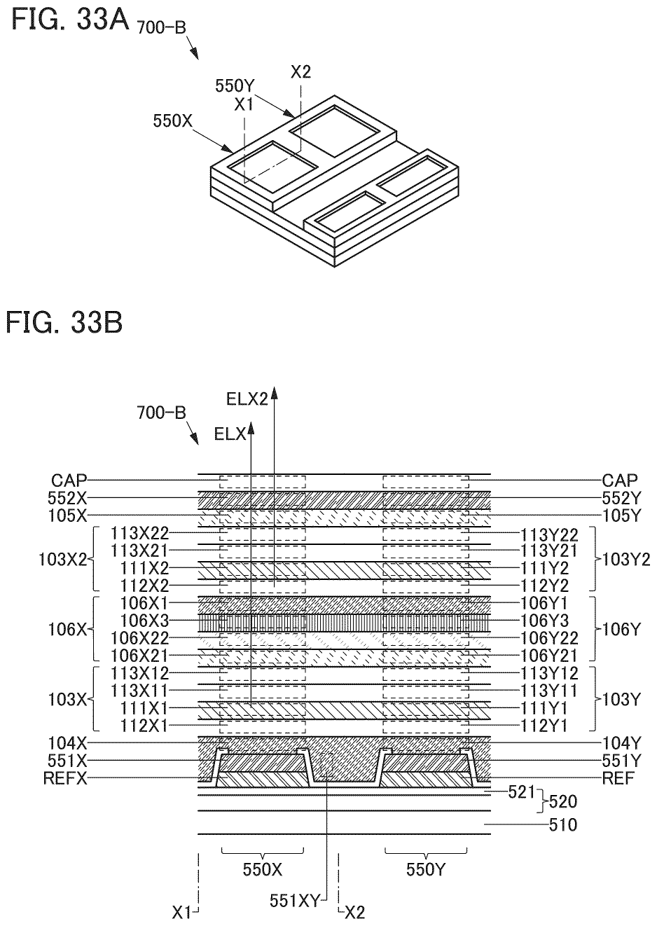

In this example, the display apparatus 700-B of one embodiment of the present invention will be described with reference to FIG. 33 to FIG. 38.

FIG. 33 is a diagram illustrating the structure of the light-emitting device 550X.

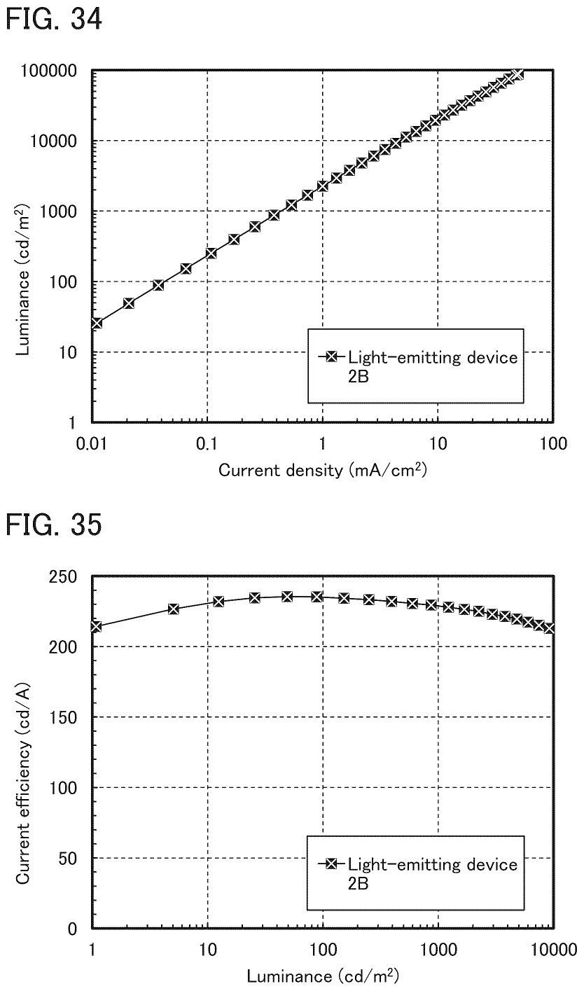

FIG. 34 is a graph showing current density-luminance characteristics of a light-emitting device 2B.

FIG. 35 is a graph showing luminance-current efficiency characteristics of the light-emitting device 2B.

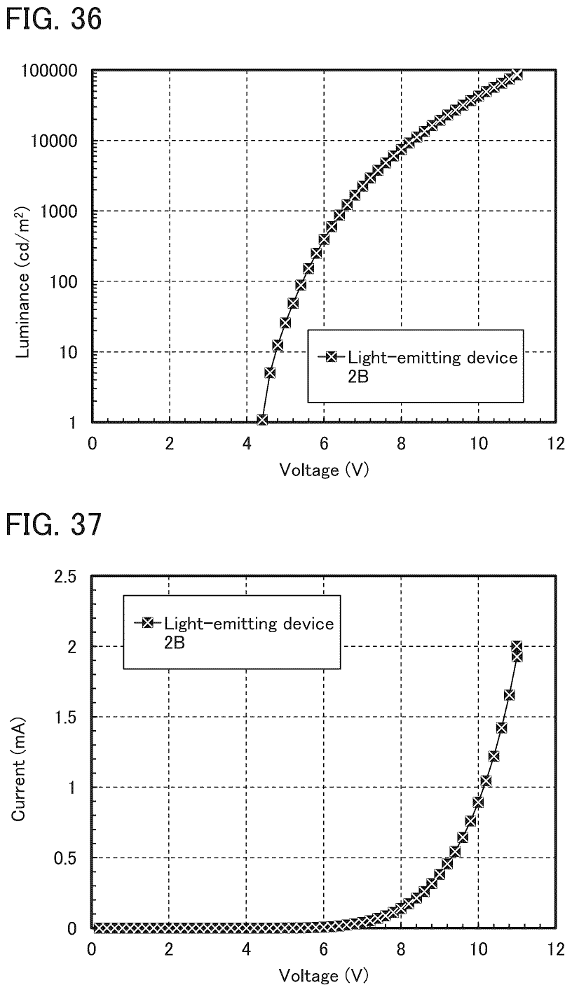

FIG. 36 is a graph showing voltage-luminance characteristics of the light-emitting device 2B.

FIG. 37 is a graph showing voltage-current characteristics of the light-emitting device 2B.

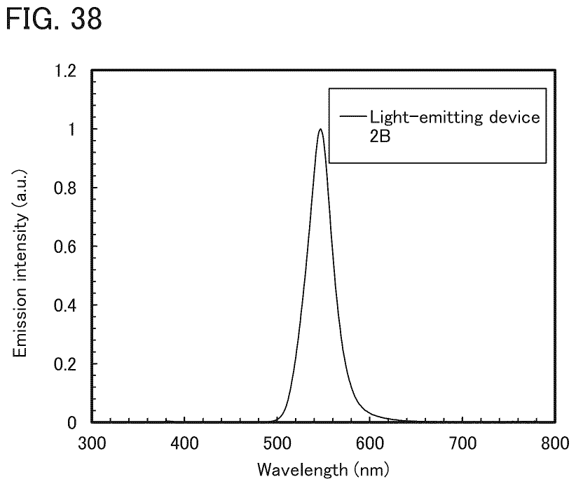

FIG. 38 is a graph showing an emission spectrum of the light-emitting device 2B emitting light at a luminance of 1000 cd/m².

### <Display Apparatus 700-B>

The fabricated display apparatus 700-B described in this example includes the light-emitting device 550X and the light-emitting device 550Y (see FIG. 33A). The light-emitting device 550Y is adjacent to the light-emitting device 550X. Note that the display apparatus 700-B is different from the display apparatus 700-A described in Example 1 in that a gap is not included between the light-emitting device 550Y and the light-emitting device 550X.

### <Light-Emitting Device 2B>

The fabricated light-emitting device 2B has a structure similar to that of the light-emitting device 550X (see FIG. 33B).

### Structure of Light-Emitting Device 2B

Table 5 shows a structure of the light-emitting device 2B. Note that the structure of the light-emitting device 2B is different from that of the light-emitting device TA in the layer 106X2. Specifically, the light-emitting device 2B is different from the light-emitting device TA in that a stacked-layer structure of the layer 106X21 and the layer 106X22 are provided instead of the layer 106X2.

TABLE 5

| | Reference | | Composition | Thickness/ |
|---|---|---|---|---|
| Structure | numeral | Material | ratio | nm |
| Layer | CAP | DBT3P-II | | 70 |
| Electrode | 552X | Ag:Mg | 1:0.1 | 15 |
| Layer | 105X | LiF:Yb | 2:1 | 1.5 |
| Layer | 113X22 | mPPhen2P | | 20 |
| Layer | 113X21 | 2mPCCzPDBq | | 20 |
| Layer | 111X2 | 4,8mDBtP2Bfpm:βNCCP:Ir(ppy)2(mbfpypy-d3) | 0.5:0.5:0.1 | 40 |
| Layer | 112X2 | PCBBiF | | 40 |
| Layer | 106X1 | PCBBiF:OCHD-003 | 1:0.15 | 10 |
| Layer | 106X3 | CuPc | | 2 |
| Layer | 106X22 | Al | | 0.5 |
| Layer | 106X21 | mPPhen2P:2,7hpp2SF | 1:1 | 5 |
| Layer | 113X12 | mPPhen2P | | 15 |
| Layer | 113X11 | 2mPCCzPDBq | | 10 |
| Layer | 111X | 4,8mDBtP2Bfpm:βNCCP:Ir(ppy)2(mbfpypy-d3) | 0.5:0.5:0.1 | 40 |
| Layer | 112X1 | PCBBiF | | 60 |
| Layer | 104X | PCBBiF:OCHD-003 | 1:0.03 | 10 |
| Electrode | 551X | ITSO | | 100 |
| Reflective film | REFX | APC | | 100 |

### Fabrication Method of Light-Emitting Device 2B

The light-emitting device 2B described in this reference example was fabricated using a method including the following steps. Note that the fabrication method of the light-emitting device 2B is different from the fabrication method of the light-emitting device 1A in that the layer 106X21 was formed instead of the layer 106X2 in Step 8, Step 8-2 of forming the layer 106X22 was performed after Step 8 and before Step 9, and the layer 105X was formed over the unit 103X2 without the step of forming a slit between the unit 103X2 and the unit 103Y2. In other words, a method was employed in which Step 15-1 to Step 15-4 are not performed and the process goes to Step 16 after Step 14. Different portions are described in detail here, and the above description is referred to for portions formed by a similar method.

### [Step 8-2]

In Step 8-2, the layer 106X22 was formed over the layer 106X21. Specifically, a material was evaporated by a resistance heating method.

Note that the layer 106X22 contains aluminum (Al) and has a thickness of 0.5 nm.

### [Step 9]

In Step 9, the layer 106X3 was formed over the layer 106X22. Specifically, a material was evaporated by a resistance heating method.

Note that the layer 106X3 contains CuPc and has a thickness of 2 nm.

### Operation Characteristics of Light-Emitting Device 2B

When supplied with electric power, the light-emitting device 2B emitted the light ELX and the light ELX2 (see FIG. 33B). The operation characteristics of the light-emitting device 2B were measured at room temperature (see FIG. 34 to FIG. 38). The luminance, CIE chromaticity, and emission spectrum were measured using a spectroradiometer (SR-UL1R, manufactured by TOPCON TECHNOHOUSE CORPORATION).

Table 2 shows main initial characteristics of the fabricated light-emitting device emitting light at a luminance of approximately 1000 cd/m².

TABLE 6

| | | | Current | | | Current |
|---|---|---|---|---|---|---|
| | Voltage | Current | density | | | efficiency |
| | (V) | (mA) | (mA/cm2) | Chromaticity x | Chromaticity y | (cd/A) |
| Light-emitting | 6.4 | 0.02 | 0.4 | 0.31 | 0.68 | 229.5 |
| device 2B | | | | | | |

The light-emitting device 2B was found to have favorable characteristics. For example, the light-emitting device 2B was driven at a lower voltage than the comparative device 1B. The light-emitting device 2B exhibited current efficiency as high as the comparative device 1B. Thus, 2,7hpp2SF and Al can be suitably used for an intermediate layer in a tandem light-emitting device. Furthermore, an intermediate layer in a tandem light-emitting device can be formed without using an alkali metal or an alkaline earth metal. Furthermore, high resistance to an atmospheric component, an agent containing water, a microfabrication process, and the like can be expected.

### Example 3

In this example, a solubility of an organic compound that can be used in the display apparatus of one embodiment of the present invention will be described.

<Solubility Test of 2,7hpp2SF>

In a sample bottle (capacity: 20 mL) was put 1.16 mg of 1,1′-(9,9′-spirobi[9H-fluorene]-2,7-diyl)bis(1,3,4,6,7,8-hexahydro-2H-pyrimido[1,2-a]pyrimidine) (abbreviation: 2,7hpp2SF), and 0.5 mL of water was added thereto. This mixture was irradiated with ultrasonic waves for one minute. A precipitated white powder was found by visual inspection for an insoluble residue. After further addition of 0.5 mL of water and one-minute ultrasonic wave irradiation, a precipitated white powder was found by visual inspection. This procedure was repeatedly executed until the dissolution was confirmed by visual inspection.

The precipitated white powder was found until the total amount of water reached 3.0 mL. After further addition of 0.5 mL of water and ultrasonic wave irradiation, no precipitated white powder was found.

The results indicate that the weight of 2,7hpp2SF which can be dissolved in 1.0 mL of water is greater than or equal to 0.33 mg and less than 0.39 mg. The weight fraction of the solubility of 2,7hpp2SF in water is higher than or equal to 3.3×10⁻⁴ and lower than 3.9×10⁻⁴. The solubility of 2,7hpp2SF in water was less than or equal to 1/10 of the solubility of 1,1′-pyridine-2,6-diyl-bis(1,3,4,6,7,8-hexahydro-2H-pyrimido[1,2-a]pyrimidine) (abbreviation: hpp2Py) in water.

<Solubility test of 2hppSF>

In a sample bottle (capacity: 100 mL) was put 1.08 mg of 1-(9,9′-spirobi[9H-fluorene]-2-yl)-1,3,4,6,7,8-hexahydro-2H-pyrimido[1,2-a]pyrimidine) (abbreviation: 2hppSF), and 50 mL of water was added thereto. A precipitated white powder was found by visual inspection for an insoluble residue. When 10 mL of water was further added, the precipitated white powder was not observed by visual inspection.

The results indicate that the weight of 2hppSF which can be dissolved in 1.0 mL of water is greater than or equal to 0.018 mg and less than 0.022 mg. The weight fraction of the solubility of 2hppSF in water is higher than or equal to 1.8×10⁻⁵ and lower than 2.2×10⁻⁵. The solubility of 2hppSF in water was less than or equal to 1/10 of the solubility of 1,1′-pyridine-2,6-diyl-bis(1,3,4,6,7,8-hexahydro-2H-pyrimido[1,2-a]pyrimidine) (abbreviation: hpp2Py) in water.

### Reference Example 6

<Solubility Test of hpp2Py>

In a sample bottle (capacity: 5 mL) was put 50.2 mg of 1,1′-pyridine-2,6-diyl-bis(1,3,4,6,7,8-hexahydro-2H-pyrimido[1,2-a]pyrimidine) (abbreviation: hpp2Py), and 1.0 mL of water was added thereto. The dissolution was found by visual inspection for an insoluble residue.

The results indicate that the weight of hpp2Py dissolved in 1.0 mL of water is greater than or equal to 50.2 mg. The weight fraction of the solubility of hpp2Py in water is higher than or equal to 4.8×10².

### Example 4

Described in this example are evaluation results of organic compounds that can be used for the display apparatus of one embodiment of the present invention by a method of computational science.

Specifically, the calculation results of energy levels of the highest occupied molecular orbital (HOMO) and the lowest unoccupied molecular orbital (LUMO) in the stable structure in the ground state S₀ are described.

### <Calculation Method>

A method for calculating the stable structure in the ground state S₀ is described.

### Stable Structure in Ground State s₀

In this example, the stable structure in the ground state S₀ of the organic compound was calculated by a density functional theory method (DFT). Note that Gaussian 16 manufactured by Gaussian, Inc. was used for the quantum chemical calculation program, and a high performance computer (SG18600 manufactured by HPE) was used for calculation.

The total energy obtained using the DFT expresses interactions between complicated electrons of the organic compound. Specifically, the sum of potential energy, electrostatic energy between electrons, and exchange-correlation energy including all the electronic kinetic energy can be expressed. Moreover, a functional (a function of another function) of one electron potential is represented in terms of electron density, and exchange-correlation interaction was approximated by the functional. Thus, the calculation accuracy of DFT is high.

Note that in this example, B3LYP was applied to a hybrid functional to specify the weight of each parameter related to exchange-correlation energy.

In addition, 6-311G was applied to a basis function. 6-311G is a basis function of a triple-split valence basis set using three contraction functions for each valence orbital. By applying the above basis function, for example, is to 3s orbitals are considered in the case of hydrogen atoms, while is to 4s and 2p to 4p orbitals are considered in the case of carbon atoms. In addition, the p function was added to hydrogen atoms and d function was added to atoms other than hydrogen atoms as a basis function of a polarization basis set, so that calculation accuracy is improved.

### <Calculation Result>

In this example, as examples of the organic compounds that can be used for the display apparatus of one embodiment of the present invention, 2hppSF, 2,7hpp2SF, (103), and (104), which are organic compounds represented by structural formulae shown below, were calculated.

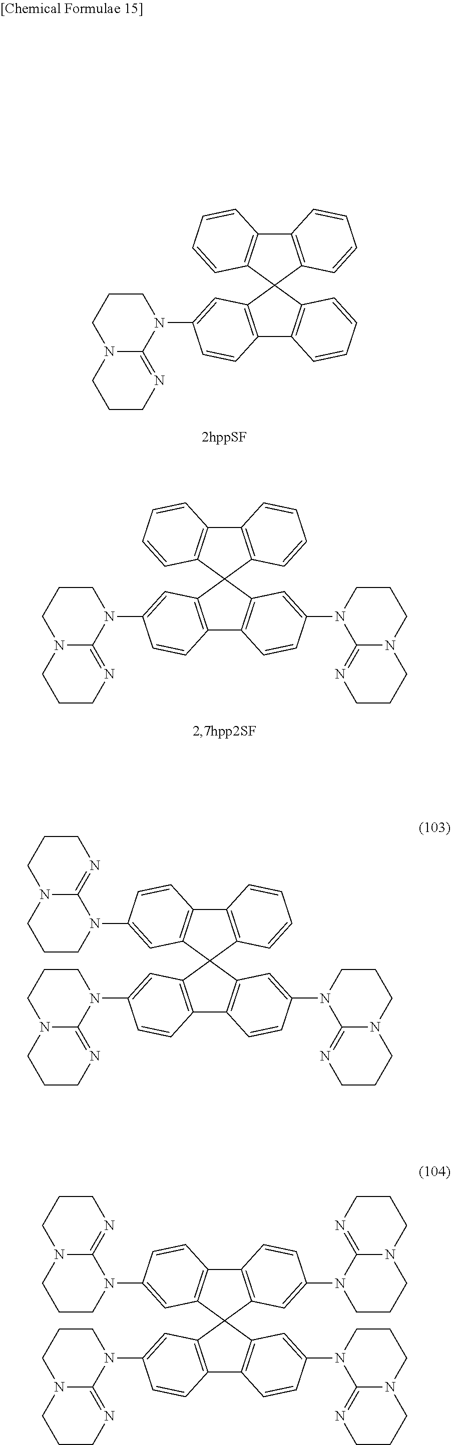 [SMILES: c1ccc2c(c1)-c1ccccc1C21c2ccccc2-c2ccc(N3CCCN4CCCN=C43)cc21 ; c1ccc2c(c1)-c1ccccc1C21c2cc(N3CCCN4CCCN=C43)ccc2-c2ccc(N3CCCN4CCCN=C43)cc21 ; c1ccc2c(c1)-c1ccc(N3CCCN4CCCN=C43)cc1C21c2cc(N3CCCN4CCCN=C43)ccc2-c2ccc(N3CCCN4CCCN=C43)cc21 ; c1cc2c(cc1N1CCCN3CCCN=C31)C1(c3cc(N4CCCN5CCCN=C54)ccc3-2)c2cc(N3CCCN4CCCN=C43)ccc2-c2ccc(N3CCCN4CCCN=C43)cc21]

Calculation results are shown in Table 7.

TABLE 7

| | 2hppSF | 2,7hpp2SF | (103) | (104) |
|---|---|---|---|---|
| LUMO | −1.00 eV | −0.93 eV | −0.72 eV | −0.49 eV |
| HOMO | −5.17 eV | −4.82 eV | −4.69 eV | −4.65 eV |

As the number of 1,3,4,6,7,8-hexahydro-2H-pyrimido[1,2-a]pyrimidino groups is increased, the HOMO level is increased.

### Example 5

In this example, the display apparatus 700-A of one embodiment of the present invention will be described with reference to FIG. 19 and FIG. 40 to FIG. 45.

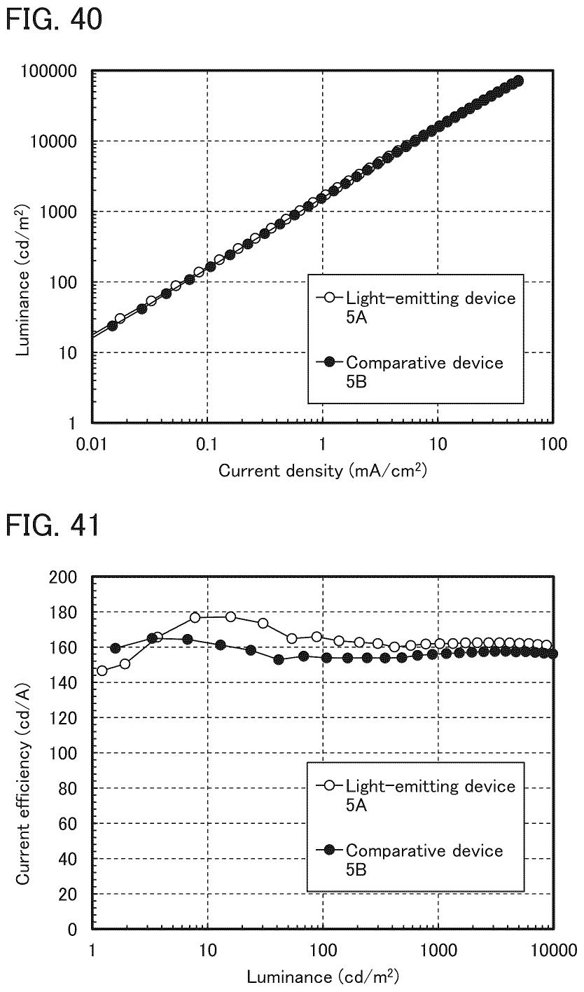

FIG. 40 is a graph showing current density-luminance characteristics of a light-emitting device 5A.

FIG. 41 is a graph showing luminance-current efficiency characteristics of the light-emitting device 5A.

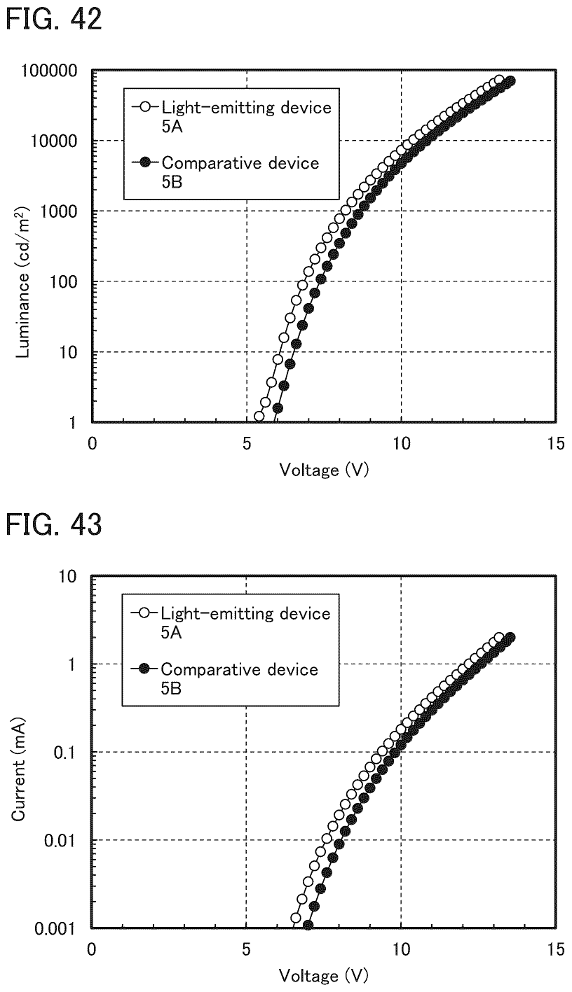

FIG. 42 is a graph showing voltage-luminance characteristics of the light-emitting device 5A.

FIG. 43 is a graph showing voltage-current characteristics of the light-emitting device 5A.

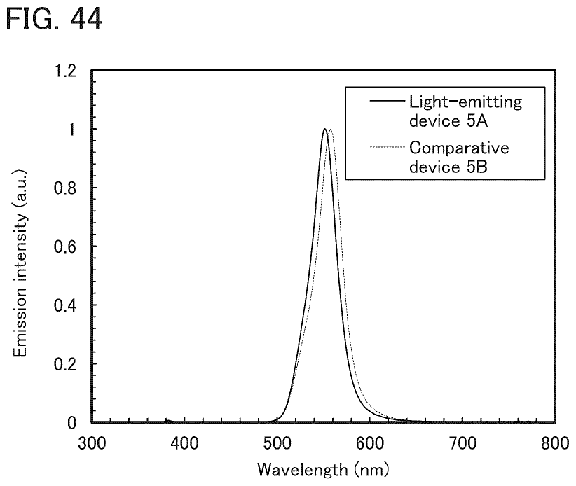

FIG. 44 is a graph showing an emission spectrum of the light-emitting device 5A emitting light at a luminance of 1000 cd/m².

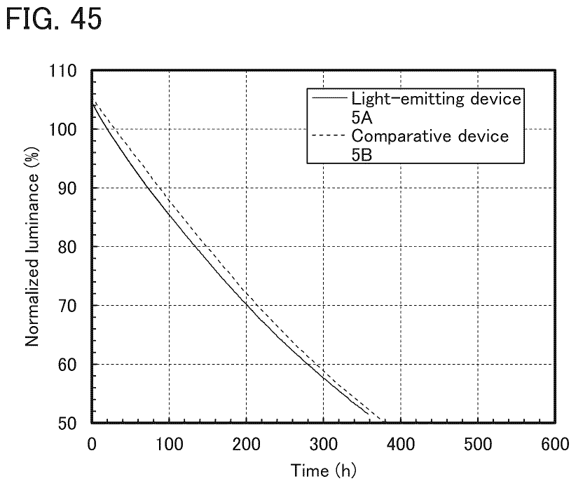

FIG. 45 is a graph showing a change in normalized luminance over time of the light-emitting device 5A emitting light at a constant current density (50 mA/cm²).

### <Display Apparatus 700-A>

The fabricated display apparatus 700-A described in this example includes the light-emitting device 550X and the light-emitting device 550Y (see FIG. 19 and FIG. 19B). The light-emitting device 550Y is adjacent to the light-emitting device 550X and includes a gap between the light-emitting device 550Y and the light-emitting device 550X.

### <Light-Emitting Device 5A>

The fabricated light-emitting device 5A described in this example has a structure similar to that of the light-emitting device 550X (see FIG. 19B).

### Structure of Light-Emitting Device 5A>>

Table 8 shows the structure of the light-emitting device 5A. Note that the structure of the light-emitting device 5A is different from that of the light-emitting device 1A in the layer 106X2. Specifically, the light-emitting device 5A is different from the light-emitting device 1A in that the layer 106X2 contains 2hppSF instead of 2,7hpp2SF.

TABLE 8

| | Reference | | Composition | Thickness/ |
|---|---|---|---|---|
| Structure | numeral | Material | ratio | nm |
| Layer | CAP | DBt3P-II | | 70 |
| Electrode | 552X | Ag:Mg | 1:0.1 | 15 |
| Layer | 105X | LiF:Yb | 2:1 | 1.5 |
| Layer | 113X22 | mPPhen2P | | 20 |
| Layer | 113X21 | 2mPCCzPDBq | | 20 |
| Layer | 111X2 | 4,8mDBtP2Bfpm:βNCCP:Ir(ppy)2(mbfpypy-d3) | 0.5:0.5:0.1 | 40 |
| Layer | 112X2 | PCBBiF | | 40 |
| Layer | 106X1 | PCBBiF:OCHD-003 | 1:0.15 | 10 |
| Layer | 106X3 | CuPc | | 2 |
| Layer | 106X2 | mPPhen2P:2hppSF | 1:0.5 | 5 |
| Layer | 113X12 | mPPhen2P | | 15 |
| Layer | 113X11 | 2mPCCzPDBq | | 10 |
| Layer | 111X | 4,8mDBtP2Bfpm:βNCCP:Ir(ppy)2(mbfpypy-d3) | 0.5:0.5:0.1 | 40 |
| Layer | 112X1 | PCBBiF | | 60 |
| Layer | 104X | PCBBiF:OCHD-003 | 1:0.03 | 10 |
| Electrode | 551X | ITSO | | 100 |
| Reflective film | REF1 | APC | | 100 |

### Fabrication Method of Light-Emitting Device 5A

The light-emitting device 5A described in this example was fabricated using a method including the following steps. Note that the fabrication method of the light-emitting device 5A is different from the fabrication method of the light-emitting device 1A in that mPPhen2P and 2hppSF are used instead of mPPhen2P and 2,7hpp2SF in Step 8. Different portions are described in detail here, and the above description is referred to for portions formed by a similar method.

### [Step 8]

In Step 8, the layer 106X2 was formed over the layer 113X12. Specifically, materials were co-evaporated by a resistance heating method.

The layer 106X2 contains mPPhen2P and 2hppSF at mPPhen2P: 2hppSF=1: 0.5 (weight ratio) and has a thickness of 5 nm.

### Operation Characteristics of Light-Emitting Device 5A

When supplied with electric power, the light-emitting device 5A emitted the light ELX and the light ELX2 (see FIG. 19B). The operation characteristics of the light-emitting device 5A were measured at room temperature (see FIG. 40 to FIG. 45). The luminance, CIE chromaticity, and emission spectrum were measured using a spectroradiometer (SR-UL1R, manufactured by TOPCON TECHNOHOUSE CORPORATION).

Table 9 shows main initial characteristics of the fabricated light-emitting device emitting light at a luminance of approximately 1000 cd/m². Table 10 shows LT90, which is taken for the luminance to drop to 90% of its initial value and is obtained under the condition where the light-emitting device emitted light at a constant current density (50 mA/cm²). Table 9 and Table 10 also show the characteristics of the other light-emitting devices whose structures will be described later.

TABLE 9

| | | | Current | | | Current |
|---|---|---|---|---|---|---|
| | Voltage | Current | density | | | efficiency |
| | (V) | (mA) | (mA/cm2) | Chromaticity x | Chromaticity y | (cd/A) |
| Light-emitting | 8.2 | 0.03 | 0.6 | 0.33 | 0.66 | 161.9 |
| device 5A | | | | | | |
| Comparative | 8.6 | 0.02 | 0.6 | 0.36 | 0.63 | 155.8 |
| device 5B | | | | | | |

TABLE 10

| | LT90 (hr) |
|---|---|
| Light-emitting device 5A | 73 |
| Comparative device 5B | 87 |

The light-emitting device 5A was found to have favorable characteristics. For example, the light-emitting device 5A has substantially the same driving voltage and current efficiency as a comparative device 5B that will be described later (see FIG. 41 to FIG. 43). Furthermore, a reduction in the driving lifetime of the light-emitting device 5A was not observed as compared with the comparative device 5B described later (see FIG. 45). In other words, in comparison with the comparative device 5B, an increase in driving voltage and a reduction in current efficiency were not observed in the light-emitting device 5A fabricated through Step 15-1 to Step 15-4. The light-emitting device 5A has high resistance to atmospheric components to which the light-emitting device 5A is exposed in Step 15-1 to Step 15-4. An intermediate layer containing 2hppSF has high resistance to microfabrication techniques used in Step 15-1 to Step 15-4. The intermediate layer containing 2hppSF has high resistance to an agent containing water and phosphoric acid that is exposed in Step 15-3, for example.

### Reference Example 7

The fabricated comparative display apparatus 700-B described in this reference example includes the light-emitting device 550X and the light-emitting device 550Y (see FIG. 25A). The light-emitting device 550Y is adjacent to the light-emitting device 550X. Note that the comparative display apparatus 700-B is different from the display apparatus 700-A described in Example 5 in that a gap is not included between the light-emitting device 550Y and the light-emitting device 550X.

### <Comparative Device 5B>

The fabricated comparative device 5B has a structure similar to that of the light-emitting device 550X (see FIG. 25B).

### «Structure of Comparative Device 5B»

The structure of the comparative device 5B is the same as that of the light-emitting device 5A except that a gap is not formed between the comparative device 5B and its adjacent comparative device (see Table 8).

### Fabrication Method of Comparative Device 5B

The comparative device 5B described in this reference example was fabricated using a method including the following steps. Note that the fabrication method of the comparative device 5B is different from the fabrication method of the light-emitting device 5A in that the layer 105X was formed over the unit 103X2 without the step of forming a slit between the unit 103X2 and the unit 103Y2. In other words, a method was employed in which Step 15-1 to Step 15-4 are not performed and the process goes to Step 16 after Step 14.

### REFERENCE NUMERALS

CFX: coloring layer, 103X: unit, 103X2: unit, 103Y: unit, 103Y2: unit, 104X: layer, 104Y: layer, 105X: layer, 105Y: layer, 106X: intermediate layer, 106XX: intermediate layer, 106X1: layer, 106X2: layer, 106X21: layer, 106X22: layer, 106X3: layer, 106XY: region, 106XY1: region, 106XY2: region, 106Y: intermediate layer, 106Y1: layer, 106Y2: layer, 111X: layer, 111X2: layer, 111Y: layer, 111Y2: layer, 112X: layer, 112X2: layer, 112Y: layer, 112Y2: layer, 113X: layer, 113X2: layer, 113Y: layer, 113Y2: layer, 231: region, 400: substrate, 401: first electrode, 403: EL layer, 404: second electrode, 405: sealant, 406: sealant, 407: sealing substrate, 412: pad, 420: IC chip, 510: substrate, 520: functional layer, 520T: region, 521: insulating film, 528: insulating film, 528_1: insulating film, 528_2: insulating film, 528_3: insulating film, 540: functional layer, 550X: light-emitting device, 550Y: light-emitting device, 551X: electrode, 551Y: electrode, 551XY: gap, 552X: electrode, 552Y: electrode, 601: source line driver circuit, 602: pixel portion, 603: gate line driver circuit, 604: sealing substrate, 605: sealant, 607: space, 608: lead wiring, 609: external input terminal, 610: element substrate, 611: switching FET, 612: current control FET, 613: first electrode, 614: insulator, 616: EL layer, 617: second electrode, 618: light-emitting device, 623: FET, 951: substrate, 952: electrode, 953: insulating layer, 954: partition layer, 955: EL layer, 956: electrode, 1001: substrate, 1002: base insulating film, 1003: gate insulating film, 1006: gate electrode, 1007: gate electrode, 1008: gate electrode, 1020: first interlayer insulating film, 1021: second interlayer insulating film, 1022: electrode, 1024B: electrode, 1024G: electrode, 1024R: electrode, 1024 W: electrode, 1025: partition, 1028: EL layer, 1029: electrode, 1031: sealing substrate, 1032: sealant, 1033: base material, 1034B: coloring layer, 1034G: coloring layer, 1034R: coloring layer, 1035: black matrix, 1036: overcoat layer, 1037: third interlayer insulating film, 1040: pixel portion, 1041: driver circuit portion, 1042: peripheral portion, 2001: housing, 2002: light source, 2100: robot, 2102: microphone, 2103: upper camera, 2104: speaker, 2105: display, 2106: lower camera, 2107: obstacle sensor, 2108: moving mechanism, 2110: arithmetic device, 3001: lighting apparatus, 5000: housing, 5001: display portion, 5002: display portion, 5003: speaker, 5004: LED lamp, 5006: connection terminal, 5007: sensor, 5008: microphone, 5012: support, 5013: earphone, 5100: cleaning robot, 5101: display, 5102: camera, 5103: brush, 5104: operation button, 5120: dust, 5140: portable electronic device, 5200: display region, 5201: display region, 5202: display region, 5203: display region, 7101: housing, 7103: display portion, 7105: stand, 7107: display portion, 7109: operation key, 7110: remote controller, 7201: main body, 7202: housing, 7203: display portion, 7204: keyboard, 7205: external connection port, 7206: pointing device, 7210: second display portion, 7401: housing, 7402: display portion, 7403: operation button, 7404: external connection port, 7405: speaker, 7406: microphone, 9310: portable information terminal, 9311: display panel, 9313: hinge, 9315: housing

1. A display apparatus comprising:
a first light-emitting device; and
a second light-emitting device,
wherein the first light-emitting device comprises a first electrode, a second electrode, a first unit, a second unit, and a first intermediate layer,
wherein the first unit is sandwiched between the first electrode and the second electrode,
wherein the first unit comprises a first light-emitting material,
wherein the second unit is sandwiched between the second electrode and the first unit,
wherein the second unit comprises a second light-emitting material,
wherein the first intermediate layer is sandwiched between the second unit and the first unit,
wherein the first intermediate layer comprises a first layer and a second layer,
wherein the first layer is sandwiched between the second unit and the second layer,
wherein the first layer comprises an organic compound comprising a halogen group or a cyano group, or a transition metal oxide,
wherein the second layer comprises an organic compound exhibiting an electron-injection property,
wherein the second light-emitting device is adjacent to the first light-emitting device,
wherein the second light-emitting device comprises a third electrode, a fourth electrode, a third unit, a fourth unit, and a second intermediate layer,
wherein a gap is included between the third electrode and the first electrode,
wherein the third unit is sandwiched between the third electrode and the fourth electrode,
wherein the third unit comprises a third light-emitting material,
wherein the fourth unit is sandwiched between the fourth electrode and the third unit,
wherein the fourth unit comprises a fourth light-emitting material,
wherein the second intermediate layer is sandwiched between the fourth unit and the third unit,
wherein a region is included between the second intermediate layer and the first intermediate layer,
wherein the first intermediate layer and the second intermediate layer are separated from each other by the region,
wherein the region overlaps with the gap,
wherein the second intermediate layer comprises a third layer and a fourth layer,
wherein the third layer is sandwiched between the fourth unit and the fourth layer,
wherein the third layer comprises an organic compound comprising a halogen group or a cyano group, or a transition metal oxide,
wherein the fourth layer comprises the organic compound exhibiting an electron-injection property, and
wherein the organic compound exhibiting an electron-injection property is represented by General Formula (G0): 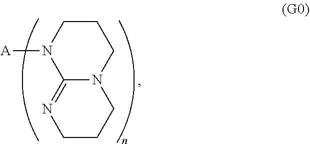
wherein A is a substituted or unsubstituted aryl skeleton having 6 to 30 carbon atoms or a substituted or unsubstituted heteroaryl skeleton having 2 to 30 carbon atoms, and n is an integer greater than or equal to 1 and less than or equal to 4.

2. The display apparatus according to claim 1,
wherein a solubility of the organic compound exhibiting an electron-injection property in water is less than or equal to 1/10 of a solubility of 1,1′-pyridine-2,6-diyl-bis(1,3,4,6,7,8-hexahydro-2H-pyrimido[1,2-a]pyrimidine) in water at a pressure of one atmosphere and 300 K.

3. The display apparatus according to claim 1,
wherein the organic compound exhibiting an electron-injection property has a solubility in water of greater than 0 and less than 4.0×10⁻⁴ by weight fraction at a pressure of one atmosphere and 300 K.

4. The display apparatus according to claim 1,
wherein the organic compound exhibiting an electron-injection property is represented by General Formula (G1): 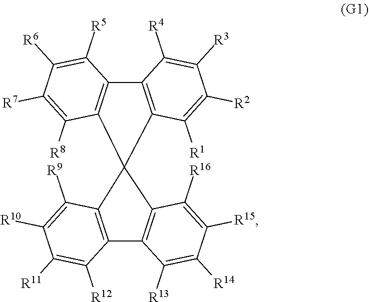
wherein one or more and four or less of R¹ to R¹⁶ each comprise a substituted or unsubstituted 1,3,4,6,7,8-hexahydro-2H-pyrimido[1,2-a]pyrimidino group, and the others of R¹ to R¹⁶ are each hydrogen, a substituted or unsubstituted alkyl group having 1 to 6 carbon atoms, a substituted or unsubstituted cycloalkyl group having 3 to 10 carbon atoms, a substituted or unsubstituted polycyclic cycloalkyl group having 4 to 10 carbon atoms, a substituted or unsubstituted aromatic hydrocarbon group having 6 to 30 carbon atoms, or a substituted or unsubstituted heteroaromatic hydrocarbon group having 2 to 30 carbon atoms, and the hydrogen may be deuterium in General Formula (G1).

5. The display apparatus according to claim 1, further comprising:
a first functional layer; and
a second functional layer,
wherein the first functional layer overlaps with the second functional layer,
wherein the first functional layer comprises a first pixel circuit and a second pixel circuit,
wherein the second functional layer comprises the first light-emitting device and the second light-emitting device,
wherein the first light-emitting device is electrically connected to the first pixel circuit, and
wherein the second light-emitting device is electrically connected to the second pixel circuit.

6. The display apparatus according to claim 1, further comprising:
a first pixel; and
a second pixel,
wherein the first pixel is adjacent to the second pixel,
wherein the first pixel comprises the first light-emitting device and a first pixel circuit,
wherein the second pixel comprises the second light-emitting device and a second pixel circuit,
wherein the first light-emitting device is electrically connected to the first pixel circuit, and
wherein the second light-emitting device is electrically connected to the second pixel circuit.

7. An electronic device comprising the display apparatus according to claim 1, and a sensor, an operation button, a speaker, or a microphone.
